(19) United States
(12) Patent Application Publication
(10) Pub. No.: US 2012/0207978 A1
(43) Pub. Date: Aug. 16, 2012

(54) ACTINIC-RAY-SENSITIVE OR RADIATION-SENSITIVE RESIN COMPOSITION, AND RESIST FILM AND PATTERN FORMING METHOD USING THE SAME COMPOSITION

(75) Inventors: Akinori SHIBUYA, Shizuoka (JP); Shuhei YAMAGUCHI, Shizuoka (JP); Kunihiko KODAMA, Shizuoka (JP); Kenji WADA, Shizuoka (JP); Tomoki MATSUDA, Shizuoka (JP)

(73) Assignee: FUJIFILM CORPORATION, Tokyo (JP)

(21) Appl. No.: 13/369,528

(22) Filed: Feb. 9, 2012

(30) Foreign Application Priority Data
Feb. 10, 2011 (JP) 2011-027910

(51) Int. Cl. G03F 7/20; B32B 3/30; G03F 7/004

(52) U.S. Cl. 428/156; 430/270.1; 430/285.1; 430/325; 430/311

(57) ABSTRACT

An object of the present invention is to provide an actinic-ray-sensitive or radiation-sensitive resin composition which is significantly excellent in terms of exposure latitude, is capable of forming a favorable rectangular pattern profile, and exhibits low dissolution of the components into an immersion liquid when performing immersion exposure, and a resist film and a pattern forming method each using the same composition. The actinic-ray-sensitive or radiation-sensitive resin composition contains (A) a compound represented by formula (I) and capable of generating an acid upon irradiation of actinic-rays or radiations, and (B) a resin capable of increasing the solubility in an alkaline developer by the action of an acid.

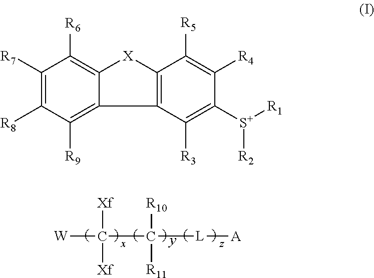

### BACKGROUND OF THE INVENTION

1. Field of the Invention

The present invention relates to an actinic-ray-sensitive or radiation-sensitive resin composition showing changes of a property in response to irradiation of actinic-rays or radiations, a resist film formed using the same composition, and a pattern forming method using the same composition. More specifically, the present invention relates to an actinic-ray-sensitive or radiation-sensitive resin composition that is used in a manufacturing process of semiconductors such as ICs, a process of producing circuit boards for liquid crystals and thermal heads, or other photofabrication processes, lithographic printing plates or acid-curable compositions, to a resist film formed using the same composition, and a pattern forming method using the same composition.

2. Description of the Related Art

A chemical amplification type resist composition is a pattern formation material which is capable of forming a pattern on a substrate by generating an acid in the exposed area upon irradiation of active radiations, for example, far ultraviolet rays, and making a difference in the solubility in a developer between the unirradiated area and the irradiated area, through a reaction using the generated acid as a catalyst.

In the case where a KrF excimer laser is used as a light source for exposure, the chemical amplification type resist composition is mainly composed of a resin having as a basic skeleton, poly(hydroxystyrene) that has a weak absorption in a wavelength region of 248 nm. Therefore, such a composition is a favorable system capable of forming a good-quality pattern with high sensitivity and high resolution, as compared to the conventional naphthoquinone-diazide/novolak resin system.

On the other hand, in the case where a light source having a shorter wavelength, for example, an ArF excimer laser (193 nm) is used for exposure, the chemical amplification type resist composition mentioned above is not satisfactory since an aromatic group-containing compound used in the composition intrinsically shows strong absorption at a wavelength region of 193 nm. In order to address such a problem, a resist composition for use with an ArF excimer laser, containing a resin having an alicyclic hydrocarbon structure, has been developed.

Further, various compounds have also been developed for a photoacid generator which is a main component of a chemical amplification type resist composition (for example, see JP2003-140332A, EP 1270553A, WO02/042845A, JP2002-131897A, JP2002-214774A, US2004/0087690A, JP2005-266766A, and JP2005-308969A). For example, JP2005-308969A discloses a photoacid generator of a sulfonium salt having an indole group or the like.

However, the current situation is that it is extremely difficult to find an appropriate combination of a resin, a photoacid generator, a basic compound, an additive, a solvent and the like to be employed, from the viewpoint of overall performance of the resist. For example, there is a need for development of a resist composition which is excellent in terms of exposure latitude, is capable of forming a favorable pattern profile, and exhibits low dissolution of the components into an immersion liquid when performing immersion exposure.

### SUMMARY OF THE INVENTION

Therefore, the present invention has been made in view of the aforesaid related art, and an object of the present invention is to provide an actinic-ray-sensitive or radiation-sensitive resin composition which is significantly excellent in terms of exposure latitude, is capable of forming a favorable rectangular pattern profile, and exhibits low dissolution of the components into an immersion liquid when performing immersion exposure, and a resist film and a pattern forming method each using the same composition.

The inventors have conducted extensive and intensive studies with a view toward solving the above problems, and have arrived at this invention. That is, the actinic-ray-sensitive or radiation-sensitive resin composition of the present invention which is capable of solving the above problems is characterized by containing (A) a compound represented by the following formula (I) and capable of generating an acid upon irradiation of actinic-rays or radiations, and (B) a resin capable of increasing the solubility in an alkaline developer by the action of an acid.

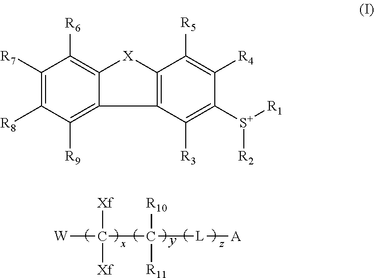

In the formula (I),

X represents an oxygen atom, a sulfur atom or —N(Rx)—,

R₁ and R₂ each independently represent an alkyl group, a cycloalkyl group or an aryl group,

R₃ to R₉ each independently represent a hydrogen atom, an alkyl group, a cycloalkyl group, an alkoxy group, an alkoxycarbonyl group, an acyl group, an alkylcarbonyloxy group, an aryl group, an aryloxy group, an aryloxycarbonyl group or an arylcarbonyloxy group,

Rx represents a hydrogen atom, an alkyl group, a cycloalkyl group, an acyl group, an alkenyl group, an alkoxycarbonyl group, an aryl group, an arylcarbonyl group or aryloxycarbonyl group,

R₁ and R₂ may combine with each other to form a ring, and two or more of R₆ to R₉, R₃ and R₉, R₄ and R₅, R₅ and Rx, and R₆ and Rx each may combine with each other to form a ring,

Xf's each independently represent a fluorine atom, or an alkyl group substituted with at least one fluorine atom,

R₁₀ and R₁₁ each independently represent a hydrogen atom, a fluorine atom, or an alkyl group, and in the case where a plurality of R₁₀'s or R₁₁'s are present, each R₁₀ or R₁₁ may be the same as or different from every other R₁₀ or R₁₁,

L represents a divalent linking group, and in the case where a plurality of L's are present, each L may be the same as or different from every other L,

A represents a cyclic organic group,

W represents ⁻O₃S—, RfSO₂—N⁻—SO₂—, Rf—CO—N⁻—SO₂— or Rf—SO₂—N⁻—CO— wherein Rf represents an alkyl group substituted with at least one fluorine atom, and

x represents an integer of 1 to 20, y represents an integer of 0 to 10, and z represents an integer of 0 to 10.

In the present invention, preferred embodiments are an embodiment in which X of formula (I) represents a sulfur atom or —N(Rx)—, an embodiment in which L of formula (I) represents —COO—, —COO—, —CO—, —SO₂—, —CON(Ri)—, —SO₂N(Ri)—, —CON(Ri)-alkylene group-, —OCO-alkylene group- or —COO-alkylene group- (wherein, Ri represents a hydrogen atom or alkyl), and an embodiment which further contains a hydrophobic resin.

Further, in the present invention, preferred embodiments are also an embodiment in which the hydrophobic resin has a repeating unit (b) containing at least one group selected from the group consisting of the following (x) to (z) and an embodiment in which the content of the hydrophobic resin is in the range of 0.01 to 20 mass %, based on the total solid content:

(x) an alkali-soluble group,

(y) a group capable of decomposing by the action of an alkaline developer to increase the solubility in an alkaline developer, and

(z) a group capable of decomposing by the action of an acid to increase the solubility in an alkaline developer.

Further, in the present invention, preferred embodiments are also an embodiment in which the resin (B) contains an alicyclic hydrocarbon structure, an embodiment in which the resin (B) contains a repeating unit having a lactone structure, and an embodiment in which the hydrophobic resin is a hydrophobic resin having at least either a fluorine atom or a silicon atom.

Further, preferred embodiments are also an embodiment in which the actinic-ray-sensitive or radiation-sensitive resin composition of the present invention further contains at least one of a fluorine-based surfactant and a silicon-based surfactant, an embodiment in which the actinic-ray-sensitive or radiation-sensitive resin composition of the present invention further contains a basic material, and an embodiment in which the actinic-ray-sensitive or radiation-sensitive resin composition of the present invention further contains a low molecular weight compound containing a nitrogen atom and having a group capable of leaving by the action of an acid.

Also in the present invention is included a resist film formed using the above-described actinic-ray-sensitive or radiation-sensitive resin composition.

Further, the present invention also encompasses a pattern forming method including a step of exposing the above-described resist film, and a step of developing the exposed resist film. In the present invention, a preferred embodiment is an embodiment in which the exposure is immersion exposure.

Further, the present invention also encompasses a manufacturing method of an electronic device including the foregoing pattern forming method, and an electronic device manufactured by such a method.

With regard to the actinic-ray-sensitive or radiation-sensitive resin composition of the present invention, preferred embodiments are an embodiment in which the cyclic organic group A in the formula (I) is an alicyclic group, an embodiment in which R₁ and R₂ in the formula (I) do not combine with each other to form a ring, an embodiment in which R₃ to R₉ in the formula (I) each independently represent a hydrogen atom, and an embodiment in which z in the formula (I) is 1.

Further, a preferred embodiment is also an embodiment in which the resin (B) is a resin having at least either a repeating unit represented by the following formula (I) or a repeating unit represented by the following formula (II):

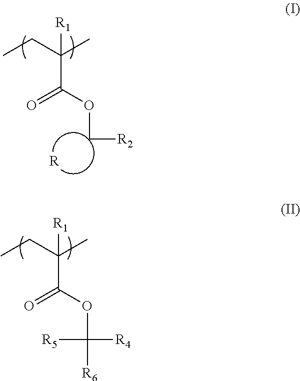

In the formulae (I) and (II),

R₁ and R₃ each independently represent a hydrogen atom, a methyl group which may have a substituent or a group represented by —CH₂—R₉ wherein R₉ represents a hydroxyl group or a monovalent organic group,

R₂, R₄, R₅, and R₆ each independently represent an alkyl group or a cycloalkyl group, and

R represents an atomic group necessary for forming an alicyclic structure together with the carbon atom.

In the pattern forming method of the present invention, a preferred embodiment is also an embodiment in which the exposure is carried out by an ArF excimer laser.

The actinic-ray-sensitive or radiation-sensitive resin composition of the present invention and the resist film and the pattern forming method each using the same composition enable the realization of significantly excellent exposure latitude, the formation of a favorable rectangular pattern profile, and low dissolution of the components into an immersion liquid upon immersion exposure. Further, the actinic-ray-sensitive or radiation-sensitive resin composition of the present invention and the resist film and the pattern forming method each using the same composition can be used suitably in, for example, ArF immersion exposure processes.

### DESCRIPTION OF THE PREFERRED EMBODIMENTS

In the description of the present invention, when a group (atomic group) is denoted without specifying whether substituted or unsubstituted, the group includes both a group having no substituent and a group having a substituent. For example, “an alkyl group” includes not only an alkyl group having no substituent (unsubstituted alkyl group) but also an alkyl group having a substituent (substituted alkyl group).

As used herein, the term “actinic-ray” or “radiation” refers to, for example, a bright line spectrum of mercury lamp, a far ultraviolet ray typified by excimer laser, an extreme-ultraviolet ray (EUV light), an X-ray or an electron beam (EB). Also, the term “light” as used herein means actinic-rays or radiations.

Unless otherwise specifically indicated, the term “exposure” as used herein includes not only exposure to a mercury lamp, far ultraviolet rays typified by excimer laser, X-rays, EUV light or the like but also lithography with a particle beam such as electron beam and an ion beam. In the following description, “in the range of xx to yy” means that it includes numerical values designated by “xx” and “yy” as a lower limit and an upper limit, respectively.

The actinic-ray-sensitive or radiation-sensitive resin composition of the present invention contains:

(A) a compound represented by the following formula (I) and capable of generating an acid upon irradiation of actinic-rays or radiations (hereinafter, also referred to as “compound (A) or “photoacid generator (A)”), and

(B) a resin capable of increasing the solubility in an alkaline developer by the action of an acid.

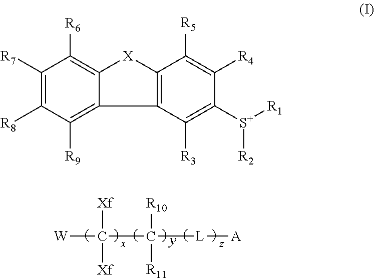

In the formula (I),

X represents an oxygen atom, a sulfur atom or —N(Rx)—,

R₁ and R₂ each independently represent an alkyl group, a cycloalkyl group or an aryl group,

R₃ to R₉ each independently represent a hydrogen atom, an alkyl group, a cycloalkyl group, an alkoxy group, an alkoxycarbonyl group, an acyl group, an alkylcarbonyloxy group, an aryl group, an aryloxy group, an aryloxycarbonyl group or an arylcarbonyloxy group,

Rx represents a hydrogen atom, an alkyl group, a cycloalkyl group, an acyl group, an alkenyl group, an alkoxycarbonyl group, an aryl group, an arylcarbonyl group or aryloxycarbonyl group,

R₁ and R₂ may combine with each other to form a ring, and two or more of R₆ to R₉, R₃ and R₉, R₄ and R₅, R₅ and Rx, and R₆ and Rx each may combine with each other to form a ring,

Xf's each independently represent a fluorine atom, or an alkyl group substituted with at least one fluorine atom,

R₁₀ and R₁₁ each independently represent a hydrogen atom, a fluorine atom, or an alkyl group, and when a plurality of R₁₀'s or R₁₁'s are present, each R₁₀ or R₁₁ may be the same as or different from every other R₁₀ or R₁₁,

L represents a divalent linking group, and when a plurality of L's are present, each L may be the same as or different from every other L,

A represents a cyclic organic group,

W represents ⁻O₃S—, RfSO₂—N⁻—SO₂—, Rf—CO—N⁻—SO₂— or Rf—SO₂—N⁻—CO— wherein Rf represents an alkyl group substituted with at least one fluorine atom, and

x represents an integer of 1 to 20, y represents an integer of 0 to 10, and z represents an integer of 0 to 10.

The actinic-ray-sensitive or radiation-sensitive resin composition of the present invention, due to containing the compound (A), is excellent in exposure latitude, is capable of forming a favorable pattern profile, and is also capable of reducing dissolution of the components into an immersion liquid during immersion exposure. Although the reason for such effects is not clear, it is considered that, due to a high molecular weight and a bulky volume of an acid generated by irradiation of actinic-rays or radiations, diffusion of the acid when performing a post-baking step after exposure is inhibited in having an effect on enlargement of exposure latitude. Further, it is believed that since the compound (A) has adequate hydrophobicity, a favorable pattern profile is obtainable due to inhibition of dissolution of the components into an immersion liquid, and also low dissolution acceleration of the components and inhibition of film thickness loss of the pattern upper part during alkaline development.

The actinic-ray-sensitive or radiation-sensitive resin composition of the present invention is, for example, a positive composition, typically a positive resist composition. Hereinafter, individual components of this composition will be described.

[1] Compound (A) Represented by Formula (I) and Capable of Generating an Acid Upon Irradiation of Actinic-Rays or Radiations.

The actinic-ray-sensitive or radiation-sensitive resin composition of the present invention contains, as described above, the compound (A) represented by formula (I) and capable of generating an acid upon irradiation of actinic-rays or radiations.

Hereinafter, the compound (A) represented by formula (I) and capable of generating an acid upon irradiation of actinic-rays or radiations will be described in more detail.

X is preferably a sulfur atom or —N(Rx)—, from the viewpoint of inhibiting a light absorption property of a resist film (for example, absorbance at a wavelength of 193 nm) to be low.

The alkyl group for R₁ to R₉, and Rx may have a substituent, is preferably a linear or branched alkyl group having 1 to 20 carbon atoms, and may have an oxygen atom, a sulfur atom or a nitrogen atom in the alkyl chain. Specific examples of the alkyl group include linear alkyl groups such as a methyl group, an ethyl group, an n-propyl group, an n-butyl group, an n-pentyl group, an n-hexyl group, an n-octyl group, an n-dodecyl group, an n-tetradecyl group, and an n-octadecyl group, and branched alkyl groups such as an isopropyl group, an isobutyl group, a t-butyl group, a neopentyl group, and a 2-ethylhexyl group.

Examples of the substituent-containing alkyl group for Rx include a cyanomethyl group, a 2,2,2-trifluoroethyl group, a methoxycarbonylmethyl group, and an ethoxycarbonylmethyl group.

Examples of the substituent-containing alkyl group for R₁ and R₂ include a methoxyethyl group.

Further, the substituent-containing alkyl group includes, particularly, a group where a cycloalkyl group is substituted on a linear or branched alkyl group, such as an adamantylmethyl group, an adamantylethyl group, a cyclohexylethyl group and a camphor residue.

The cycloalkyl group of R₁ to R₉, and Rx, which may have a substituent, is preferably a cycloalkyl group having 3 to 20 carbon atoms and may contain an oxygen atom in the ring. Specific examples thereof include a cyclopropyl group, a cyclopentyl group, a cyclohexyl group, a norbornyl group and an adamantyl group.

The acyl group of R₃ to R₉, Rx, which may have a substituent, is preferably an acyl group having 1 to 10 carbon atoms. Specific examples thereof include an acetyl group, a propionyl group, and an isobutyryl group.

The alkenyl group of Rx is preferably an alkenyl group having 2 to 8 carbon atoms, and examples thereof include a vinyl group, an allyl group, and a butenyl group.

The alkoxy group of R₃ to R₉, which may have a substituent, is preferably an alkoxy group having 1 to 20 carbon atoms. Specific examples thereof include a methoxy group, an ethoxy group, an isopropyloxy group, and a cyclohexyloxy group.

The alkoxycarbonyl group of R₃ to R₉, and Rx, which may have a substituent, is preferably an alkoxycarbonyl group having 2 to 20 carbon atoms. Specific examples thereof include a methoxycarbonyl group, an ethoxycarbonyl group, an isopropyloxycarbonyl group, and a cyclohexyloxycarbonyl group.

The alkylcarbonyloxy group of R₃ to R₉, which may have a substituent, is preferably an alkylcarbonyloxy group having 2 to 20 carbon atoms. Specific examples thereof include a methylcarbonyloxy group, an ethylcarbonyloxy group, an isopropylcarbonyloxy group, and a cyclohexylcarbonyloxy group.

The aryl group of R₁ to R₉, and Rx, which may have a substituent, is preferably an aryl group having 6 to 14 carbon atoms, and examples thereof include a phenyl group, and a naphthyl group.

The aryloxy group of R₃ to R₉, which may have a substituent, is preferably an aryloxy group having 6 to 14 carbon atoms, and examples thereof include a phenyloxy group, and naphthyloxy group.

The aryloxycarbonyl group of R₃ to R₉, and Rx, which may have a substituent, is preferably an aryloxycarbonyl group having 7 to 15 carbon atoms, and examples thereof include a phenyloxycarbonyl group, and a naphthyloxycarbonyl group.

The arylcarbonyloxy group of R₃ to R₉, which may have a substituent, is preferably an arylcarbonyloxy group having 7 to 15 carbon atoms, and examples thereof include a phenylcarbonyloxy group, and a naphthylcarbonyloxy group.

The arylcarbonyl group of Rx, which may have a substituent, is preferably an arylcarbonyl group having 7 to 15 carbon atoms, and examples thereof include a phenylcarbonyl group, and a naphthylcarbonyl group.

Examples of the substituent that the cycloalkyl group of R₁ to R₉, and Rx, the acyl group of R₃ to R₉, and Rx, the alkoxy group of R₃ to R₉, the alkoxycarbonyl group of R₃ to R₉, the alkylcarbonyloxy group of R₃ to R₉, the aryl group of R₁ to R₉, and Rx, the aryloxy group of R₃ to R₉, the aryloxycarbonyl group of R₃ to R₉, and Rx, the arylcarbonyloxy group of R₃ to R₉, and the arylcarbonyl group of Rx may further have include an alkyl group (linear, branched, or cyclic, and preferably having 1 to 12 carbon atoms), an aryl group (preferably having 6 to 14 carbon atoms), a halogen atom such as a nitro group or a fluorine atom, a carboxyl group, a hydroxyl group, an amino group, a cyano group, an alkoxy group (preferably having 1 to 15 carbon atoms), a cycloalkyl group (preferably having 3 to 15 carbon atoms), and an acyl group (preferably having 2 to 12 carbon atoms).

The ring structure which may be formed by combining R₁ and R₂ with each other includes a 5- or 6-membered ring formed by divalent R₁ and R₂ (for example, an ethylene group, a propylene group, and a 1,2-cyclohexylene group) together with the sulfur atom in formula (I), and a 5-membered ring (that is, a tetrahydrothiophene ring) is particularly preferred. From the viewpoint of decomposition efficiency of acid anion generated, it is preferred that R₁ and R₂ do not combine with each other to form a ring.

The ring structure which may be formed by combining two or more of R₆ to R₉, R₃ and R₉, R₄ and R₅, R₅ and Rx, and R₆ and Rx with each other includes preferably a 5- or 6-membered ring, and a 6-membered ring is particularly preferred.

R₁ and R₂ are particularly preferably an alkyl group or an aryl group.

Particularly preferred examples of R₃ to R₉ include an alkyl group which may have a substituent, or a hydrogen atom. When the composition of the present invention is used for ArF resist, a hydrogen atom is particularly preferred from the viewpoint of absorption intensity at 193 nm.

Rx is particularly preferably an alkyl group or an acyl group.

Xf is a fluorine atom, or an alkyl group substituted with at least one fluorine atom, and the alkyl group in the alkyl group substituted with a fluorine atom preferably contains 1 to 10 carbon atoms, and more preferably 1 to 4 carbon atoms. Further, the alkyl group substituted with a fluorine atom is preferably a perfluoroalkyl group.

Xf is preferably a fluorine atom or a perfluoroalkyl group having 1 to 4 carbon atoms. Specific examples thereof include a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and

CH₂CH₂C₄F₉. Among these, a fluorine atom or CF₃ are preferred. In particular, both Xf's are preferably a fluorine atom.

R₁₀ and R₁₁ represent a hydrogen atom, a fluorine atom, or an alkyl group, and the alkyl group may have a substituent (preferably, a fluorine atom) and preferably contains 1 to 4 carbon atoms. More preferred is a perfluoroalkyl group having 1 to 4 carbon atoms. Specific examples of the alkyl group having a substituent for R₁₀ and R₁₁ include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉. Among these, CF₃ is preferred.

L represents a divalent linking group, and examples thereof include —COO—, —COO—, —CO—, —O—, —S—, —SO—, —SO₂—, —N(Ri)— (wherein Ri represents a hydrogen atom or alkyl), an alkylene group, a cycloalkylene group, an alkenylene group and a divalent linking group formed by connecting a plurality of these members. L is preferably —COO—, —COO—, —CO—, —SO₂—, —CON(Ri)—, —SO₂N(Ri)—, —CON(Ri)-alkylene group-, —OCO-alkylene group- or —COO-alkylene group-, and more preferably —COO—, —COO-alkylene group-, —COO—, —OCO-alkylene group-, —SO₂—, —CON(Ri)— or —SO₂N(Ri)—. When a plurality of L's are present, each L may be the same as or different from every other L.

Specific examples and preferred examples of the alkyl group for R₁ are the same as those described for R₁ to R₉, and Rx.

The cyclic organic group of A is not particularly limited as long as it has a cyclic structure. The cyclic organic group includes an alicyclic group, an aryl group, a heterocyclic group (including one having or having not aromaticity, for example, a tetrahydropyran ring, and a lactone ring structure), and the like.

The alicyclic group may be monocyclic or polycyclic and preferably includes monocyclic cycloalkyl groups such as a cyclopentyl group, a cyclohexyl group and a cyclooctyl group, and polycyclic cycloalkyl groups such as a norbornyl group, a norbornenyl group, a tricyclodecanyl group (for example, a tricyclo[5.2.1.0(2,6)]decanyl group), a tetracyclodecanyl group, a tetracyclododecanyl group, and an adamantyl group. Among these, an alicyclic group having a bulky structure containing 7 or more carbon atoms, such as a norbornyl group, a tricyclodecanyl group, a tetracyclodecanyl group, a tetracyclododecanyl group, or an adamantyl group, is preferred since diffusion of counter anions into a film during a post-exposure baking (PEB) step is inhibited and exposure latitude is improved.

Examples of the aryl group include a benzene ring, a naphthalene ring, a phenanthrene ring, and an anthracene ring. Among these, naphthalene with low absorbance is preferred from the viewpoint of absorbance at 193 nm.

Examples of the heterocyclic group include heterocycles containing an oxygen atom, a sulfur atom or a nitrogen atom in the ring, such as a furan ring, a thiophene ring, a benzofuran ring, a benzothiophene ring, a dibenzofuran ring, a dibenzothiophene ring, a pyridine ring, a piperidine ring, a decahydroquinoline ring, and a decahydroisoquinoline ring. Among these, a furan ring, a thiophene ring, a pyridine ring, a piperidine ring, a decahydroquinoline ring, or a decahydroisoquinoline ring is preferred. Further, a ring having a bulky structure containing 7 or more carbon atoms is preferred since diffusion of counter anions into a film during a post-exposure baking (PEB) step is inhibited and exposure latitude is improved.

The cyclic organic group may have a substituent, and examples of the substituent include an alkyl group (linear, branched or cyclic, and preferably having 1 to 12 carbon atoms), an aryl group (preferably having 6 to 14 carbon atoms), a hydroxyl group, an alkoxy group, an ester group, an amido group, a urethane group, a ureido group, a thioether group, a sulfonamide group, and a sulfonic acid ester group.

Further, carbons constituting the cyclic organic group (carbons contributing to the formation of a ring) may be carbonyl carbons.

W represents ⁻O₃S—, RfSO₂—N⁻—SO₂—, Rf—CO—N⁻—SO₂— or Rf—SO₂—N⁻—CO—. Rf represents an alkyl group substituted with at least one fluorine atom. Specific examples and preferred examples of the alkyl group substituted with at least one fluorine atom as Rf are the same as those described for an alkyl group substituted with at least one fluorine atom for Xf.

x is preferably 1 to 8, more preferably 1 to 4, and particularly preferably 1. y is preferably 0 to 4, more preferably 0 or 1, and even more preferably 0. z is preferably 0 to 8, more preferably 0 to 4, and even more preferably 1.

With regard to a preferred embodiment of sulfonate anion structure of the compound (A), an example thereof represented by a hydrogen-added sulfonic acid structure may be the following formula (Ia). Xf, R₁₀, R₁₁, L, A, y, and z in formula (Ia) have the same meanings as those in formula (I), respectively.

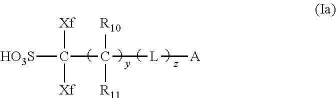

Preferred specific examples of (A) the compound represented by formula (I) and capable of generating an acid by actinic-rays or radiations are as follows, but the present invention is not limited thereto. In the following formulae, Me represents a methyl group, and Et represents an ethyl group.

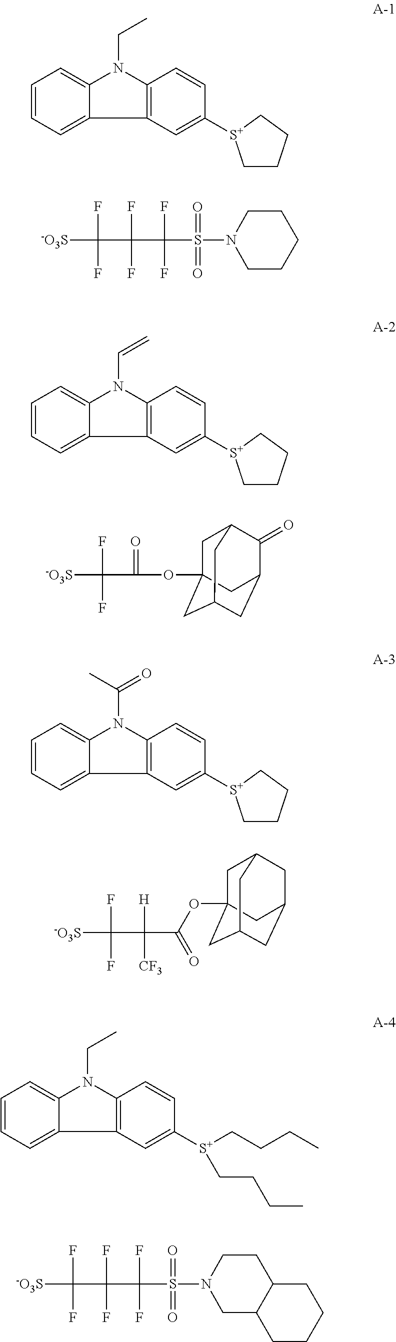

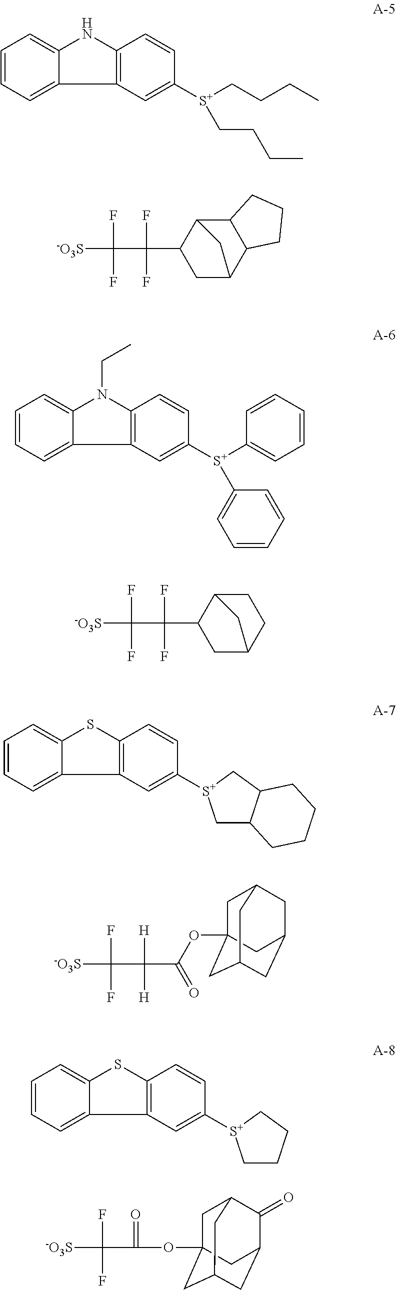

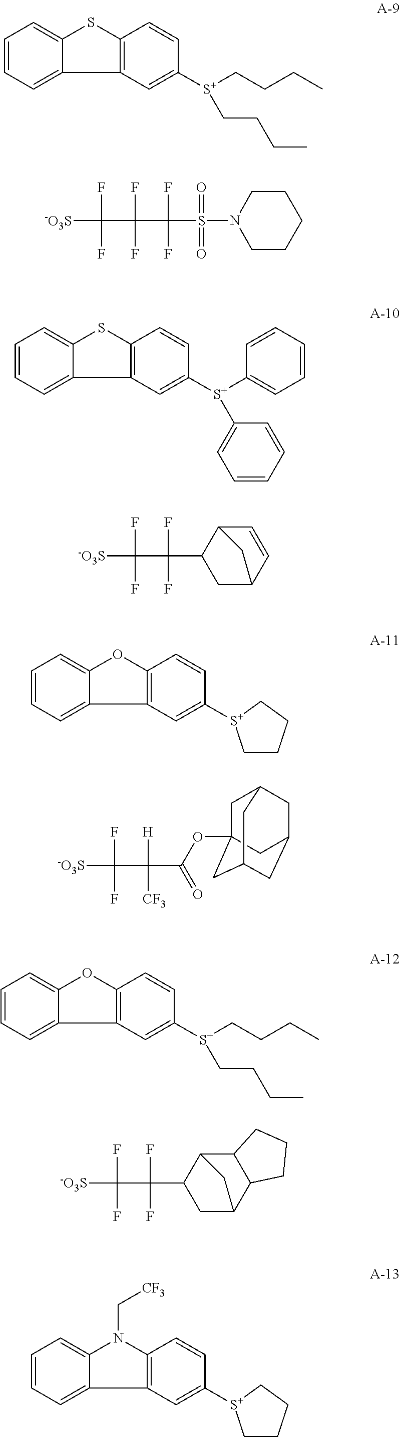

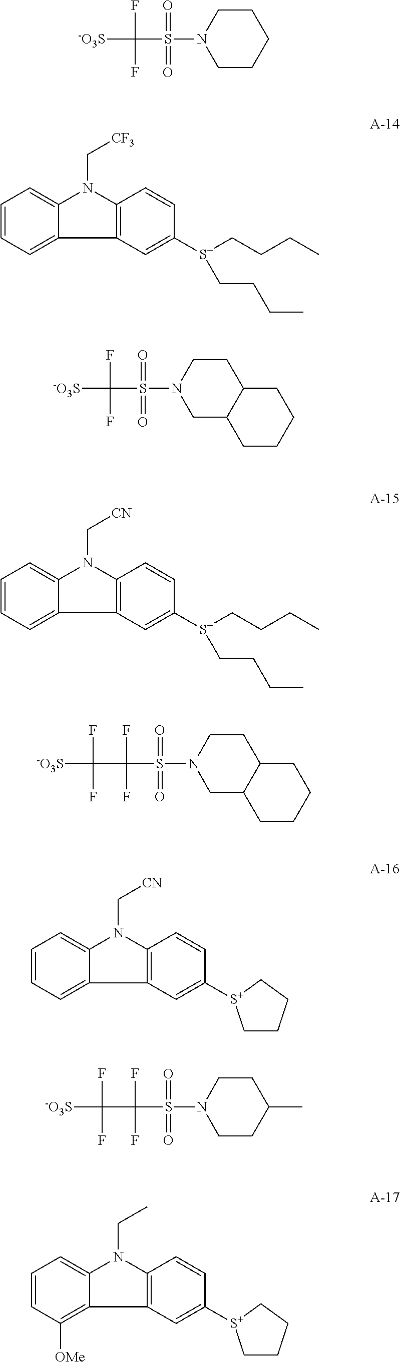

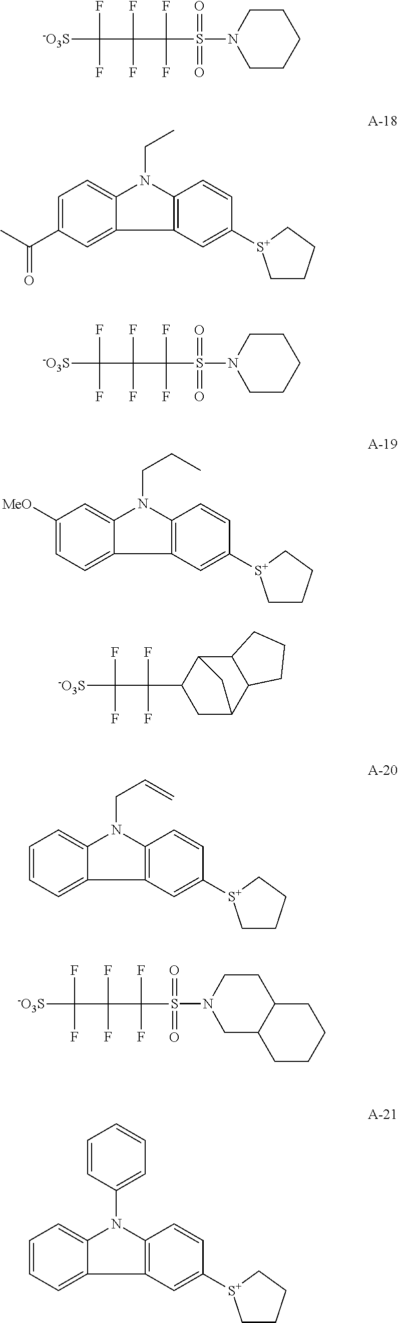

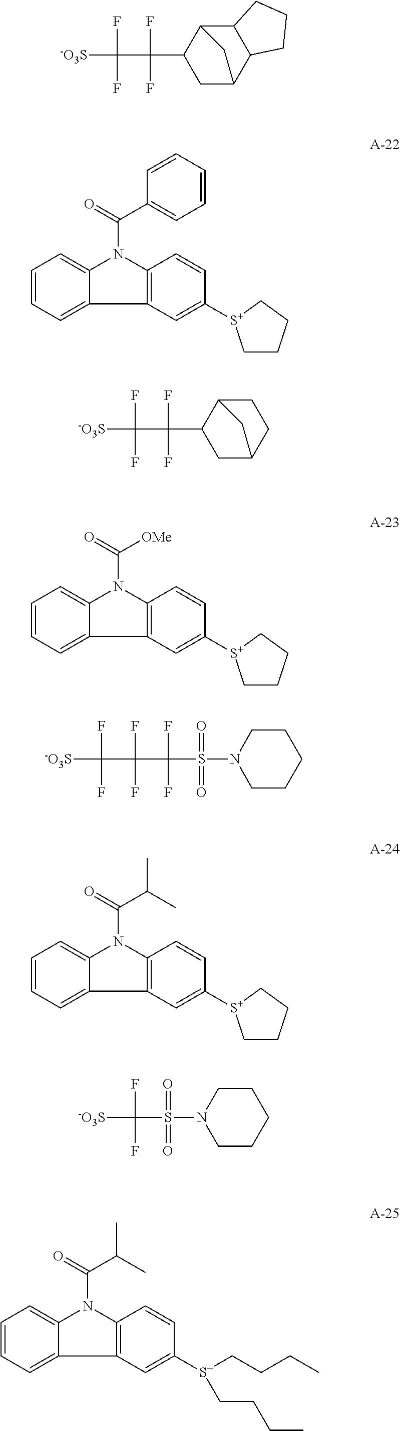

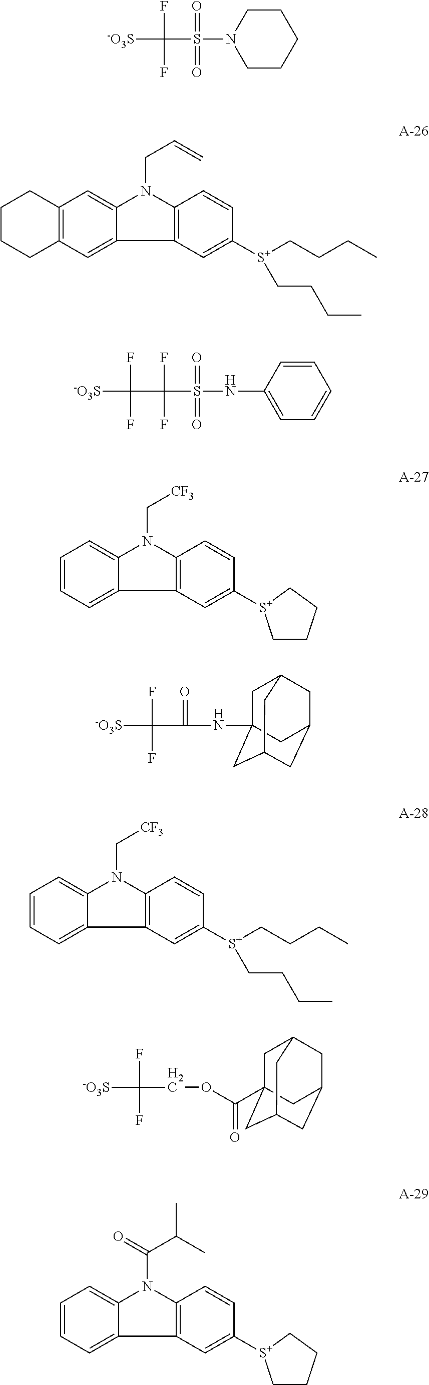

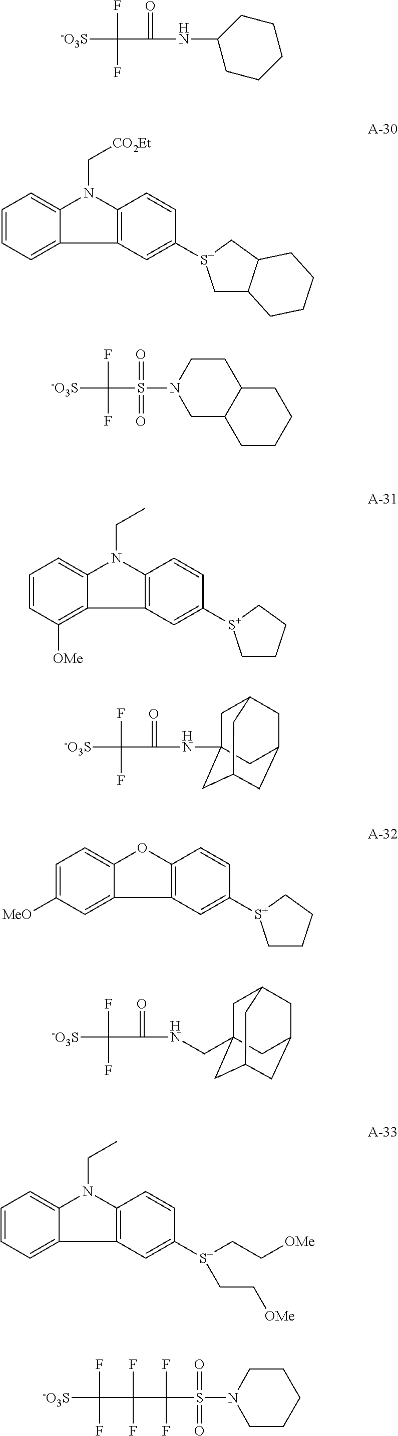

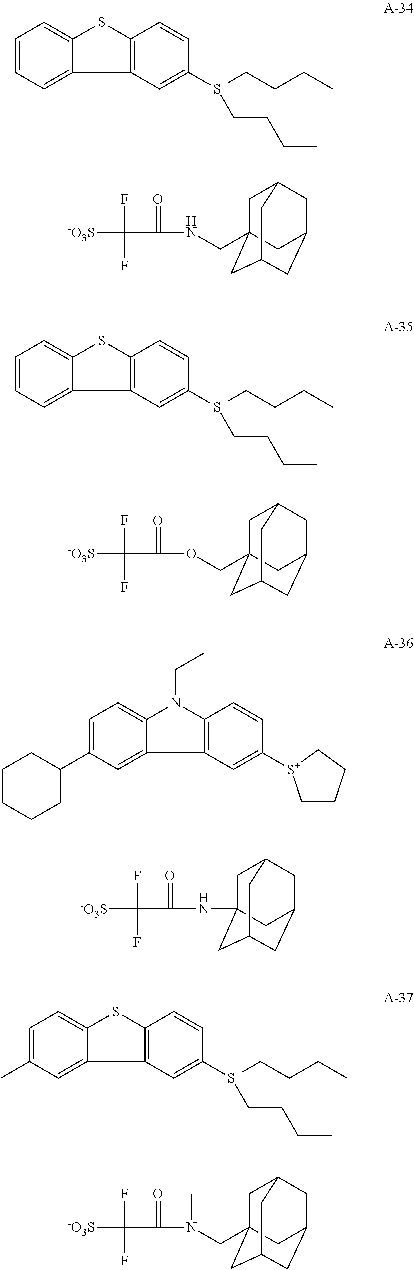

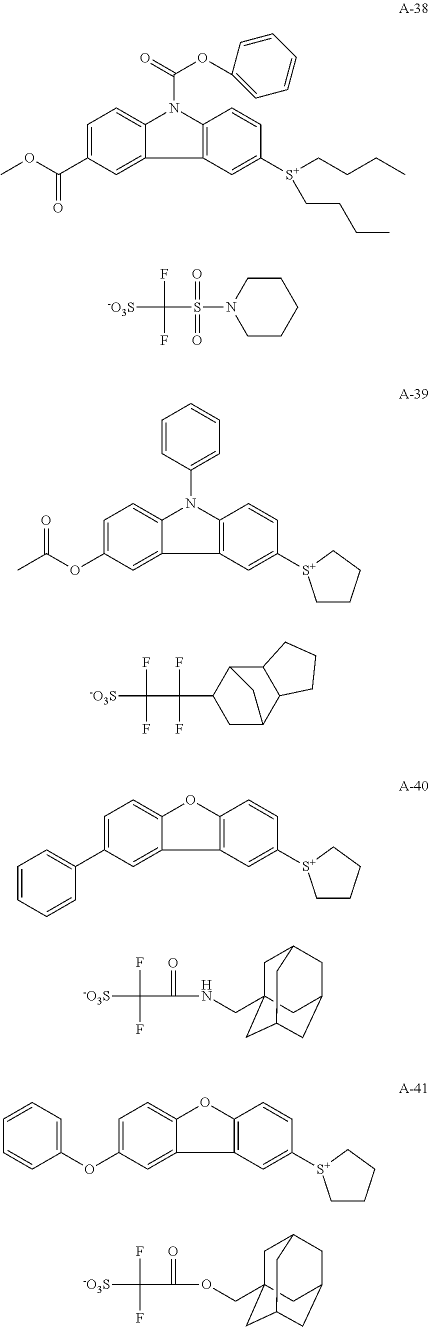

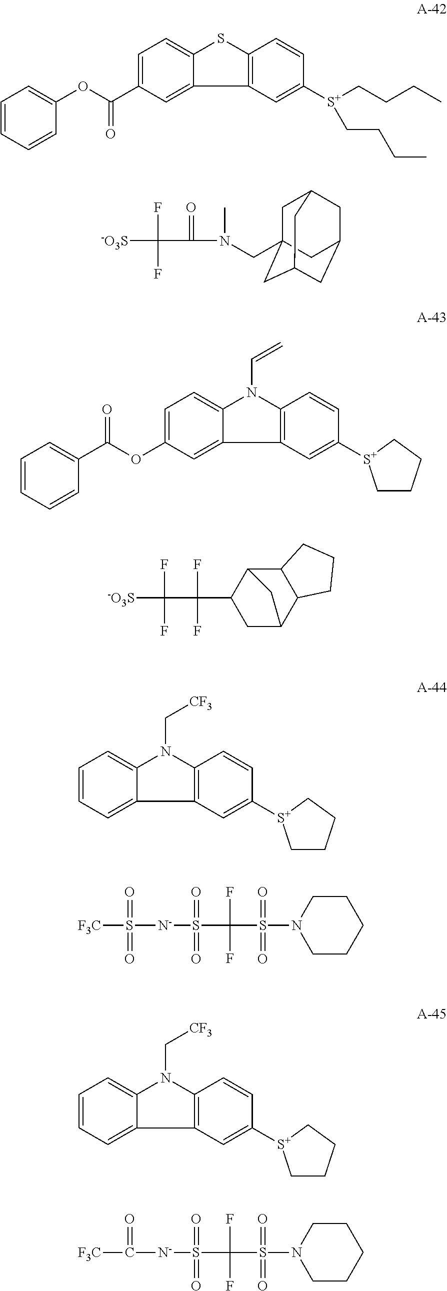

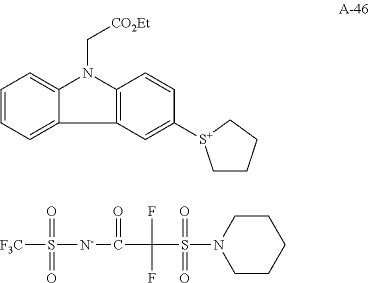

Of the compounds represented by formula (I), the sulfonate anion or a salt thereof (for example, an onium salt, or a metal salt) may be synthesized by using a general sulfonic acid esterification reaction or sulfonamidation reaction. For example, the compound may be obtained by a method of selectively reacting one sulfonyl halide moiety of a bis-sulfonyl halide compound with an amine, alcohol, amide compound or the like to form a sulfonamide bond, a sulfonic acid ester bond, or a sulfonimide bond and then hydrolyzing the other sulfonyl halide moiety, or a method of ring-opening a cyclic sulfonic anhydride by an amine, alcohol or amide compound.

Examples of the salt of sulfonic acid in formula (I) include a metal salt of sulfonic acid, and a sulfonic acid onium salt. Examples of the metal in the metal salt of sulfonic acid include Na, Li, and K. Examples of the onium cation in the sulfonic acid onium salt include an ammonium cation, a sulfonium cation, an iodonium cation, a phosphonium cation, and a diazonium cation.

The sulfonate anion or a salt thereof in formula (I) may be used in synthesis of the compound (A) represented by formula (I) and capable of generating a sulfonic acid upon irradiation of actinic-rays or radiations.

The compound (A) may be synthesized by salt exchange of the sulfonate anion in the formula (I) with an optically active onium salt, such as sulfonium salt corresponding to the sulfonium cation in the formula (I).

The content of the compound (A) in the composition of the present invention is preferably from 0.1 to 30 mass %, more preferably from 0.5 to 25 mass %, and more preferably from 5 to 20 mass %, based on the total solid content of the composition.

The compound (A) may be also used in combination with an acid generator (hereinafter, also referred to as a “compound (A′)”) other than the compound (A).

The compound (A′) is not particularly limited, but compounds represented by the following formulae (ZI′) (ZII′) and (ZIII′) are preferred.

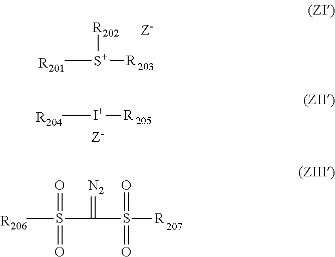

In formula (ZI′), R₂₀₁, R₂₀₂ and R₂₀₃ each independently represent an organic group.

The carbon number of the organic group as R₂₀₁, R₂₀₂ and R₂₀₃ is generally from 1 to 30, and preferably from 1 to 20.

Two members out of R₂₀₁ to R₂₀₃ may combine to form a ring structure, and the ring may contain an oxygen atom, a sulfur atom, an ester bond, an amide bond or a carbonyl group. Examples of the group formed by combining two members out of R₂₀₁ to R₂₀₃ include an alkylene group (e.g., a butylene group, or a pentylene group).

Examples of the organic groups represented by R₂₀₁, R₂₀₂ and R₂₀₃ include the corresponding groups in a compound (ZI′-1) which will be described hereinafter.

The compound (A′) may be a compound having a plurality of structures represented by formula (ZI′). For example, the compound (A′) may be a compound having a structure in which at least one of R₂₀₁ to R₂₀₃ of the compound represented by formula (ZI′) is connected to at least one of R₂₀₁ to R₂₀₃ of another compound represented by formula (ZI′) through a single bond or a linking group.

Z⁻ represents a non-nucleophilic anion (an anion that has significantly low ability to cause a nucleophilic reaction).

Examples of Z⁻ include a sulfonate anion (an aliphatic sulfonate anion, an aromatic sulfonate anion, a camphor-sulfonate anion, or the like), a carboxylate anion (an aliphatic carboxylate anion, an aromatic carboxylate anion, an aralkyl carboxylate anion, or the like), a sulfonylimide anion, a bis(alkylsulfonyl) imide anion, and a tris(alkylsulfonyl)methide anion.

The aliphatic moiety in the aliphatic sulfonate anion and the aliphatic carboxylate anion may be an alkyl group or a cycloalkyl group but is preferably a linear or branched alkyl group having 1 to 30 carbon atoms and a cycloalkyl group having 3 to 30 carbon atoms.

The aromatic group in the aromatic sulfonate anion and aromatic carboxylate anion is preferably an aryl group having 6 to 14 carbon atoms, and examples thereof include a phenyl group, a tolyl group, and a naphthyl group.

The foregoing alkyl group, cycloalkyl group and aryl group may have a substituent. Specific examples thereof include a halogen atom such as a nitro group or a fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms). As for the aryl group or ring structure in each group, examples of the substituent further include an alkyl group (preferably having 1 to 15 carbon atoms).

The aralkyl group in the aralkyl carboxylate anion is preferably an aralkyl group having 7 to 12 carbon atoms, and examples thereof include a benzyl group, a phenethyl group, a naphthylmethyl group, a naphthylethyl group, and a naphthylbutyl group.

As to the sulfonylimide anion, a saccharin anion can be given as an example.

The alkyl group in the bis(alkylsulfonyl)imide anion and the tris(alkylsulfonyl)methide anion is preferably an alkyl group having 1 to 5 carbon atoms. Examples of the substituent of such an alkyl group include a halogen atom, and an alkyl group, an alkoxy group, an alkylthio group, an alkyloxysulfonyl group, an aryloxysulfonyl group and a cycloalkylaryloxysulfonyl group each substituted with a halogen atom. A fluorine atom, or an alkyl group substituted with a fluorine atom is preferred.

Other examples of Z⁻ include phosphorus fluoride (for example, PF₆), boron fluoride (for example, BF₄⁻) and antimony fluoride (for example, SbF₆⁻).

The non-nucleophilic anion of Z is preferably an aliphatic sulfonate anion substituted with a fluorine atom at least at the α-position of sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom, more preferably a perfluoroaliphatic sulfonate anion (even more preferably having 4 to 8 carbon atoms) or a benzenesulfonate anion having a fluorine atom, still more preferably a nonafluorobutanesulfonate anion, a perfluorooctanesulfonate anion, a pentafluorobenzenesulfonate anion or a 3,5-bis(trifluoromethyl)benzenesulfonate anion.

From the viewpoint of acid strength, a pKa of the generated acid is preferably −1 or less for the purpose of increasing sensitivity.

As the component (ZI′), a compound (ZI′-1) described below is more preferred.

The compound (ZI′-1) is an arylsulfonium compound where at least one of R₂₀₁ to R₂₀₃ of formula (ZI′) is an aryl group, that is, a compound having an arylsulfonium as the cation.

In the arylsulfonium compound, all of R₂₀₁ to R₂₀₃ may be an aryl group or a part of R₂₀₁ to R₂₀₃ may be an aryl group with the remaining being an alkyl group or a cycloalkyl group. All of R₂₀₁ to R₂₀₃ are preferably an aryl group.

Examples of the arylsulfonium compound include a triarylsulfonium compound, a diarylalkylsulfonium compound, an aryldialkylsulfonium compound, a diarylcycloalkylsulfonium compound and an aryldicycloalkylsulfonium compound. A triarylsulfonium compound is preferred.

The aryl group in the arylsulfonium compound is preferably a phenyl group or a naphthyl group, and more preferably a phenyl group. The aryl group may be an aryl group having a heterocyclic structure containing an oxygen atom, a nitrogen atom, a sulfur atom or the like. Examples of the heterocyclic structure include pyrrole, furan, thiophene, indole, benzofuran and benzothiophene residues. In the case where the arylsulfonium compound has two or more aryl groups, these two or more aryl groups may be the same or different.

The alkyl or cycloalkyl group which is present, if desired, in the arylsulfonium compound is preferably a linear or branched alkyl group having 1 to 15 carbon atoms or a cycloalkyl group having 3 to 15 carbon atoms, and examples thereof include a methyl group, an ethyl group, a propyl group, an n-butyl group, a sec-butyl group, a tert-butyl group, a cyclopropyl group, a cyclobutyl group and a cyclohexyl group.

The aryl group, alkyl group and cycloalkyl group of R₂₀₁ to R₂₀₃ may have, as the substituent, an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group or a phenylthio group. The substituent is preferably a linear or branched alkyl group having 1 to 12 carbon atoms, a cycloalkyl group having 3 to 12 carbon atoms, or a linear, branched or cyclic alkoxy group having 1 to 12 carbon atoms, and more preferably an alkyl group having 1 to 4 carbon atoms, or an alkoxy group having 1 to 4 carbon atoms. The substituent may be substituted on any one of three members R₂₀₁ to R₂₀₃ or may be substituted on all of these three members. In the case where R₂₀₁ to R₂₀₃ are an aryl group, the substituent is preferably substituted at the p-position of the aryl group.

Hereinafter, formulae (ZII′) and (ZIII′) will be described.

In formulae (ZII′) and (ZIII′), R₂₀₄ to R₂₀₇ each independently represent an aryl group, an alkyl group or a cycloalkyl group.

The aryl group, alkyl group and cycloalkyl group of R₂₀₄ to R₂₀₇ have the same meanings as the aryl group, alkyl group and cycloalkyl group of R₂₀₁ to R₂₀₃ in formula (ZI′-1), respectively.

The aryl group, alkyl group and cycloalkyl group of R₂₀₄ to R₂₀₇ which may have a substituent. These substituents are the same as those described for the aryl group, alkyl group and cycloalkyl group of R₂₀₁ to R₂₀₃ in formula (ZI′-1).

Z⁻ represents a non-nucleophilic anion, which is the same as the non-nucleophilic anion of Z⁻ described for formula (ZI′).

The acid generator (A′), which may be used in combination with the acid generator in accordance with the present invention, further includes compounds represented by the following formulae (ZIV′), (ZV′) and (ZVI′):

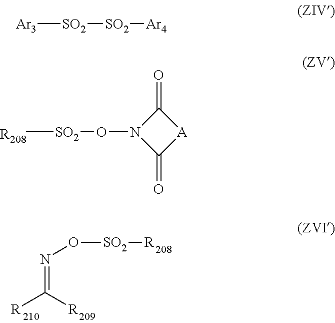

In formulae (ZIV′) to (ZVI′), Ar₃ and Ar₄ each independently represent an aryl group. R₂₀₈, R₂₀₉ and R₂₁₀ each independently represent an alkyl group, a cycloalkyl group or an aryl group.

A represents an alkylene group, an alkenylene group or an arylene group.

Specific examples of the aryl group of Ar₃, Ar₄, R₂₀₈, R₂₀₉ and R₂₁₀ are the same as specific examples of the aryl group of R₂₀₁, R₂₀₂ and R₂₀₃ in formula (ZI′-1).

Specific examples of the alkyl group and cycloalkyl group of R₂₀₈, R₂₀₉ and R₂₁₀ are the same as specific examples of the alkyl group and cycloalkyl group of R₂₀₁, R₂₀₂ and R₂₀₃ in formula (ZI′-1), respectively.

The alkylene group of A includes an alkylene group having 1 to 12 carbon atoms (e.g., a methylene group, an ethylene group, a propylene group, an isopropylene group, a butylene group, or an isobutylene group); the alkenylene group of A includes an alkenylene group having 2 to 12 carbon atoms (e.g., an ethenylene group, a propenylene group, or a butenylene group); and the arylene group of A includes an arylene group having 6 to 10 carbon atoms (e.g., a phenylene group, a tolylene group, or a naphthylene group).

Particularly preferred examples of the acid generator (A′), which may be used in combination with the acid generator of the present invention, are as follows.

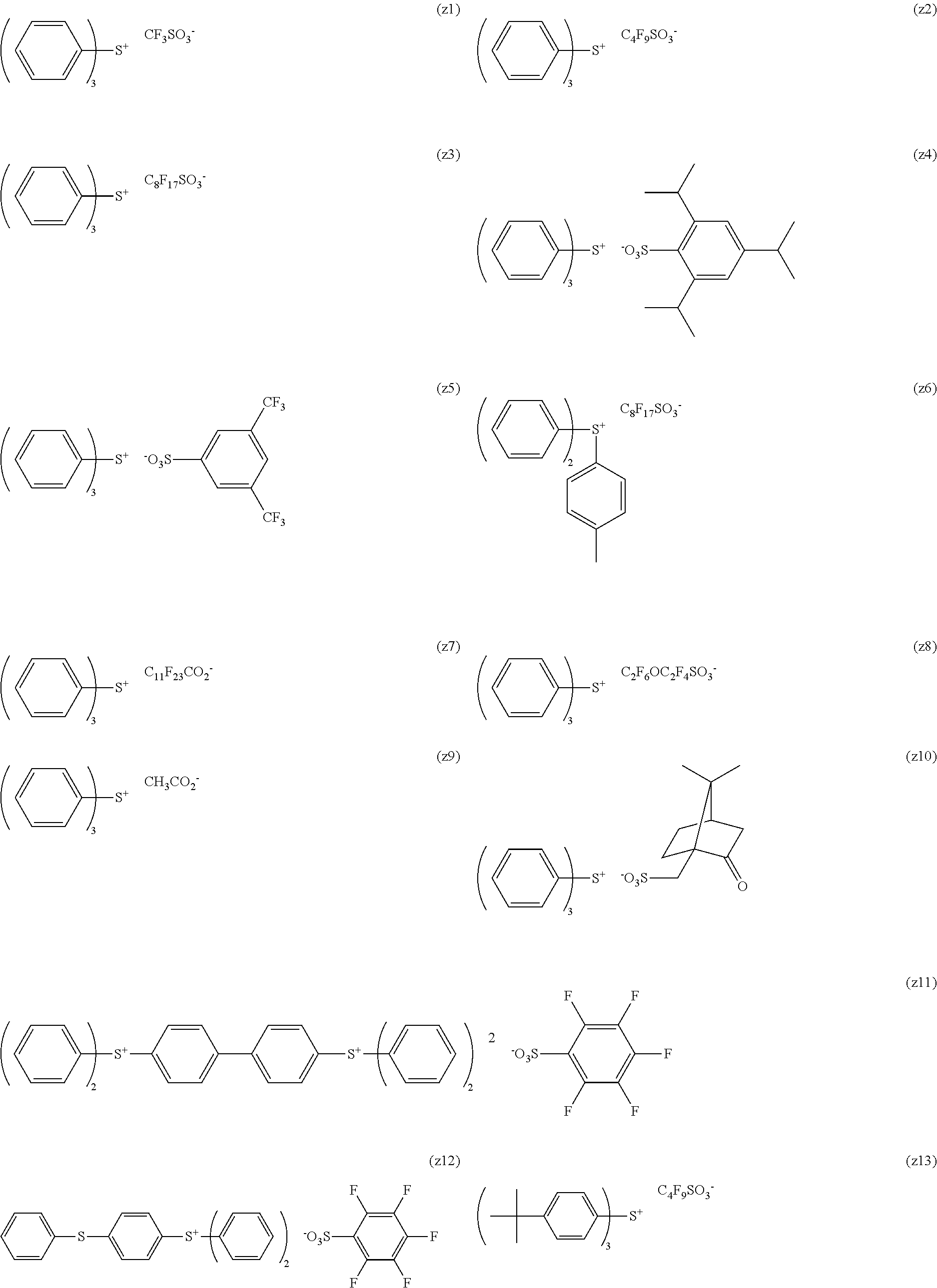

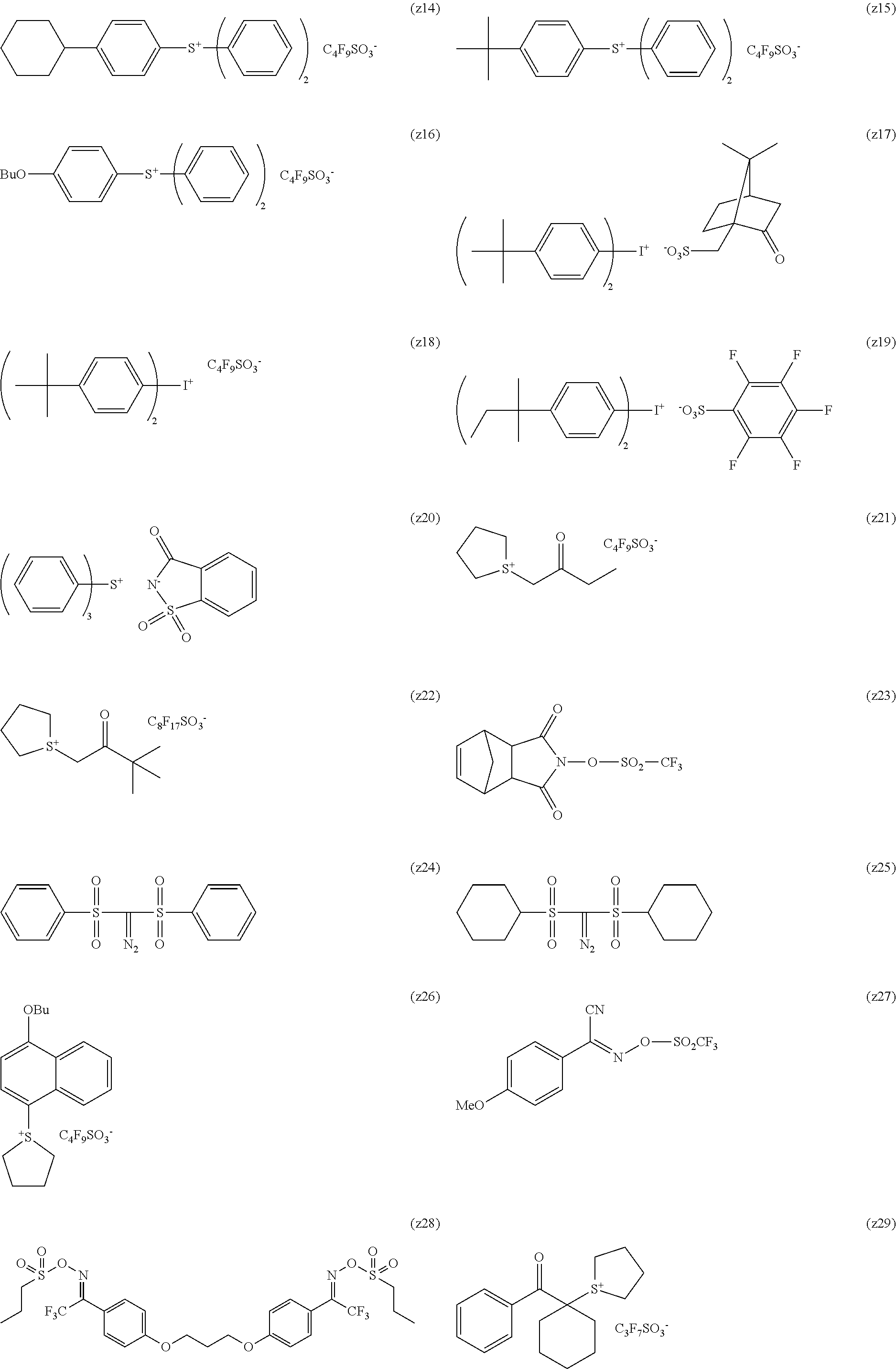

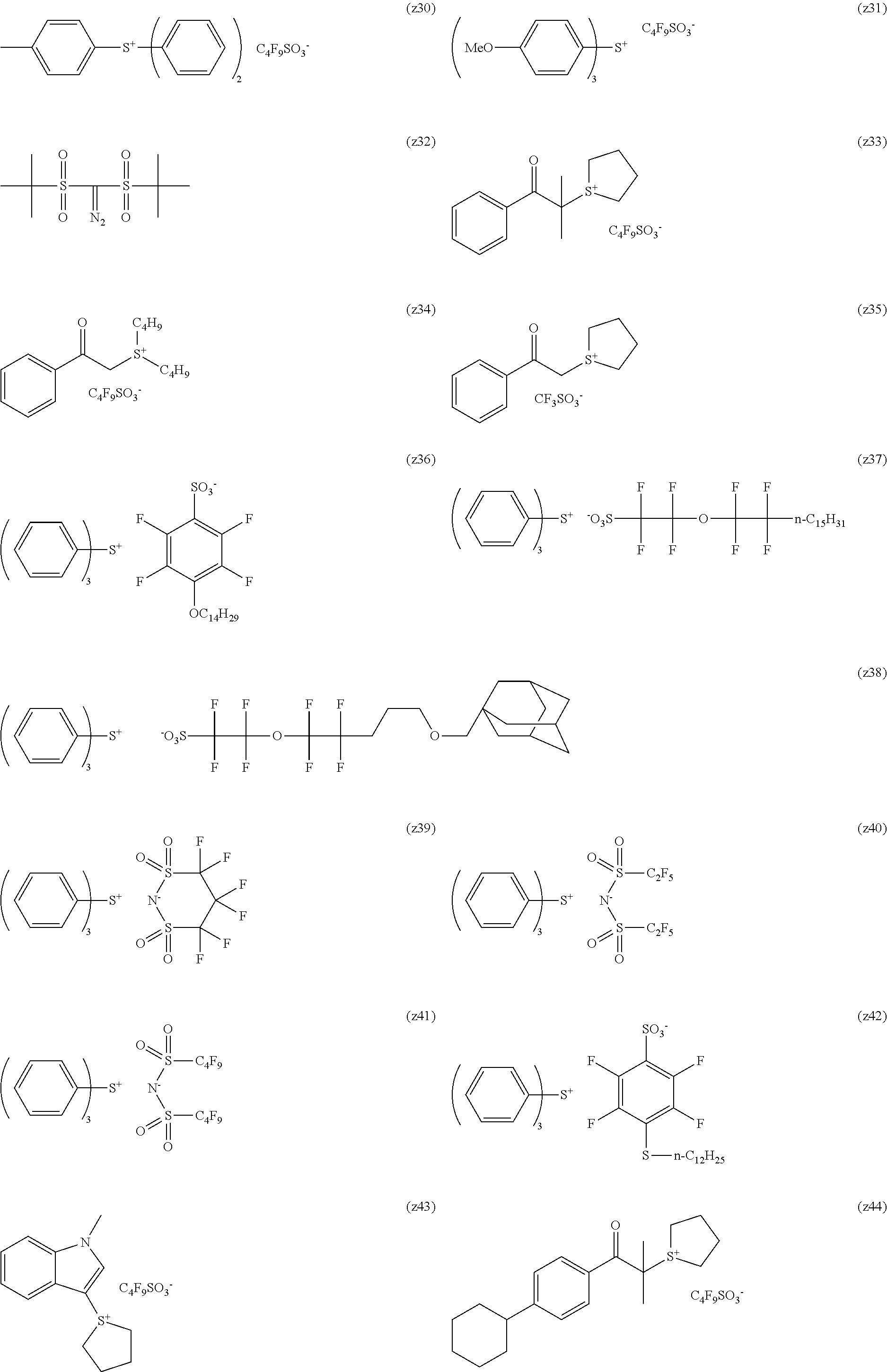

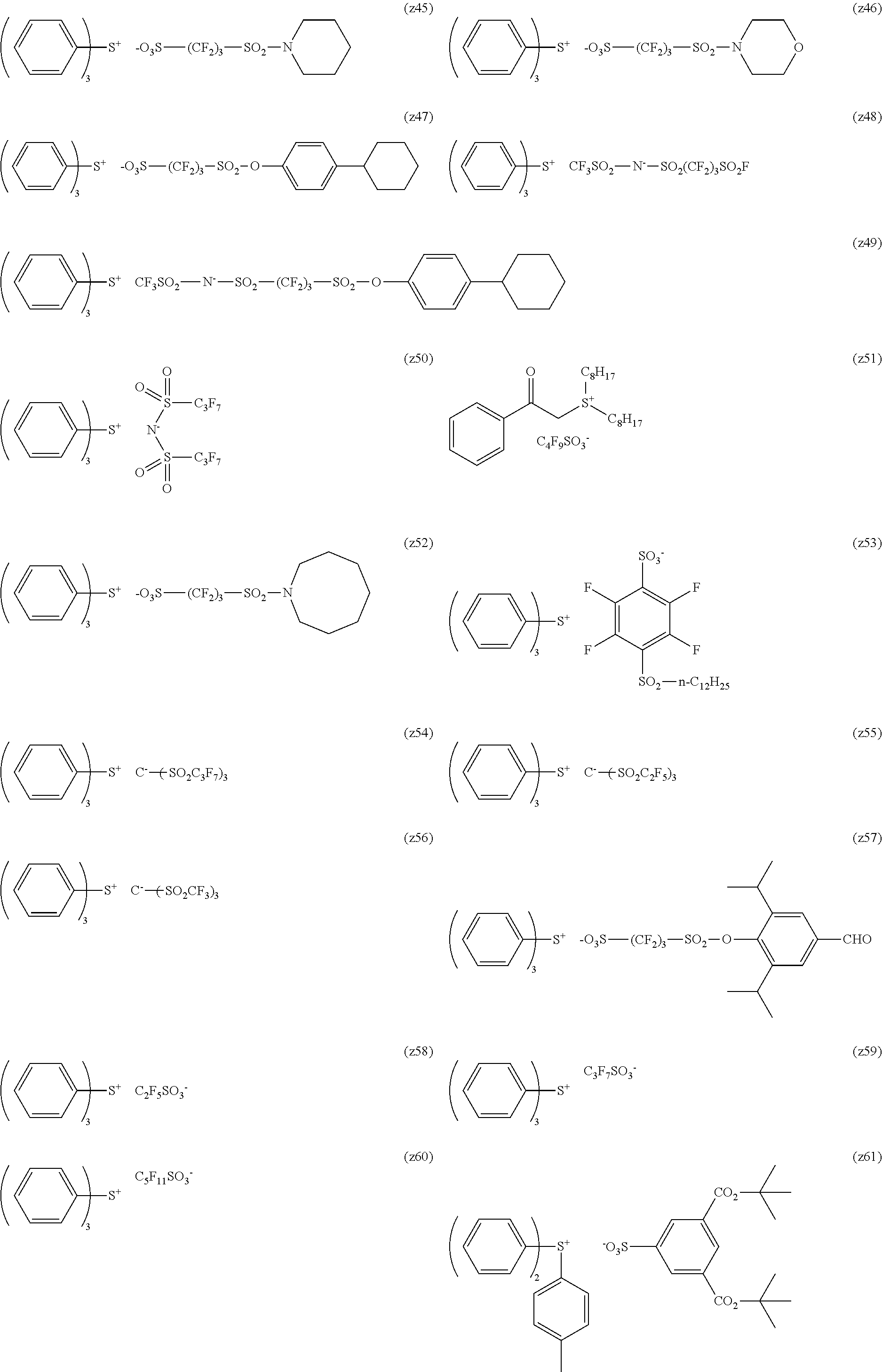

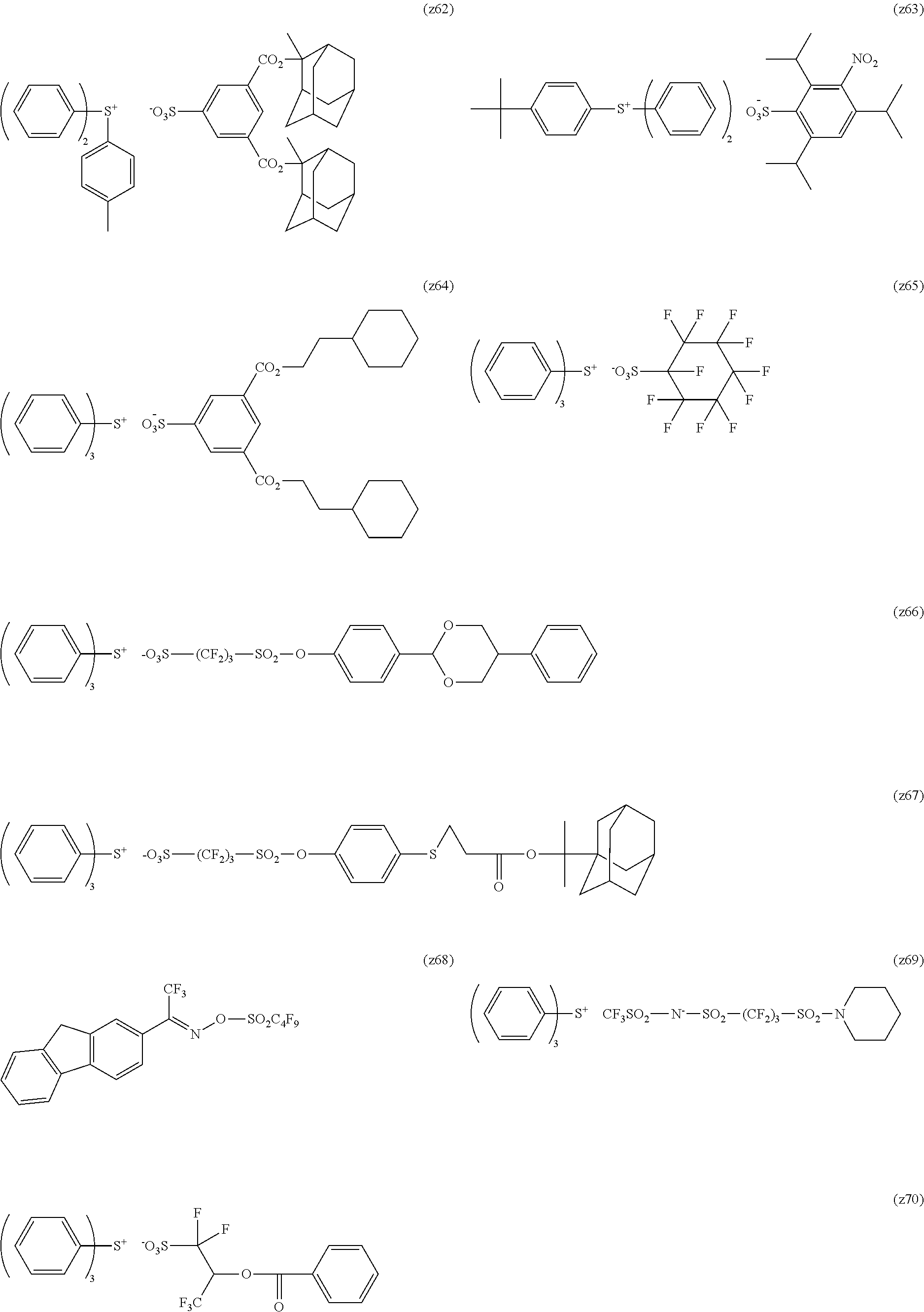

In the case where the composition of the present invention contains the compound (A′) as an acid generator, the content of the compound (A′) is preferably 50 mass % or less, more preferably from 1 to 40 mass %, and even more preferably from 2 to 30 mass %, based on the total amount of the acid generator (A) of the present invention.

[2] (B) Resin Capable of Increasing the Solubility in an Alkaline Developer by the Action of an Acid

The actinic-ray-sensitive or radiation-sensitive resin composition of the present invention contains a resin capable of increasing the solubility in an alkaline developer by the action of an acid (hereinafter, also referred to as “acid-decomposable resin” or “resin (B)”).

The acid-decomposable resin has a group capable of decomposing by the action of an acid to produce an alkali-soluble group (hereinafter, also referred to as “acid-decomposable group”), on either one or both of the main chain and the side chain of the resin.

The resin (B) is preferably insoluble or sparingly soluble in an alkaline developer. The acid-decomposable group preferably has a structure where an alkali-soluble group is protected by a group capable of decomposing and leaving by the action of an acid.

Examples of the alkali-soluble group include a phenolic hydroxyl group, a carboxyl group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group and a tris(alkylsulfonyl)methylene group.

The alkali-soluble group is preferably a carboxyl group, a fluorinated alcohol group (preferably a hexafluoroisopropanol group) or a sulfonic acid group.

The acid-decomposable group is preferably a group formed by substituting a group capable of leaving by the action of an acid for a hydrogen atom of the alkali-soluble group above.

Examples of the group capable of leaving by the action of an acid include —C(R₃₆)(R₃₇)(R₃₈), —C(R₃₆)(R₃₇)(OR₃₉) and —C(R₀₁)(R₀₂)(OR₃₉). In the formulae, R₃₆ to R₃₉ each independently represent an alkyl group, a cycloalkyl group, an aryl group, an aralkyl group or an alkenyl group. R₃₆ and R₃₇ may combine with each other to form a ring.

R₀₁ and R₀₂ each independently represent a hydrogen atom, an alkyl group, a cycloalkyl group, an aryl group, an aralkyl group or an alkenyl group.

The acid-decomposable group is preferably a cumyl ester group, an enol ester group, an acetal ester group, a tertiary alkyl ester group or the like, and more preferably a tertiary alkyl ester group.

The acid-decomposable group-containing repeating unit that the resin (B) may contain is preferably a repeating unit represented by the following formula (AI).

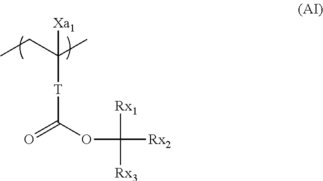

In formula (AI), Xa₁ represents a hydrogen atom, a methyl group which may have a substituent, or a group represented by —CH₂—R₉. R₉ represents a hydroxyl group or a monovalent organic group. Examples of the monovalent organic group include an alkyl group having 5 or less carbon atoms and an acyl group having 5 or less carbon atoms. Of these, an alkyl group having 3 or less carbon atoms is preferred, and a methyl group is more preferred. Xa₁ is preferably a hydrogen atom, a methyl group, a trifluoromethyl group or a hydroxymethyl group.

T represents a single bond or a divalent linking group. Rx₁ to Rx₃ each independently represent an alkyl group (linear or branched) or a cycloalkyl group (monocyclic or polycyclic).

Two members out of Rx₁ to Rx₃ may combine to form a cycloalkyl group (monocyclic or polycyclic).

Examples of the divalent linking group of T include an alkylene group, a —COO-Rt- group, and a —O-Rt- group. In the formulae, Rt represents an alkylene group or a cycloalkylene group.

T is preferably a single bond or a —COO-Rt- group. Rt is preferably an alkylene group having 1 to 5 carbon atoms, and more preferably a —CH₂— group, a —(CH₂)₂— group or a —(CH₂)₃-group.

The alkyl group of Rx₁ to Rx₃ is preferably an alkyl group having 1 to 4 carbon atoms, such as a methyl group, an ethyl group, an n-propyl group, an isopropyl group, an n-butyl group, an isobutyl group or a tert-butyl group.

The cycloalkyl group of Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group or an adamantyl group.

The cycloalkyl group formed by combining at least two members out of Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group or an adamantyl group. Above all, a monocyclic cycloalkyl group having 5 to 6 carbon atoms is particularly preferred.

An embodiment where Rx₁ is a methyl group or an ethyl group and Rx₂ and Rx₃ are combined to form the above-described cycloalkyl group is preferred.

Each of the groups above may have a substituent, and examples of the substituent include an alkyl group (having 1 to 4 carbon atoms), a halogen atom, a hydroxyl group, an alkoxy group (having 1 to 4 carbon atoms), a carboxyl group and an alkoxycarbonyl group (having 2 to 6 carbon atoms). The carbon number is preferably 8 or less.

The total content of the repeating unit having an acid-decomposable group is preferably from 20 to 70 mol %, and more preferably from 30 to 50 mol %, based on all repeating units in the resin.

Specific preferred examples of the repeating unit having an acid-decomposable group are illustrated below, but the present invention is not limited thereto.

In specific examples, each of Rx and Xa₁ represents a hydrogen atom, CH₃, CF₃ or CH₂OH, and each of Rxa and Rxb represents an alkyl group having 1 to 4 carbon atoms. Z represents a substituent containing a polar group, and when a plurality of Z's are present, each Z may be the same as or different from every other Z. p represents 0 or a positive integer. Specific examples and preferred examples of Z are the same as specific examples and preferred examples of R₁₀ in formula (II-1) described later.

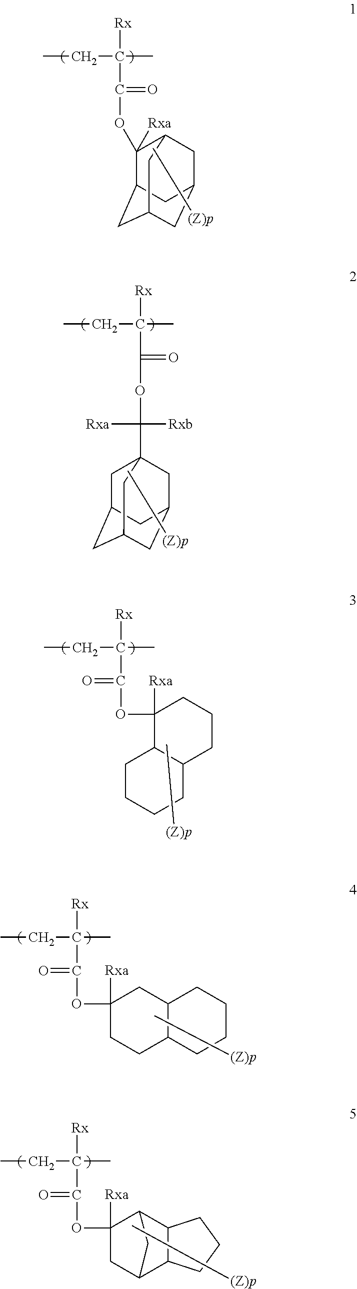

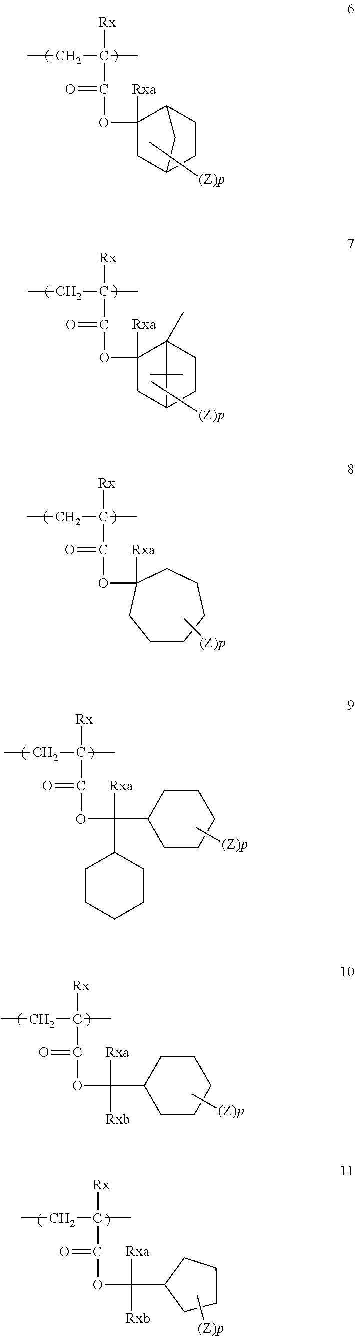

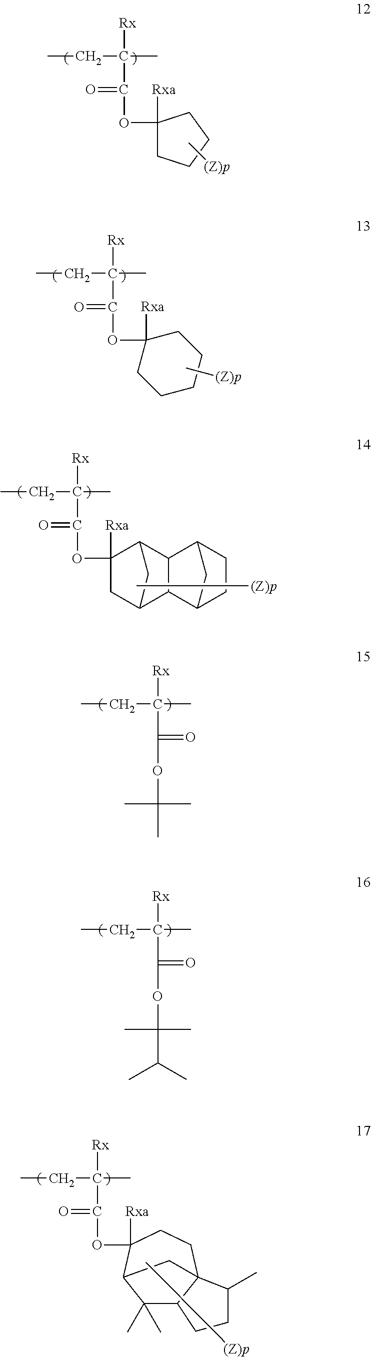

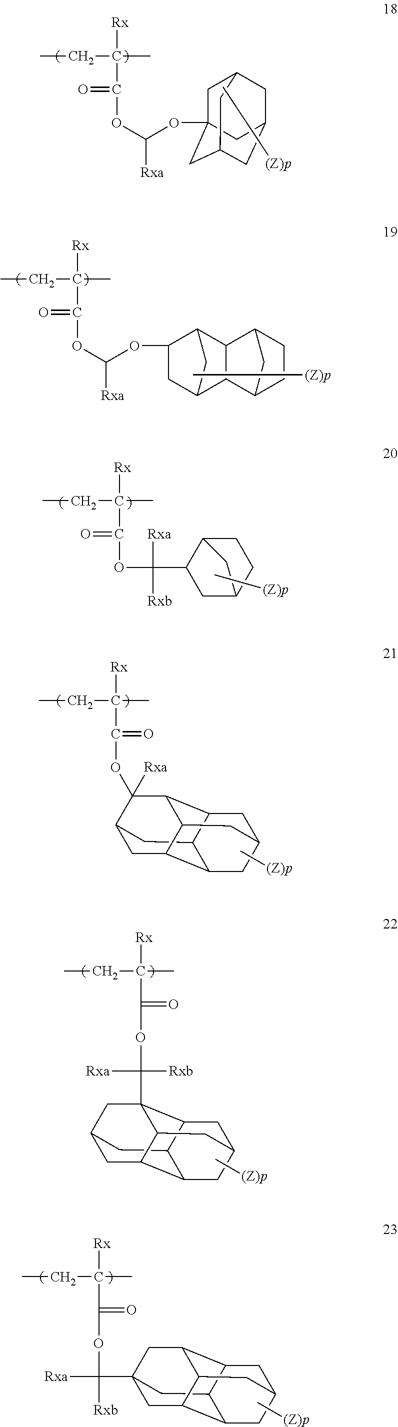

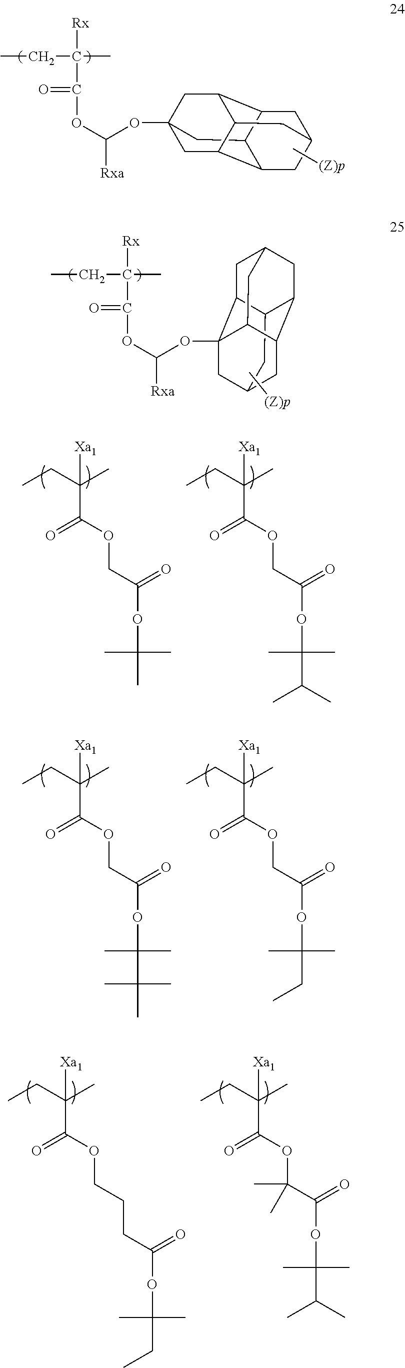

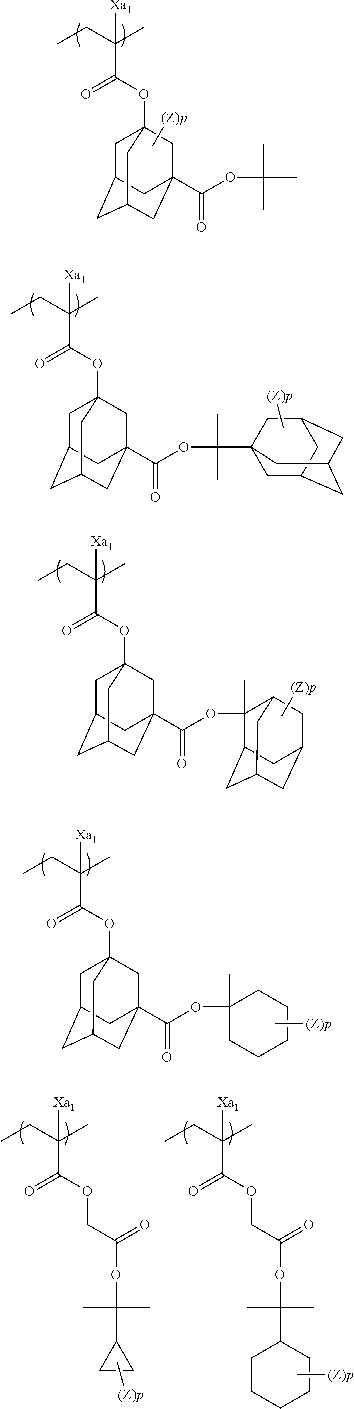

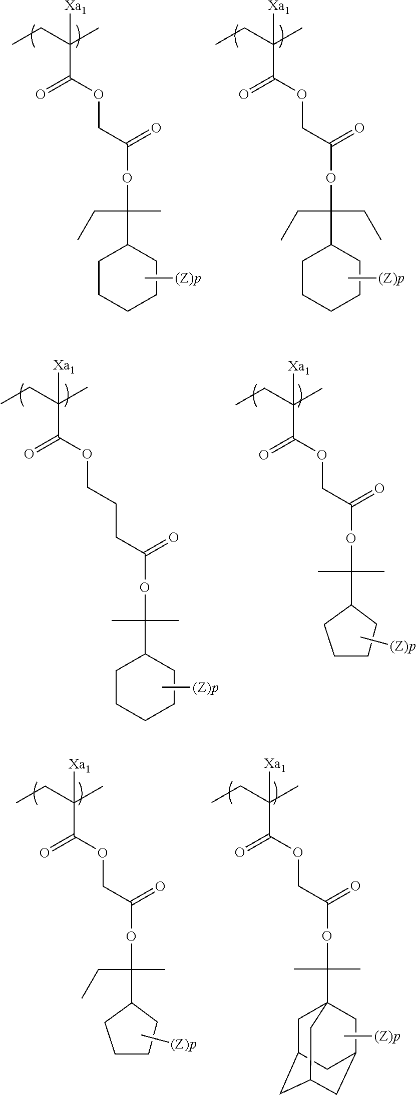

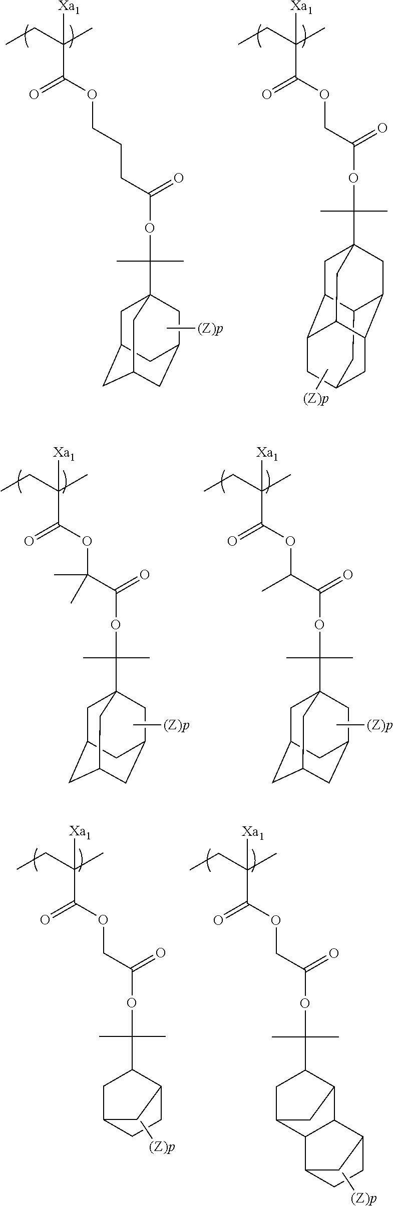

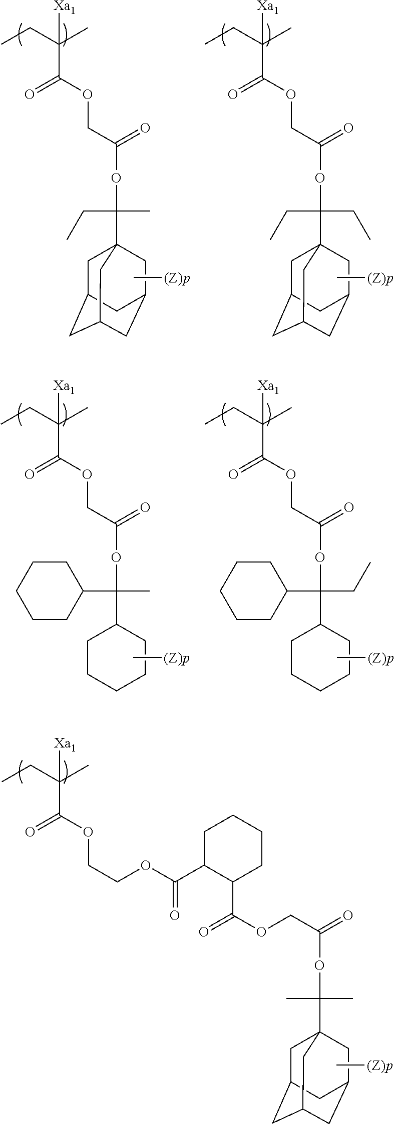

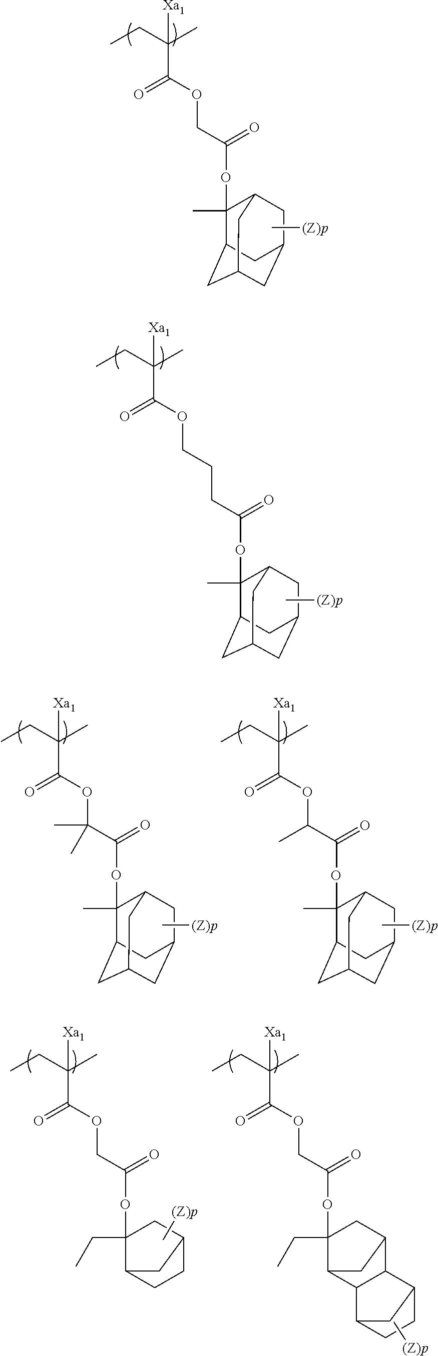

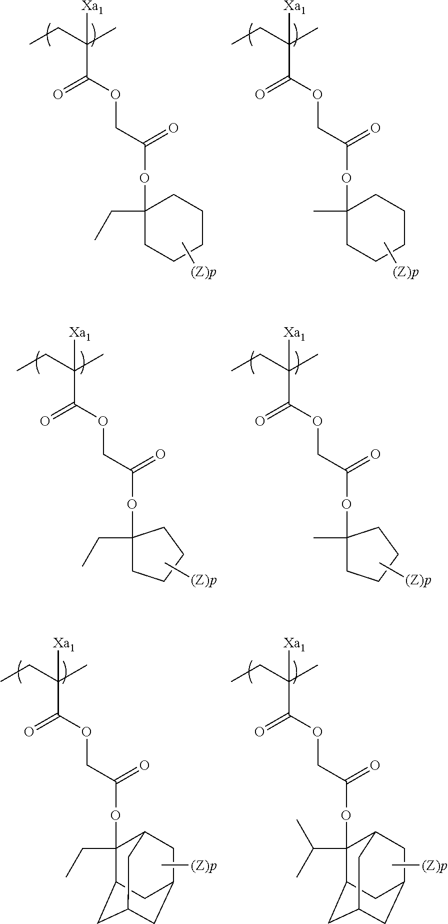

The resin (B) is more preferably a resin containing, as the repeating unit represented by formula (AI), at least either a repeating unit represented by formula (I) or a repeating unit represented by formula (II).

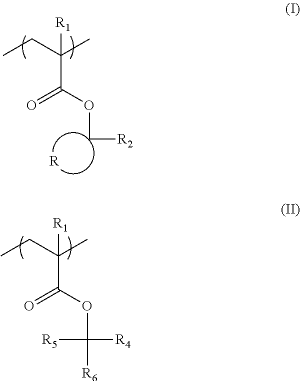

In formulae (I) and (II), R₁ and R₃ each independently represent a hydrogen atom, a methyl group which may have a substituent, or a group represented by —CH₂—R₉. R₉ represents a hydroxyl group or a monovalent organic group.

R₂, R₄, R₅ and R₆ each independently represent an alkyl group or a cycloalkyl group.

R represents an atomic group necessary for forming an alicyclic structure together with the carbon atom.

Each of R₁ and R₃ is preferably a hydrogen atom, a methyl group, a trifluoromethyl group or a hydroxymethyl group. Specific examples and preferred examples of the monovalent organic group in R₉ are the same as those described for R₉ in formula (AI).

The alkyl group in R₂ may be linear or branched and may have a substituent.

The cycloalkyl group in R₂ may be monocyclic or polycyclic and may have a substituent.

R₂ is preferably an alkyl group, more preferably an alkyl group having 1 to 10 carbon atoms, still more preferably an alkyl group having 1 to 5 carbon atoms, and examples thereof include a methyl group and an ethyl group.

R represents an atomic group necessary for forming an alicyclic structure together with the carbon atom. The alicyclic structure formed by R together with the carbon atom is preferably a monocyclic alicyclic structure, and the carbon number thereof is preferably from 3 to 7, more preferably 5 or 6.

R₃ is preferably a hydrogen atom, and more preferably a methyl group.

The alkyl group in R₄, R₅ and R₆ may be linear or branched and may have a substituent. The alkyl group is preferably an alkyl group having 1 to 4 carbon atoms, such as a methyl group, an ethyl group, an n-propyl group, an isopropyl group, an n-butyl group, an isobutyl group and a tert-butyl group.

The cycloalkyl group in R₄, R₅ and R₆ may be monocyclic or polycyclic and may have a substituent. The cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group or an adamantyl group.

The repeating unit represented by formula (I) includes, for example, a repeating unit represented by the following formula (1-a):

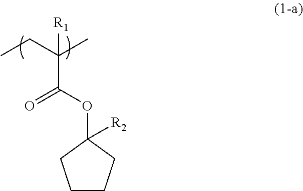

In the formula, R₁ and R₂ have the same meanings as those in formula (I).

The repeating unit represented by formula (II) is preferably a repeating unit represented by the following formula (II-1):

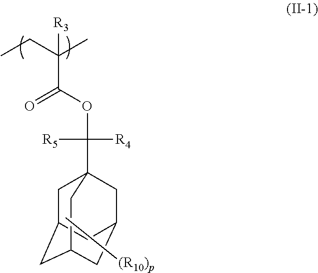

In formula (II-1), R₃ to R₅ have the same meanings as those in formula (II). R₁₀ represents a polar group-containing substituent. In the case where a plurality of R₁₀'s are present, these may be the same or different. Examples of the polar group-containing substituent include a hydroxyl group, a cyano group, an amino group, an alkylamide group, a sulfonamide group itself, and a linear or branched alkyl group or cycloalkyl group having at least one of the groups above. An alkyl group having a hydroxyl group is preferred, and a branched alkyl group having a hydroxyl group is more preferred. The branched alkyl group is particularly preferably an isopropyl group.

p represents an integer of 0 to 15. p is preferably an integer of 0 to 2, and more preferably 0 or 1.

The acid decomposable resin is more preferably a resin containing, as the repeating unit represented by formula (AI), at least either a repeating unit represented by formula (I) or a repeating unit represented by formula (II). In another embodiment, the acid decomposable resin is preferably a resin containing, as the repeating unit represented by formula (AI), at least two kinds of repeating units represented by formula (I).

As for the acid decomposable group-containing repeating unit of the resin (B), one kind of a repeating unit may be used, or two or more kinds of repeating units may be used in combination. In the case of using the repeating units in combination, preferred examples of the combination are illustrated below. In the formulae below, each R independently represents a hydrogen atom or a methyl group.

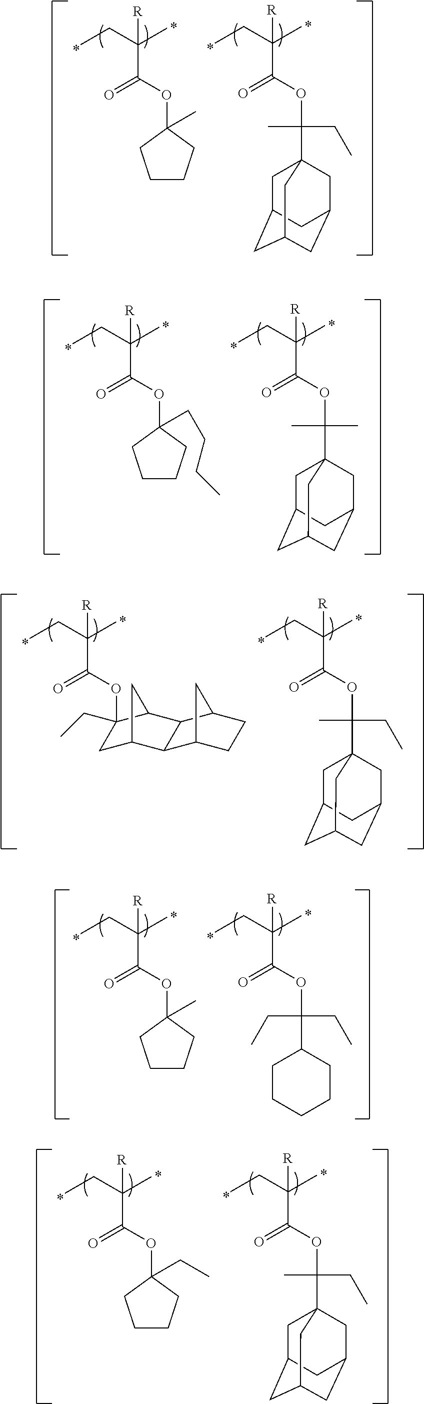

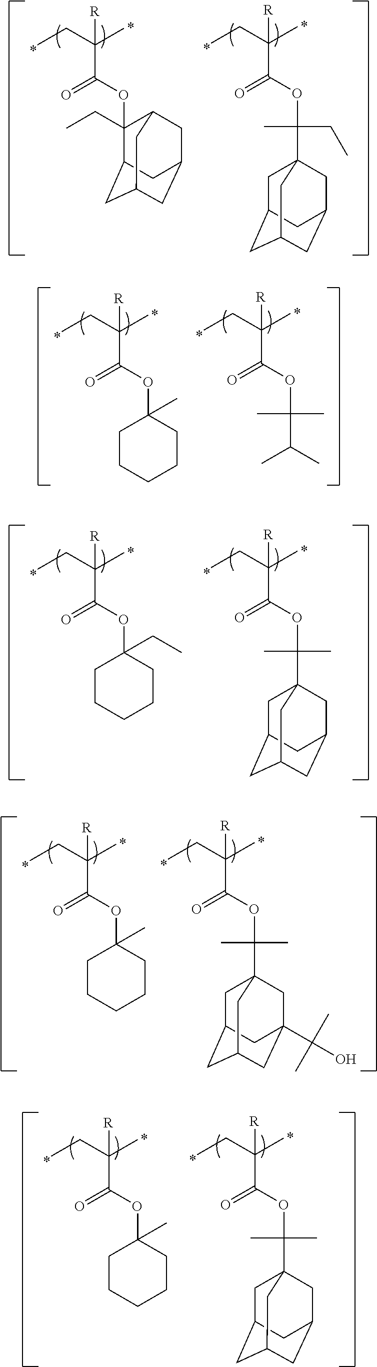

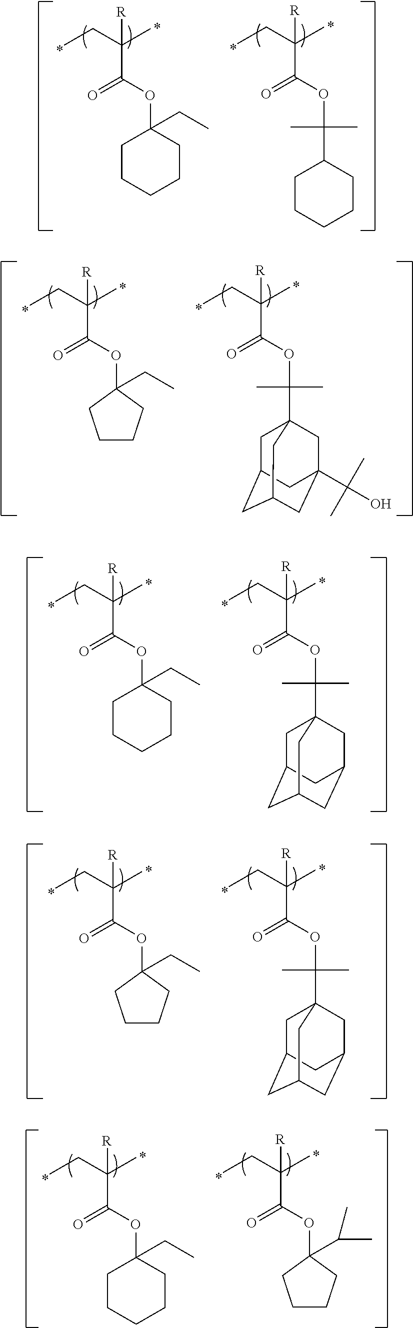

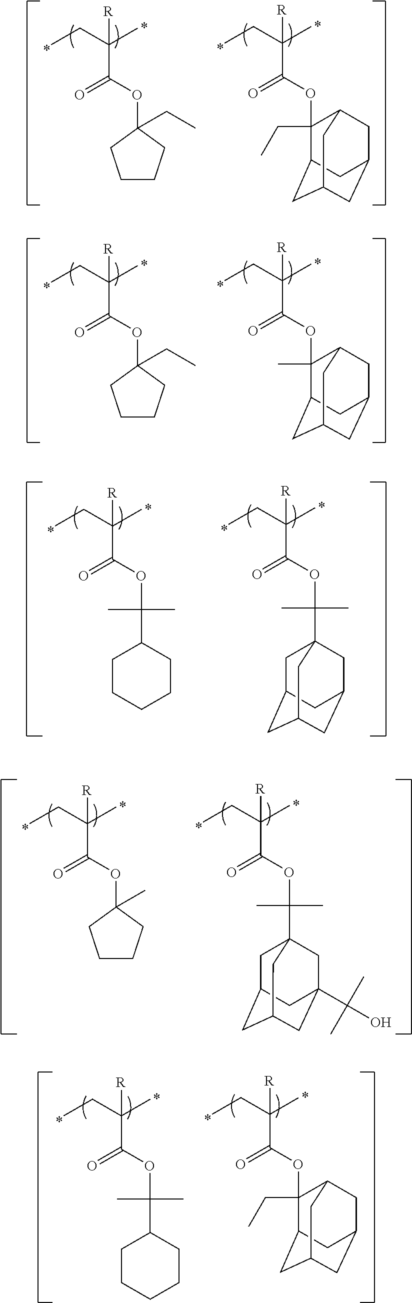

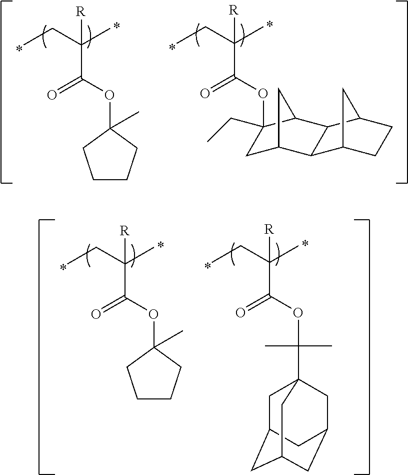

The resin (B) preferably contains a repeating unit having a lactone structure represented by the following formula (III).

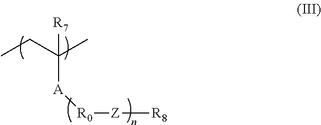

In formula (III), A represents an ester bond (a group represented by —COO—) or an amido bond (a group represented by —CONH—).

R₀ represents, when a plurality of R₀'s are present, each independently represents, an alkylene group, a cycloalkylene group or a combination thereof.

Z represents, when a plurality of Z's are present, each independently represents, a single bond, an ether bond, an ester bond, an amide bond, a urethane bond

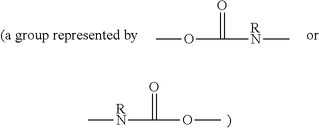

or a urea bond

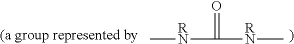

wherein each R independently represents a hydrogen atom, an alkyl group, a cycloalkyl group or an aryl group.

R₈ represents a monovalent organic group having a lactone structure.

n is the repetition number of the structure represented by —R₀—Z— and represents an integer of 1 to 5, preferably 1.

R₇ represents a hydrogen atom, a halogen atom or an alkyl group.

The alkylene group and cycloalkylene group of R₀ may have a substituent.

Z is preferably an ether bond or an ester bond, and more preferably an ester bond.

The alkyl group of R₇ is preferably an alkyl group having 1 to 4 carbon atoms, more preferably a methyl group or an ethyl group, and still more preferably a methyl group. The alkyl group in the alkylene group and cycloalkylene group of R₀ and in R₇ may be substituted, and examples of the substituent include a halogen atom such as a fluorine atom, a chlorine atom or a bromine atom, a mercapto group, a hydroxyl group, an alkoxy group such as a methoxy group, an ethoxy group, an isopropoxy group, a tert-butoxy group or a benzyloxy group, an acyl group such as an acetyl group or a propionyl group, and an acetoxy group. R₇ is preferably a hydrogen atom, a methyl group, a trifluoromethyl group or a hydroxymethyl group.

The chain alkylene group in R₀ is preferably a chain alkylene group having 1 to 10 carbon atoms, more preferably 1 to 5 carbon atoms, and examples thereof include a methylene group, an ethylene group and a propylene group. The cycloalkylene group is preferably a cycloalkylene group having 3 to 20 carbon atoms, and examples thereof include a cyclohexylene group, a cyclopentylene group, a norbornylene group and an adamantylene group. For bringing out the effects of the present invention, a chain alkylene group is more preferred, and a methylene group is still more preferred.

The monovalent organic group having a lactone structure. represented by R₈ is not limited as long as it has a lactone structure. Specific examples thereof include lactone structures represented by formulae (LC1-1) to (LC1-17) and among these, a structure represented by (LC1-4) is particularly preferred. Also, structures where n₂ in (LC1-1) to (LC1-17) is an integer of 2 or less are more preferred.

R₈ is preferably a monovalent organic group having an unsubstituted lactone structure or a monovalent organic group having a lactone structure containing a methyl group, a cyano group or an alkoxycarbonyl group as the substituent, and more preferably a monovalent organic group having a lactone structure containing a cyano group as the substituent (cyanolactone).

Specific examples of the repeating unit containing a group having a lactone structure represented by formula (III) are illustrated below, but the present invention is not limited thereto.

In specific examples, R represents a hydrogen atom, an alkyl group which may have a substituent, or a halogen atom, and preferably a hydrogen atom, a methyl group, a hydroxymethyl group or an acetyloxymethyl group.

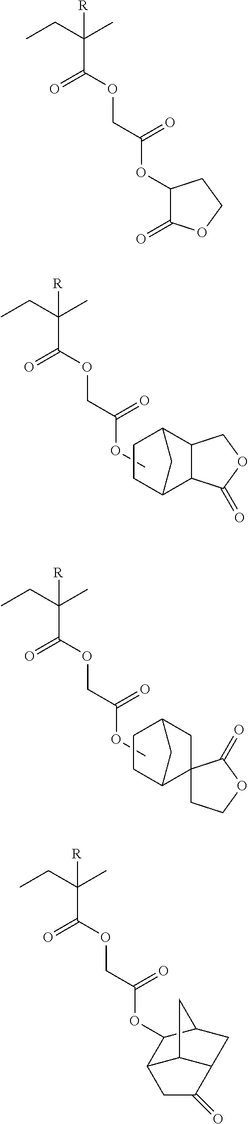

The repeating unit having a lactone structure is more preferably a repeating unit represented by the following formula (III-1):

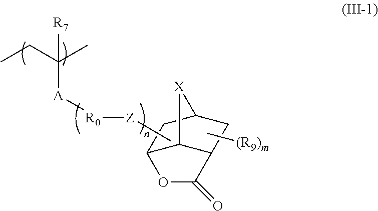

In formula (III-1), R₇, A, R₀, Z and n have the same meanings as in formula (III). R₉ represents, when a plurality of R₉'s are present, each independently represents, an alkyl group, a cycloalkyl group, an alkoxycarbonyl group, a cyano group, a hydroxyl group or an alkoxy group, and when a plurality of R₉'s are present, two members thereof may combine to form a ring.

X represents an alkylene group, an oxygen atom or a sulfur atom.

m is the number of substituents and represents an integer of 0 to 5. m is preferably 0 or 1.

The alkyl group of R₉ is preferably an alkyl group having 1 to 4 carbon atoms, more preferably a methyl group or an ethyl group, and most preferably a methyl group. Examples of the cycloalkyl group include a cyclopropyl group, a cyclobutyl group, a cyclopentyl group and a cyclohexyl group. Examples of the alkoxycarbonyl group include a methoxycarbonyl group, an ethoxycarbonyl group, an n-butoxycarbonyl group and a tert-butoxycarbonyl group. Examples of the alkoxy group include a methoxy group, an ethoxy group, a propoxy group, an isopropoxy group and a butoxy group. These groups may have a substituent, and the substituent includes a hydroxyl group, an alkoxy group such as a methoxy group or an ethoxy group, a cyano group, and a halogen atom such as fluorine atom. R₉ is preferably a methyl group, a cyano group or an alkoxycarbonyl group, and more preferably a cyano group. Examples of the alkylene group of X include a methylene group and an ethylene group. X is preferably an oxygen atom or a methylene group, and more preferably a methylene group.

When m is 1 or more, at least one R₉ is preferably substituted on the α- or β-position, more preferably the α-position, of the carbonyl group of lactone.

Specific examples of the repeating unit having a lactone structure-containing group represented by formula (III-1) are illustrated below, but the present invention is not limited thereto. In specific examples, R represents a hydrogen atom, an alkyl group which may have a substituent, or a halogen atom, and preferably a hydrogen atom, a methyl group, a hydroxymethyl group or an acetyloxymethyl group.

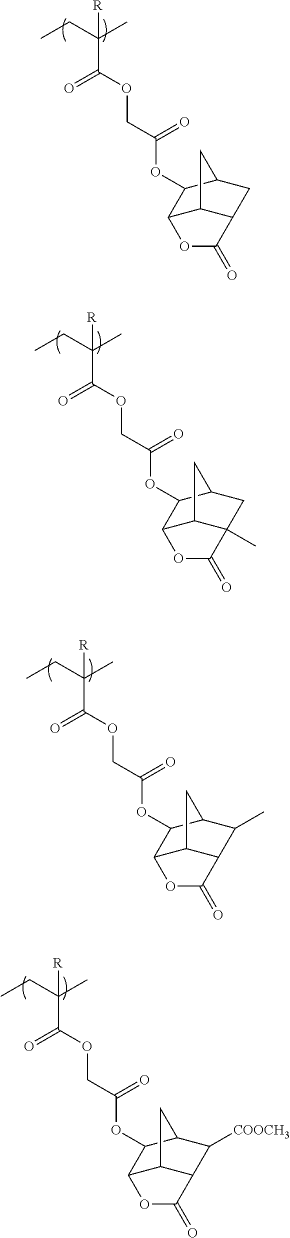

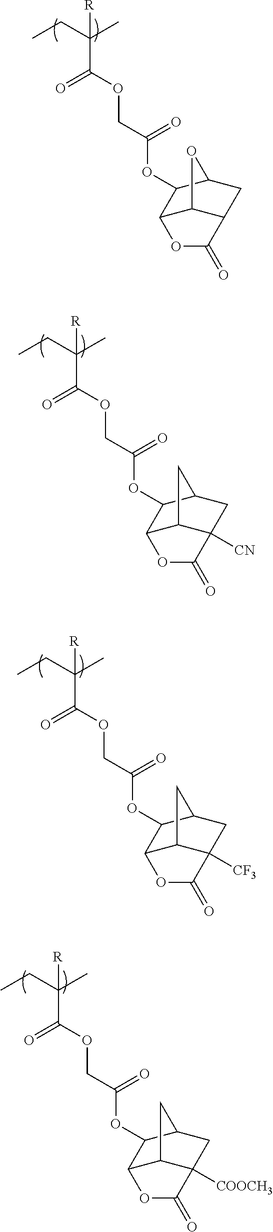

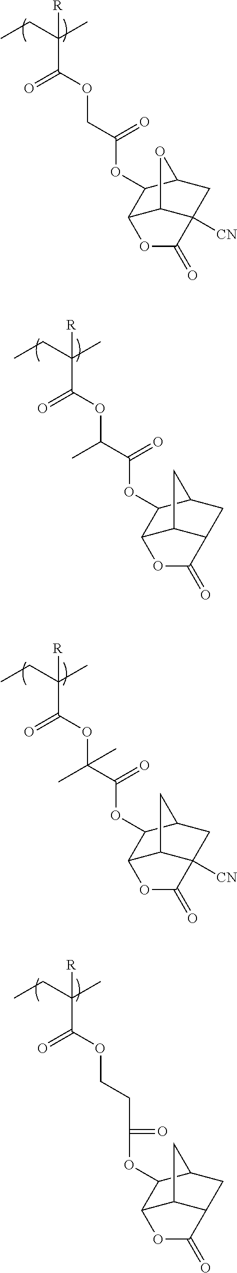

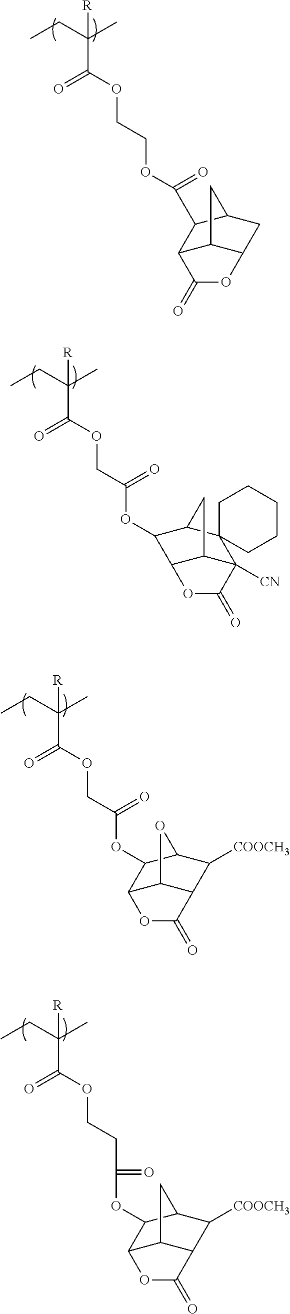

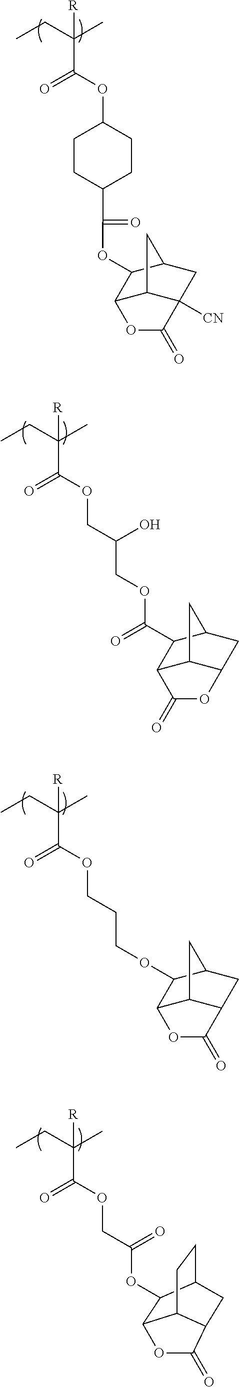

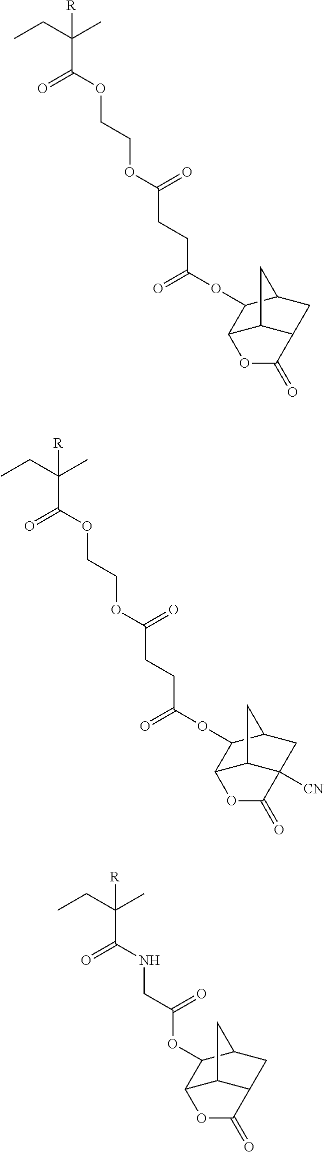

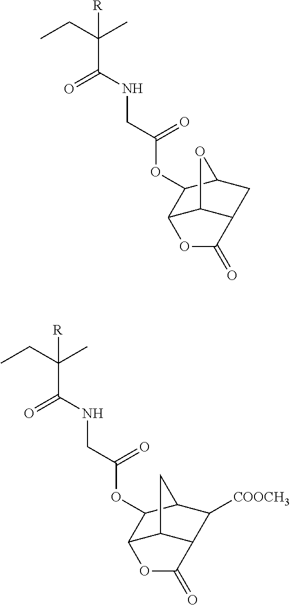

The content of the repeating unit represented by formula (III) is preferably from 15 to 60 mol %, more preferably from 20 to 60 mol %, and still more preferably from 30 to 50 mol %, based on all repeating units in the resin in the case where plural kinds of repeating units are contained.

The resin (B) may contain a repeating unit having a lactone group, in addition to the repeating unit represented by formula (III).

As for the lactone structure, any repeating unit may be used as long as it has a lactone structure, but a 5- to 7-membered ring lactone structure is preferred, and a structure where another ring structure is fused to a 5- to 7-membered ring lactone structure in the form of forming a bicyclo or spiro structure is more preferred. The resin more preferably contains a repeating unit having a lactone structure represented by any one of the following formulae (LC1-1) to (LC1-17). The lactone structure may be bonded directly to the main chain. Preferred lactone structures are (LC1-1), (LC1-4), (LC1-5), (LC1-6), (LC1-13), (LC1-14) and (LC1-17). By using a specific lactone structure, line edge roughness (LWR) and development defect are improved.

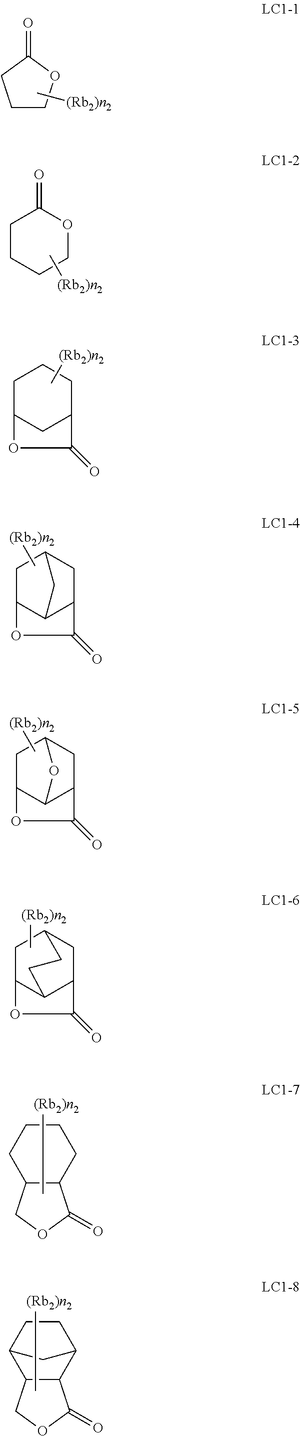

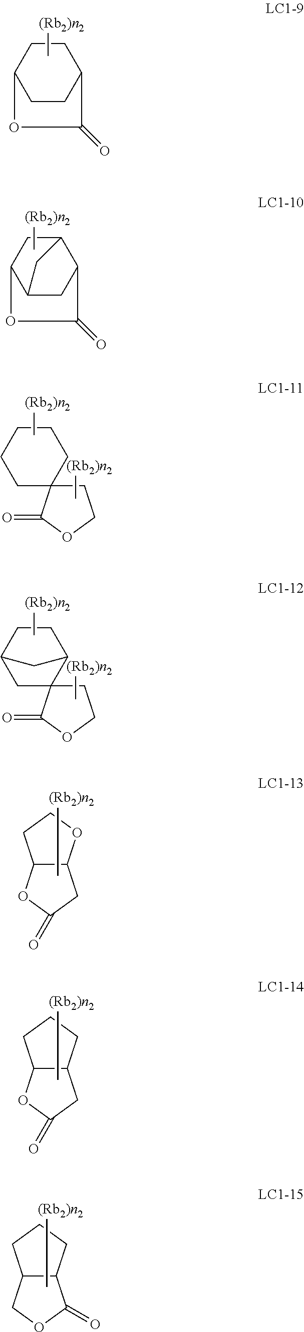

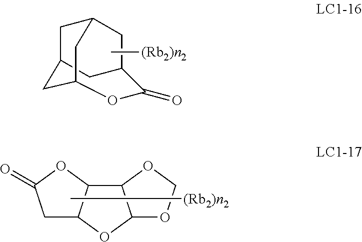

The lactone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group and an acid-decomposable group. Among these, an alkyl group having 1 to 4 carbon atoms, a cyano group and an acid-decomposable group are more preferred. n₂ represents an integer of 0 to 4. When n₂ is 2 or more, each substituent (Rb₂) may be the same as or different from every other substituent (Rb₂). Also, in this case, the plurality of substituents (Rb₂) may combine with each other to form a ring.

The repeating unit having a lactone structure other than the unit represented by formula (III) is preferably a repeating unit represented by the following formula (AII′):

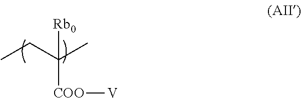

In formula (AII′), Rb₀ represents a hydrogen atom, a halogen atom, or an alkyl group having 1 to 4 carbon atoms, which may have a substituent. Preferred examples of the substituent that the alkyl group of Rb₀ may have include a hydroxyl group and a halogen atom. The halogen atom of Rb₀ includes a fluorine atom, a chlorine atom, a bromine atom and an iodine atom. Rb₀ is preferably a hydrogen atom, a methyl group, a hydroxymethyl group or a trifluoromethyl group, and more preferably a hydrogen atom or a methyl group.

V represents a group having a structure represented by any one of formulae (LC1-1) to (LC1-17).

Specific examples of the repeating unit having a lactone structure other than the unit represented by formula (III) are illustrated below, but the present invention is not limited thereto.

(In the formulae, Rx represents H, CH₃, CH₂OH or CF₃.)

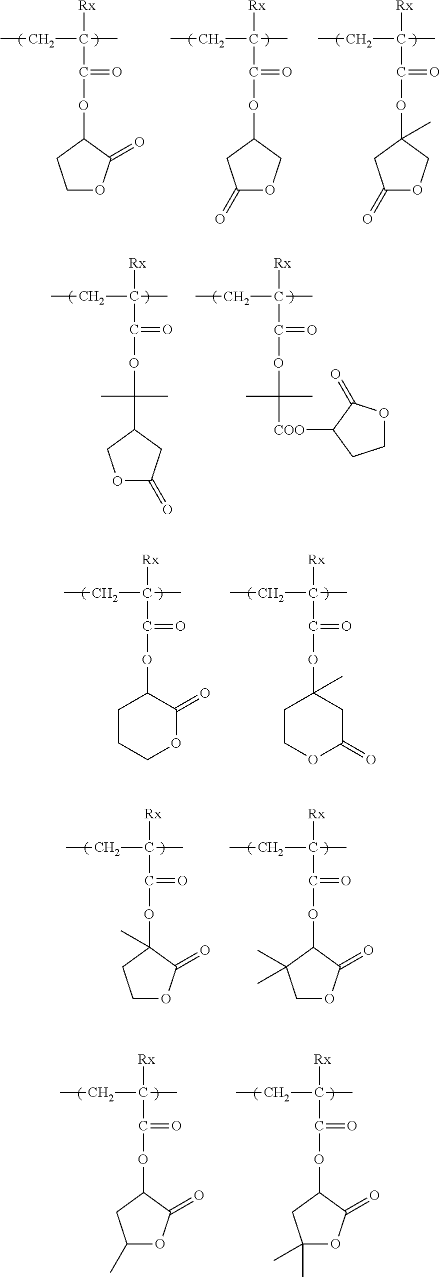

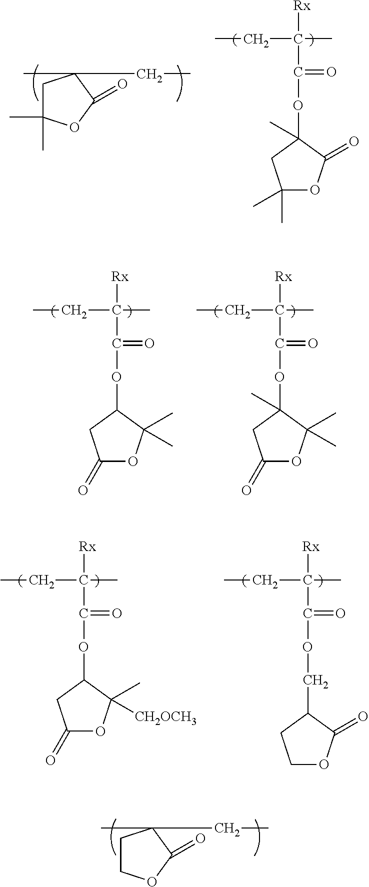

(In the formulae, Rx represents H, CH₃, CH₂OH or CF₃.)

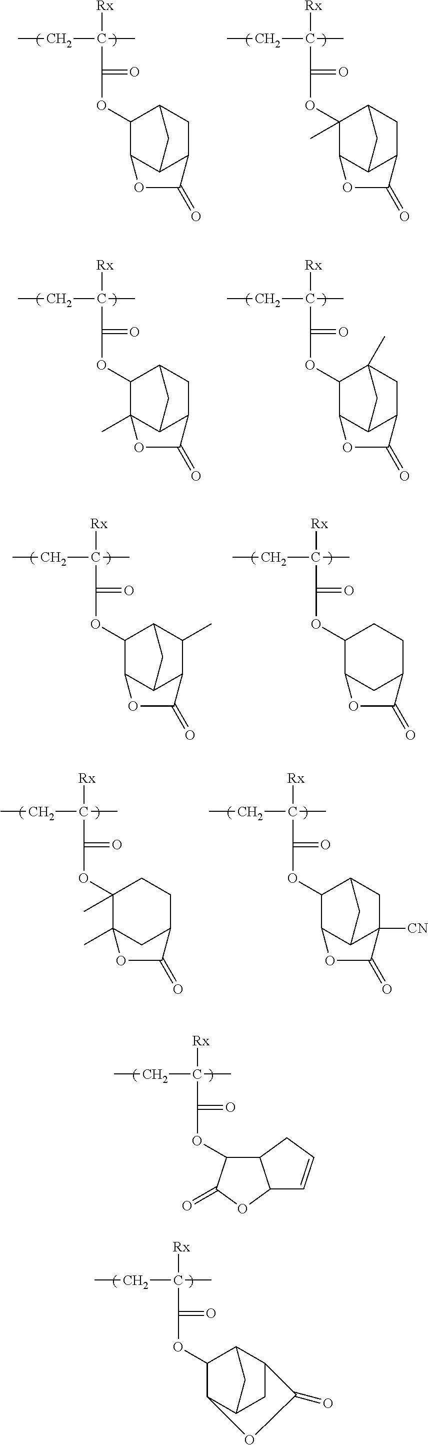

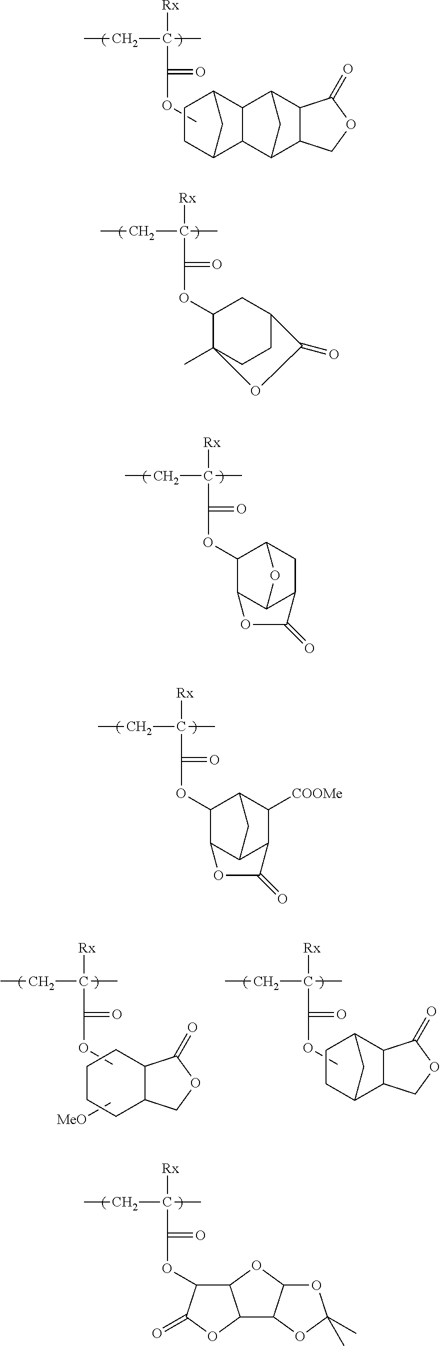

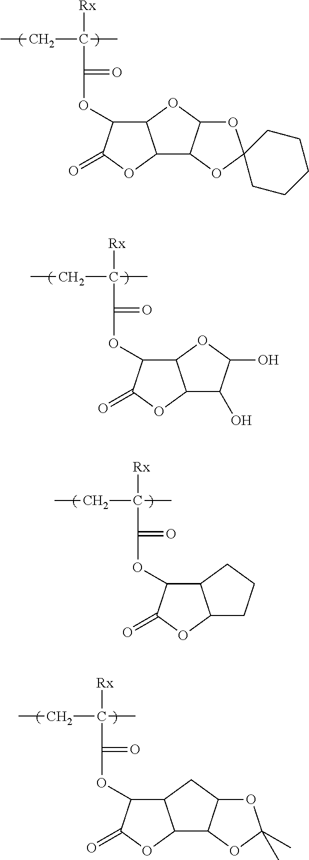

(In the formulae, Rx represents H, CH₃, CH₂OH or CF₃.)

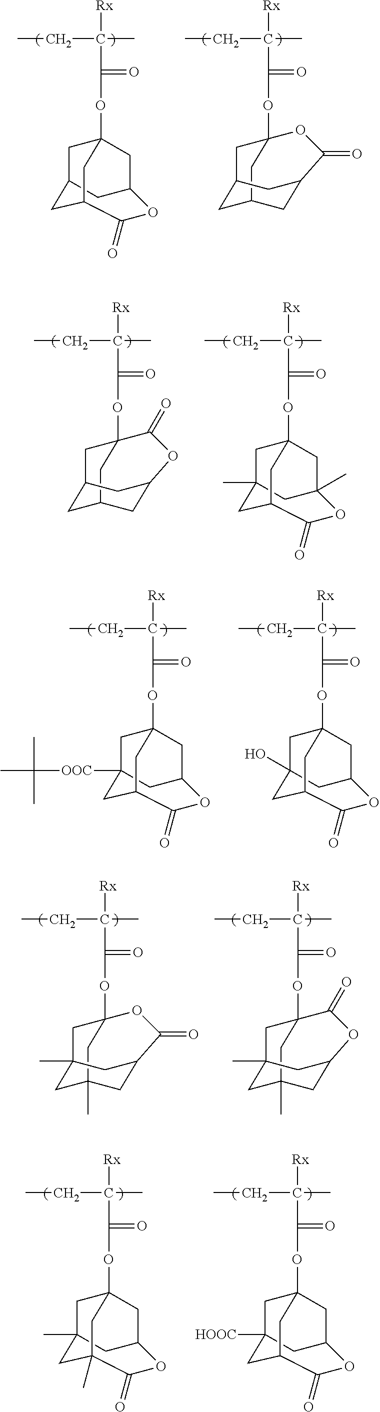

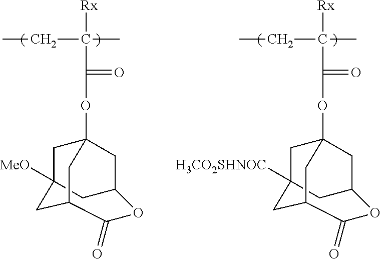

Particularly preferred repeating units having a lactone structure other than the unit represented by formula (III) include the following repeating units. By selecting an optimal lactone structure, the pattern profile and the iso/dense bias are improved.

(In the formulae, Rx represents H, CH₃, CH₂OH or CF₃.)

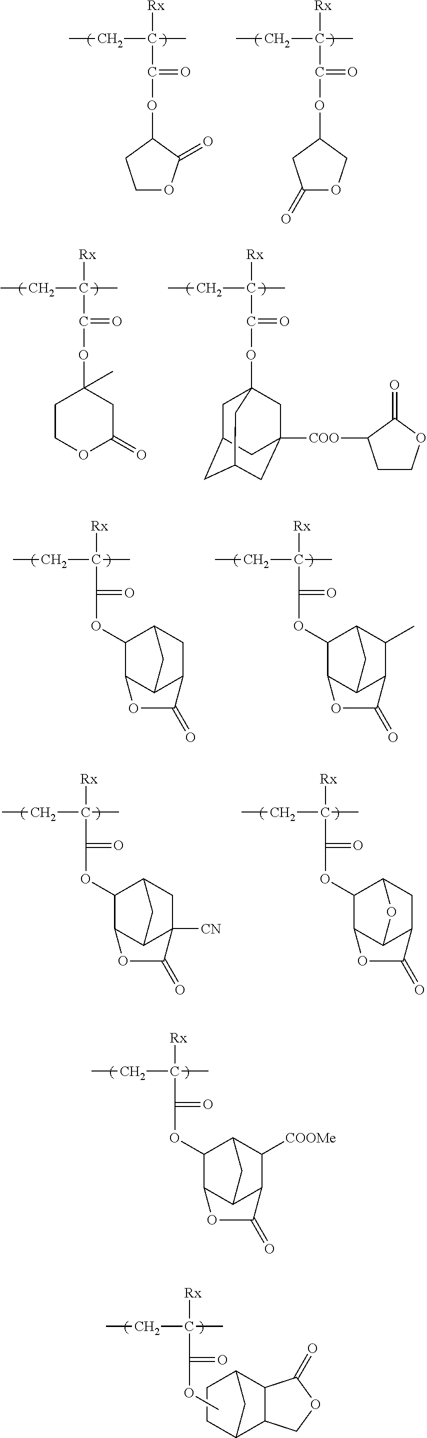

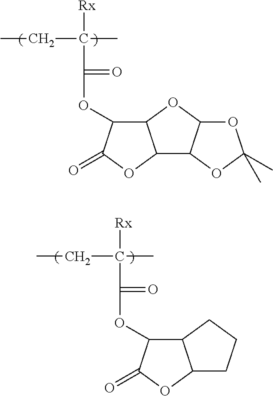

The repeating unit having a lactone group usually has an optical isomer, but any optical isomer may be used. One optical isomer may be used alone or a mixture of a plurality of optical isomers may be used. In the case of mainly using one optical isomer, the optical purity (ee) thereof is preferably 90% or more, and more preferably 95% or more.

The resin may or may not contain a repeating unit having a lactone group, other than the repeating unit represented by formula (III), but in the case of containing such a repeating unit, the content thereof is preferably from 15 to 60 mol %, more preferably from 20 to 50 mol %, and still more preferably from 30 to 50 mol %, based on all repeating units in the resin in the case where plural kinds of repeating units are contained.

Two or more kinds of lactone repeating units selected from formula (III) may also be used in combination for increasing the effects of the present invention. In the case of a combination use, it is also preferred that out of formula (III), two or more kinds of lactone repeating units where n is 1 are selected and used in combination.

The resin (B) preferably contains a repeating unit having a hydroxyl group or a cyano group, other than formulae (AI) and (III). This repeating unit serves to improve adhesion to a substrate and affinity for a developer. The repeating unit having a hydroxyl group or a cyano group is preferably a repeating unit having an alicyclic hydrocarbon structure substituted with a hydroxyl group or a cyano group and preferably has no acid-decomposable group. The alicyclic hydrocarbon structure in the alicyclic hydrocarbon structure substituted with a hydroxyl group or a cyano group is preferably an adamantyl group, a diadamantyl group or a norbornane group. The alicyclic hydrocarbon structure substituted with a hydroxyl group or a cyano group is preferably a partial structure represented by the following formulae (VIIa) to (VIId):

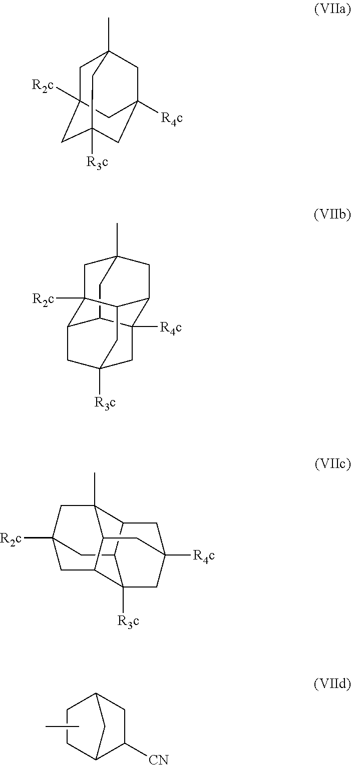

In formulae (VIIa) to (VIIc), R₂c to R₄c each independently represent a hydrogen atom, a hydroxyl group or a cyano group, provided that at least one of R₂c to R₄c represents a hydroxyl group or a cyano group. A structure where one or two members out of R₂c to R₄c are a hydroxyl group with the remaining being a hydrogen atom is preferred. In formula (VIIa), it is more preferred that two members out of R₂c to R₄c are a hydroxyl group and the remaining is a hydrogen atom.

The repeating unit having a partial structure represented by formulae (VIIa) to (VIId) includes repeating units represented by the following formulae (AIIa) to (AIId):

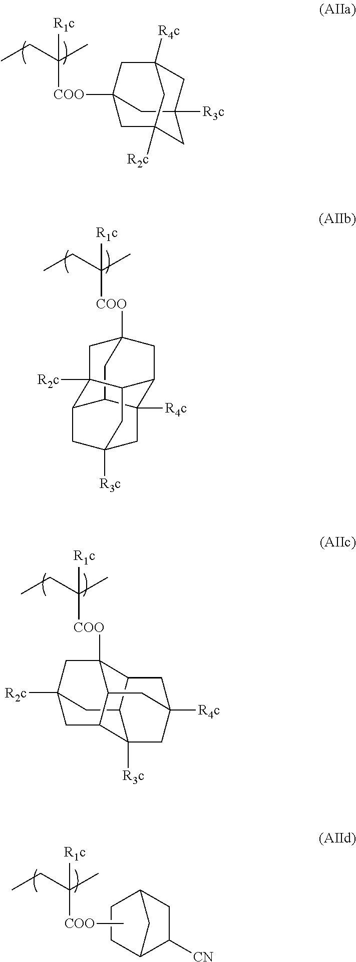

In formulae (AIIa) to (AIId), R₁c represents a hydrogen atom, a methyl group, a trifluoromethyl group or a hydroxymethyl group.

R₂c to R₄c have the same meanings as R₂c to R₄c in formulae (VIIa) to (VIIc).

The resin may or may not contain a repeating unit having a hydroxyl group or a cyano group, but in the case of containing such a repeating unit, the content thereof is preferably from 5 to 40 mol %, more preferably from 5 to 30 mol %, and still more preferably from 10 to 25 mol %, based on all repeating units in the resin (B).

Specific examples of the repeating unit having a hydroxyl group or a cyano group are illustrated below, but the present invention is not limited thereto.

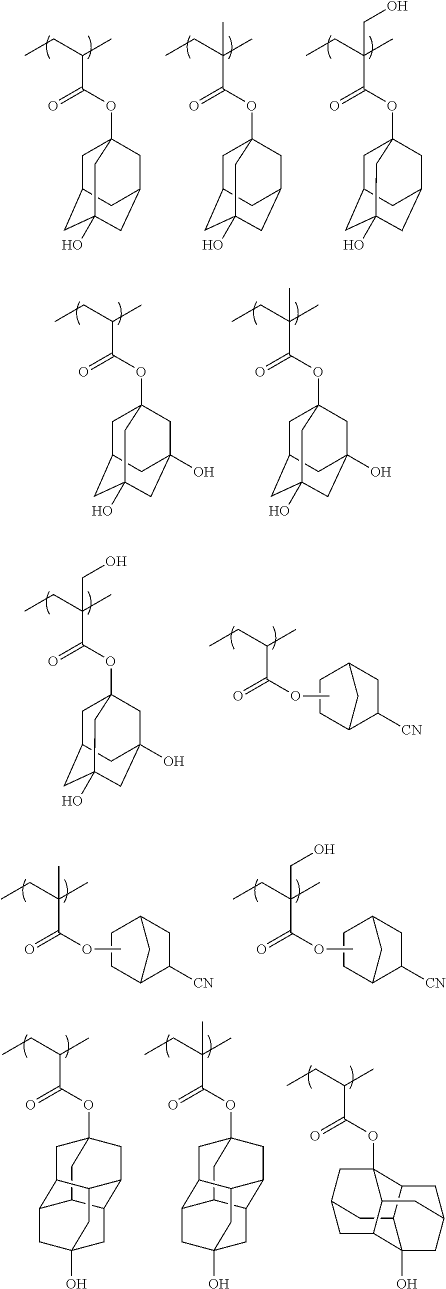

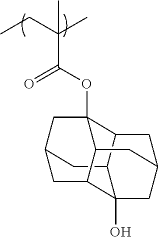

The resin used in the actinic-ray-sensitive or radiation-sensitive resin composition of the present invention may contain a repeating unit having an alkali-soluble group. The alkali-soluble group includes a carboxyl group, a sulfonamide group, a sulfonylimide group, a bissulfonylimide group, and an aliphatic alcohol substituted with an electron-withdrawing group at the α-position (for example, hexafluoroisopropanol group), with a repeating unit having a carboxyl group being more preferred. By virtue of containing a repeating unit having an alkali-soluble group, the resolution increases in the usage of forming contact holes. As for the repeating unit having an alkali-soluble group, all of a repeating unit where an alkali-soluble group is directly bonded to the main chain of the resin, such as repeating unit by an acrylic acid or a methacrylic acid, a repeating unit where an alkali-soluble group is bonded to the main chain of the resin through a linking group, and a repeating unit where an alkali-soluble group is introduced into the polymer chain terminal by using an alkali-soluble group-containing polymerization initiator or chain transfer agent at the polymerization, are preferred. The linking group may have a monocyclic or polycyclic cyclohydrocarbon structure. In particular, a repeating unit by an acrylic acid or a methacrylic acid is preferred.

The resin (B) in the present invention may or may not contain a repeating unit having an alkali-soluble group, but in the case of containing a repeating unit having an alkali-soluble group, the content thereof is preferably from 1 to 20 mol %, more preferably from 3 to 15 mol %, and still more preferably from 5 to 15 mol %, based on all repeating units in the resin (B).

Specific examples of the repeating unit having an alkali-soluble group are illustrated below, but the present invention is not limited thereto.

In specific examples, Rx represents H, CH₃, CH₂OH or CF₃.

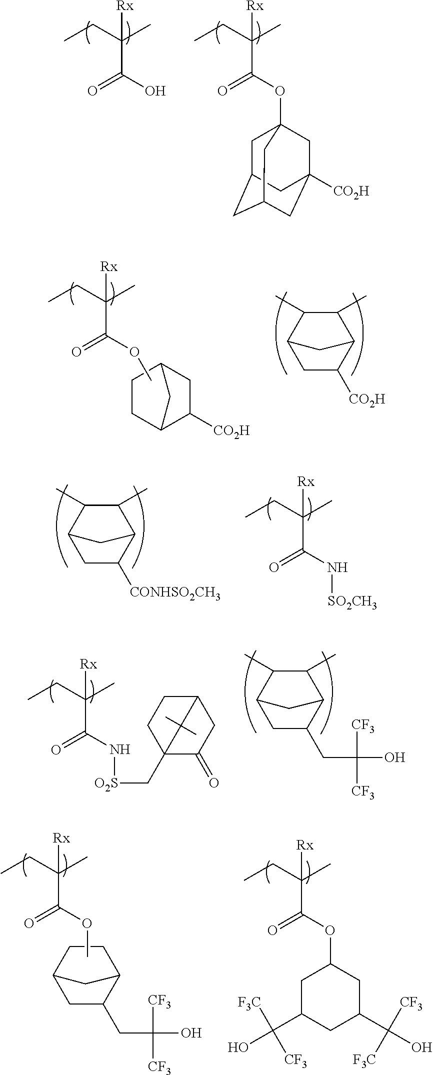

The resin (B) for use in the present invention may further contain a repeating unit having an alicyclic hydrocarbon structure free from a polar group (for example, the above-described alkali-soluble group, a hydroxyl group or a cyano group) and not exhibiting acid decomposability. Such a repeating unit includes a repeating unit represented by formula (IV):

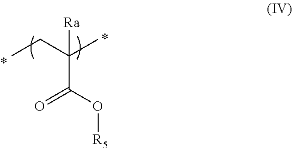

In formula (IV), R₅ represents a hydrocarbon group having at least one cyclic structure and having no polar group.

Ra represents a hydrogen atom, an alkyl group or a —CH₂—O—Ra₂ group, wherein Ra₂ represents a hydrogen atom, an alkyl group or an acyl group. Ra is preferably a hydrogen atom, a methyl group, a hydroxymethyl group or a trifluoromethyl group, and more preferably a hydrogen atom or a methyl group.

The cyclic structure contained in R₅ includes a monocyclic hydrocarbon group and a polycyclic hydrocarbon group. Examples of the monocyclic hydrocarbon group include a cycloalkyl group having 3 to 12 carbon atoms, such as a cyclopentyl group, a cyclohexyl group, a cycloheptyl group or a cyclooctyl group, and a cycloalkenyl group having 3 to 12 carbon atoms, such as a cyclohexenyl group. The monocyclic hydrocarbon group is preferably a monocyclic hydrocarbon group having 3 to 7 carbon atoms, and more preferably a cyclopentyl group or a cyclohexyl group.

The polycyclic hydrocarbon group includes a ring assembly hydrocarbon group and a crosslinked cyclic hydrocarbon group. Examples of the ring assembly hydrocarbon group include a bicyclohexyl group and a perhydronaphthalenyl group. Examples of the crosslinked cyclic hydrocarbon ring include a bicyclic hydrocarbon ring such as a pinane ring, a bornane ring, a norpinane ring, a norbornane ring or a bicyclooctane ring (e.g., a bicyclo[2.2.2]octane ring, or a bicyclo[3.2.1]octane ring), a tricyclic hydrocarbon ring such as a homobledane ring, an adamantane ring, a tricyclo[5.2.1.0^{2,6}]decane ring or a tricyclo[4.3.1.1^{2,5}]undecane ring, and a tetracyclic hydrocarbon ring such as a tetracyclo[4.4.0.1^{2,5}.1^{7,10}]dodecane ring and a perhydro-1,4-methano-5,8-methanonaphthalene ring. The crosslinked cyclic hydrocarbon ring also includes a condensed cyclic hydrocarbon ring, for example, a condensed ring formed by fusing a plurality of 5- to 8-membered cycloalkane rings, such as a perhydronaphthalene (decalin) ring, a perhydroanthracene ring, a perhydrophenanthrene ring, a perhydroacenaphthene ring, a perhydrofluorene ring, a perhydroindene ring and a perhydrophenalene ring.

Preferred examples of the crosslinked cyclic hydrocarbon ring include a norbornyl group, an adamantyl group, a bicyclooctanyl group and a tricyclo[5.2.1.0^{2,6}]decanyl group. Among these crosslinked cyclic hydrocarbon rings, a norbornyl group and an adamantyl group are more preferred.

Such an alicyclic hydrocarbon group may have a substituent, and preferred examples of the substituent include a halogen atom, an alkyl group, a hydroxyl group with a hydrogen atom being substituted for, and an amino group with a hydrogen atom being substituted for. The halogen atom is preferably a bromine atom, a chlorine atom or a fluorine atom, and the alkyl group is preferably a methyl group, an ethyl group, a butyl group or a tert-butyl group. This alkyl group may further have a substituent, and the substituent which the alkyl group may further have includes a halogen atom, an alkyl group, a hydroxyl group with a hydrogen atom being substituted for, and an amino group with a hydrogen atom being substituted for.

Examples of the substituent for the hydrogen atom include an alkyl group, a cycloalkyl group, an aralkyl group, a substituted methyl group, a substituted ethyl group, an alkoxycarbonyl group and an aralkyloxycarbonyl group. The alkyl group is preferably an alkyl group having 1 to 4 carbon atoms; the substituted methyl group is preferably a methoxymethyl group, a methoxythiomethyl group, a benzyloxymethyl group, a tert-butoxymethyl group or a 2-methoxyethoxymethyl group; the substituted ethyl group is preferably a 1-ethoxyethyl group or a 1-methyl-1-methoxyethyl group; the acyl group is preferably an aliphatic acyl group having 1 to 6 carbon atoms, such as a formyl group, an acetyl group, a propionyl group, a butyryl group, an isobutyryl group, a valeryl group or a pivaloyl group; and the alkoxycarbonyl group is preferably an alkoxycarbonyl group having 1 to 4 carbon atoms.

The resin (B) may or may not contain a repeating unit having an alicyclic hydrocarbon structure free from a polar group and not exhibiting acid decomposability, but in the case of containing this repeating unit, the content thereof is preferably from 1 to 40 mol %, and more preferably from 2 to 20 mol %, based on all repeating units in the resin (B).

Specific examples of the repeating unit having an alicyclic hydrocarbon structure free from a polar group and not exhibiting acid decomposability are illustrated below, but the present invention is not limited thereto. In the formulae, Ra represents H, CH₃, CH₂OH or CF₃.

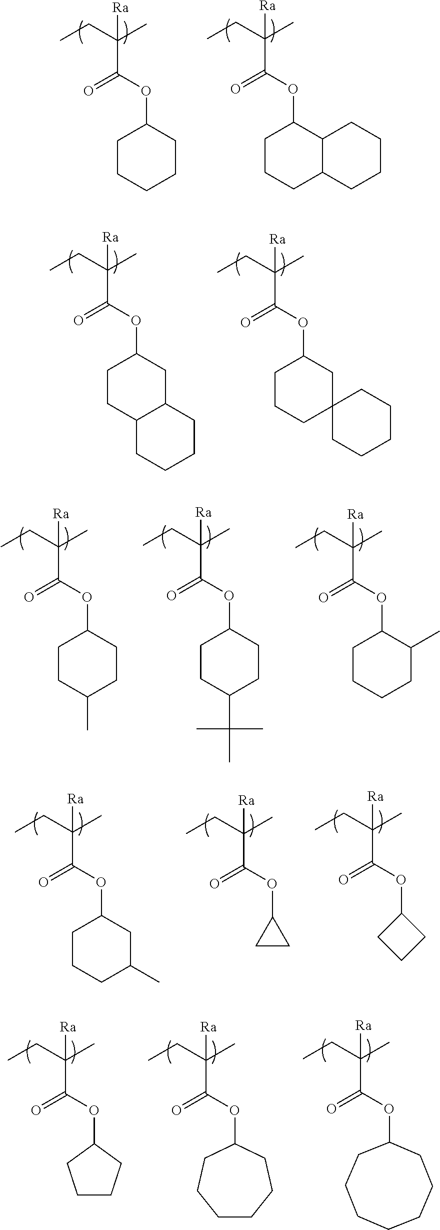

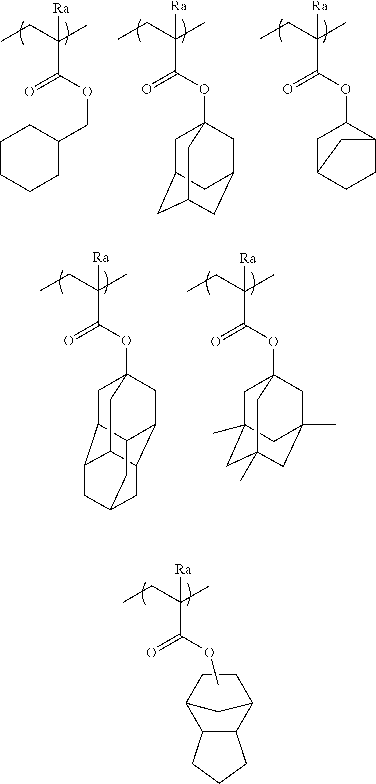

The resin (B) for use in the actinic-ray-sensitive or radiation-sensitive resin composition of the present invention may contain, in addition to the above-described repeating structural units, various repeating structural units for the purpose of controlling the dry etching resistance, suitability for standard developer, adhesion to substrate, resist profile, and properties generally required of a resist, such as resolution, heat resistance and sensitivity.

Examples of such a repeating structural unit include, but are not limited to, repeating structural units corresponding to the monomers described below.

The use of such repeating structural units enables the fine regulation of the performance required of the resin used in the actinic-ray-sensitive or radiation-sensitive resin composition of the present invention, particularly (1) solubility in a coating solvent, (2) film-forming property (glass transition point), (3) alkaline developability, (4) film loss (selection of hydrophilic, hydrophobic or alkali-soluble group), (5) adhesion of unexposed area to substrate, (6) dry etching resistance, and the like.

Examples of the monomer include a compound having one addition-polymerizable unsaturated bond selected from acrylic acid esters, methacrylic acid esters, acrylamides, methacrylamides, allyl compounds, vinyl ethers, vinyl esters and the like.

Other than these, an addition-polymerizable unsaturated compound copolymerizable with the monomers corresponding to the above-described various repeating structural units may be copolymerized.

In the resin (B) for use in the actinic-ray-sensitive or radiation-sensitive resin composition of the present invention, the molar ratio of respective repeating structural units contained in the resin (B) is appropriately set to control the dry etching resistance of resist, suitability for standard developer, adhesion to substrate, resist profile, and performances generally required of a resist, such as resolution, heat resistance and sensitivity.

Further, it is needless to say that the total content of the foregoing repeating units in the resin (B) is not more than 100 mol %.

When the actinic-ray-sensitive or radiation-sensitive resin composition of the present invention is used for ArF exposure, it is preferred that resin (B) used in the actinic-ray-sensitive or radiation-sensitive resin composition of the present invention contain substantially no aromatic group from the viewpoint of transparency to ArF light. More specifically, in all repeating units of the resin (B), the content of the aromatic group-containing repeating unit is preferably 5 mol % or less, more preferably 3 mol % or less, and ideally 0 mol %, that is, still more preferably free from the aromatic group-containing repeating unit.

Further, the resin (B) preferably has a monocyclic or polycyclic alicyclic hydrocarbon structure.

The resin (B) more preferably contains a repeating unit having a monocyclic or polycyclic alicyclic hydrocarbon structure, and examples of the repeating unit having a monocyclic or polycyclic alicyclic hydrocarbon structure include repeating units represented by formula (I), (II-1) or (IV), and repeating units having a partial structure represented by formulae (VIIa) to (VIId).

Also, the resin (B) preferably contains neither a fluorine atom nor no silicon atom from the viewpoint of compatibility with a hydrophobic resin described later.

The resin (B) for use in the actinic-ray-sensitive or radiation-sensitive resin composition of the present invention is preferably a resin where all repeating units are composed of a (meth)acrylate-based repeating unit. In this case, all repeating units may be a methacrylate-based repeating unit, all repeating units may be an acrylate-based repeating unit, or all repeating units may be composed of a methacrylate-based repeating unit and an acrylate-based repeating unit, but the content of the acrylate-based repeating unit in the resin (B) is preferably 50 mol % or less based on all repeating units. A copolymerized polymer containing from 20 to 50 mol % of an acid decomposable group-containing (meth)acrylate-based repeating unit, from 20 to 50 mol % of a lactone group-containing (meth)acrylate-based repeating unit, from 5 to 30 mol % of a (meth)acrylate-based repeating unit having an alicyclic hydrocarbon structure substituted with a hydroxyl group or a cyano group, and from 0 to 20 mol % of other (meth)acrylate-based repeating units is also preferred.

The resin (B) may be commercially available if launched or may be synthesized by a conventional method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred. Examples of the reaction solvent include tetrahydrofuran, 1,4-dioxane, ethers such as diisopropyl ether, ketones such as methyl ethyl ketone and methyl isobutyl ketone, an ester solvent such as ethyl acetate, an amide solvent such as dimethylformamide and dimethylacetamide, and the later-described solvent capable of dissolving the actinic-ray-sensitive or radiation-sensitive resin composition of the present invention, such as propylene glycol monomethyl ether acetate, propylene glycol monomethyl ether and cyclohexanone. The polymerization is more preferably carried out using the same solvent as the solvent used in the actinic-ray-sensitive or radiation-sensitive resin composition of the present invention. By the use of the same solvent, production of particles during storage may be suppressed.

The polymerization reaction is preferably carried out in an inert gas atmosphere such as nitrogen or argon. As for the polymerization initiator, the polymerization is started using a commercially available radical initiator (e.g., an azo-based initiator, or peroxide). The radical initiator is preferably an azo-based initiator, and an azo-based initiator having an ester group, a cyano group or a carboxyl group is preferred. Preferred examples of the initiator include azobisisobutyronitrile, azobisdimethylvaleronitrile and dimethyl 2,2′-azobis(2-methylpropionate). The initiator is added additionally or in parts, if desired. After the completion of reaction, the reaction solution is poured into a solvent, and the desired polymer is collected by powder or solid recovery or the like method. The concentration during the reaction is in the range of 5 to 50 mass %, preferably 30 to 50 mass %, and the reaction temperature is usually in the range of 10 to 150° C., preferably 30 to 120° C., more preferably 60 to 100° C.

In order to inhibit the aggregation or the like of the resin after the composition was prepared, for example, as described in JP2009-037108A, there may be added a step of dissolving the synthesized resin in a solvent and heating the resulting solution at a temperature of about 30° C. to 90° C. for about 30 minutes to 4 hours.

After the completion of reaction, the reaction solution is allowed to cool to room temperature and purified. The purification may be carried out by a normal method, for example, a liquid-liquid extraction method of applying water washing or combining appropriate solvents to remove residual monomers or oligomer components; a purification method in a solution sate, such as ultrafiltration of extracting and removing only polymers having a molecular weight not more than a specific value; a reprecipitation method of adding dropwise the resin solution in a poor solvent to solidify the resin in the poor solvent and thereby remove residual monomers and the like; and a purification method in a solid state, such as washing of a resin slurry with a poor solvent after separation of the slurry by filtration. For example, the resin is precipitated as a solid by contacting the reaction solution with a solvent in which the resin is sparingly soluble or insoluble (poor solvent) and which is in a volumetric amount of 10 times or less, preferably from 10 to 5 times, the reaction solution.

The solvent used at the operation of precipitation or reprecipitation from the polymer solution (precipitation or reprecipitation solvent) may be sufficient if it is a poor solvent for the polymer, and the solvent which can be used may be appropriately selected from a hydrocarbon, a halogenated hydrocarbon, a nitro compound, an ether, a ketone, an ester, a carbonate, an alcohol, a carboxylic acid, water, a mixed solvent containing these solvents, and the like, according to the kind of the polymer.

The amount of the precipitation or reprecipitation solvent used may be appropriately selected by taking into consideration the efficiency, yield and the like, but in general, the amount used is from 100 to 10,000 parts by mass, preferably from 200 to 2,000 parts by mass, more preferably from 300 to 1,000 parts by mass, based on 100 parts by mass of the polymer solution.

The temperature during the precipitation or reprecipitation may be appropriately selected by taking into consideration the efficiency or operability but is usually on the order of 0 to 50° C., preferably in the vicinity of room temperature (for example, approximately from 20 to 35° C.). The precipitation or reprecipitation operation may be carried out using a commonly employed mixing vessel such as stirring tank by a known method such as a batch system or a continuous system.

The precipitated or reprecipitated polymer is usually subjected to commonly employed solid-liquid separation such as filtration and centrifugation, then dried and used. The filtration is carried out using a solvent-resistant filter element preferably under pressure. The drying is carried out under atmospheric pressure or reduced pressure (preferably under reduced pressure) at a temperature of approximately from 30 to 100° C., preferably on the order of 30 to 50° C.

Incidentally, after the resin is once precipitated and separated, the resin may be dissolved again in a solvent and then put into contact with a solvent in which the resin is sparingly soluble or insoluble. That is, there may be used a method including, after the completion of radical polymerization reaction, bringing the polymer into contact with a solvent in which the polymer is sparingly soluble or insoluble, to precipitate a resin (step a), separating the resin from the solution (step b), dissolving the resin again in a solvent to prepare a resin solution A (step c), bringing the resin solution A into contact with a solvent in which the resin is sparingly soluble or insoluble and which is in a volumetric amount of less than 10 times (preferably 5 times or less) the resin solution A, to precipitate a resin solid (step d), and separating the precipitated resin (step e).

In order to inhibit the aggregation or the like of the resin after the composition was prepared, for example, as described in JP2009-037108A, there may be added a step of dissolving the synthesized resin in a solvent and heating the resulting solution at a temperature of about 30° C. to 90° C. for about 30 minutes to 4 hours.

The weight average molecular weight of the resin (B) for use in the present invention is preferably from 1,000 to 200,000, more preferably from 2,000 to 20,000, still more preferably from 3,000 to 15,000, in terms of polystyrene by the GPC method. When the weight average molecular weight is from 1,000 to 200,000, this may prevent the deterioration of a film forming property due to an increase in viscosity of the composition and also prevent the deterioration of developability as well as heat resistance and dry etching resistance of the film formed using the composition of the present invention.

The dispersity of the resin (B) of the present invention (molecular weight distribution, Mw/Mn) is usually from 1.0 to 3.0, preferably from 1.0 to 2.6, more preferably from 1.0 to 2.0, and still more preferably from 1.4 to 2.0. As the molecular weight distribution is smaller, the resolution and pattern profile are more excellent, the side wall of the resist pattern is smoother, and the roughness is more improved.

In the description of the present invention, the weight average molecular weight (Mw) and number average molecular weight (Mn) of the resin (B) may be calculated by using, for example, HLC-8120 (available from Tosoh Corporation) using TSK gel Multipore HXL-M (available from Tosoh Corporation, 7.8 mmID×30.0 cm) as a column and tetrahydrofuran (THF) as an eluent.

In the present invention, the content of the resin (B) in the entire composition is preferably from 30 to 99 mass %, and more preferably from 60 to 95 mass %, based on the total solid content.

As for the resin (B) for use in the present invention, one kind of a resin may be used or a plurality of kinds of resins may be used in combination.

[3] Hydrophobic Resin

The actinic-ray-sensitive or radiation-sensitive resin composition of the present invention may contain a hydrophobic resin having at least either a fluorine atom or a silicon atom (hereinafter, also referred to as a “hydrophobic resin (HR)”) particularly when the resist composition is applied to immersion exposure. The hydrophobic resin (HR) is unevenly distributed to the film surface layer and when the immersion medium is water, the static/dynamic contact angle on the resist film surface for water as well as the followability of immersion liquid can be enhanced.

The hydrophobic resin (HR) is, as described above, unevenly distributed to the interface but unlike a surfactant, need not have necessarily a hydrophilic group in the molecule and may not contribute to uniform mixing of polar/nonpolar substances.

The hydrophobic resin typically contains a fluorine atom and/or a silicon atom. The fluorine atom and/or silicon atom in the hydrophobic resin (HR) may be contained in the main chain of the resin or may be contained in the side chain.

In the case where the hydrophobic resin contains a fluorine atom, the resin preferably contains, as a fluorine atom-containing partial structure, a fluorine atom-containing alkyl group, a fluorine atom-containing cycloalkyl group or a fluorine atom-containing aryl group. The fluorine atom-containing alkyl group (preferably having 1 to 10 carbon atoms, and more preferably 1 to 4 carbon atoms) is a linear or branched alkyl group with at least one hydrogen atom being substituted for by a fluorine atom and may further have a substituent other than the fluorine atom.

The fluorine atom-containing cycloalkyl group is a monocyclic or polycyclic cycloalkyl group with at least one hydrogen atom being substituted for by a fluorine atom and may further have a substituent other than the fluorine atom.

The fluorine atom-containing aryl group is an aryl group (e.g., a phenyl group, or a naphthyl group) with at least one hydrogen atom being substituted for by a fluorine atom and may further have a substituent other than the fluorine atom.

Preferred examples of the fluorine atom-containing alkyl group, fluorine atom-containing cycloalkyl group and fluorine atom-containing aryl group include the groups represented by the following formulae (F2) to (F4), but the present invention is not limited thereto.

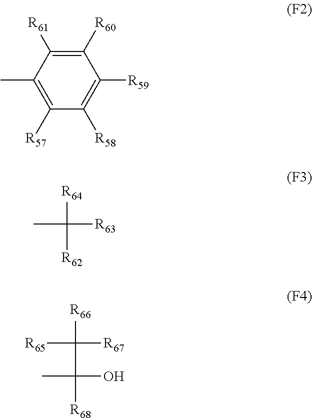

In formulae (F2) to (F4), R₅₇ to R₆₈ each independently represent a hydrogen atom, a fluorine atom or an alkyl group (linear or branched), provided that each of at least one of R₅₇ to R₆₁, at least one of R₆₂ to R₆₄, and at least one of R₆₅ to R₆₈ independently represents a fluorine atom or an alkyl group (preferably having 1 to 4 carbon atoms) with at least one hydrogen atom being substituted for by a fluorine atom.

It is preferred that all of R₅₇ to R₆₁ and R₆₅ to R₆₇ are a fluorine atom. Each of R₆₂, R₆₃ and R₆₈ is preferably a fluoroalkyl group (preferably having 1 to 4 carbon atoms), and more preferably a perfluoroalkyl group having 1 to 4 carbon atoms. When R₆₂ and R₆₃ is a perfluoroalkyl group, R₆₄ is preferably a hydrogen atom. R₆₂ and R₆₃ may combine with each other to form a ring.

Specific examples of the group represented by formula (F2) include a p-fluorophenyl group, a pentafluorophenyl group and a 3,5-di(trifluoromethyl)phenyl group.

Specific examples of the group represented by formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-tert-butyl group, a perfluoroisopentyl group, a perfluorooctyl group, a perfluoro(trimethyl)hexyl group, a 2,2,3,3-tetrafluorocyclobutyl group and a perfluorocyclohexyl group. Among these, a hexafluoroisopropyl group, a heptafluoroisopropyl group, a hexafluoro(2-methyl)isopropyl group, an octafluoroisobutyl group, a nonafluoro-tert-butyl group and a perfluoroisopentyl group are preferred, and a hexafluoroisopropyl group and a heptafluoroisopropyl group are more preferred.

Specific examples of the group represented by formula (F4) include —C(CF₃)₂OH, —C(C₂F₅)₂OH, —C(CF₃)(CH₃)OH and —CH(CF₃)OH, with —C(CF₃)₂OH being preferred.

The fluorine atom-containing partial structure may be bonded directly to the main chain or may be bonded to the main chain through a group selected from the group consisting of an alkylene group, a phenylene group, an ether bond, a thioether bond, a carbonyl group, an ester bond, an amide bond, a urethane bond and a ureylene bond, or a group formed by combining two or more thereof.

As the repeating unit having a fluorine atom, those shown below are preferred.

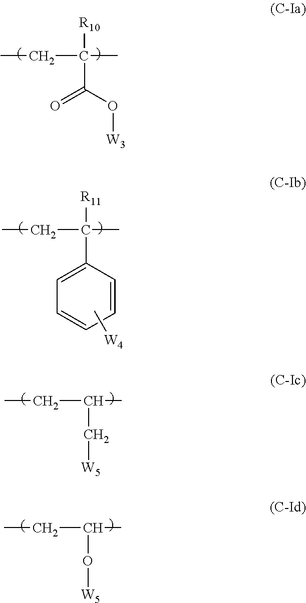

In the formulae, R₁₀ and R₁₁ each independently represent a hydrogen atom, a fluorine atom or an alkyl group. The alkyl group is preferably a linear or branched alkyl group having 1 to 4 carbon atoms and may have a substituent, and the alkyl group having a substituent includes, in particular, a fluorinated alkyl group.

W₃ to W₆ each independently represent an organic group having at least one or more fluorine atoms and specifically includes the atomic groups of (F2) to (F4).

Other than these, the hydrophobic resin may contain a unit shown below as the repeating unit having a fluorine atom.

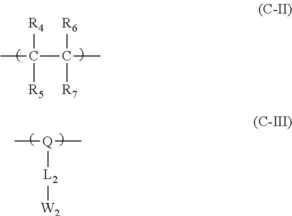

In the formulae, R₄ to R₇ each independently represent a hydrogen atom, a fluorine atom or an alkyl group. The alkyl group is preferably a linear or branched alkyl group having 1 to 4 carbon atoms and may have a substituent, and the alkyl group having a substituent includes, in particular, a fluorinated alkyl group.

However, at least one of R₄ to R₇ represents a fluorine atom. R₄ and R₅, or R₆ and R₇ may form a ring.

W₂ represents an organic group having at least one fluorine atom and specifically includes the atomic groups of (F2) to (F4).

L₂ represents a single bond or a divalent linking group. The divalent linking group is a substituted or unsubstituted arylene group, a substituted or unsubstituted alkylene group, a substituted or unsubstituted cycloalkylene group, —O—, —SO₂—, —CO—, —N(R)— (wherein R represents a hydrogen atom or an alkyl group), —NHSO₂—, or a divalent linking group formed by combining a plurality of these groups.

Q represents an alicyclic structure. The alicyclic structure may have a substituent and may be monocyclic or polycyclic, and in the case of a polycyclic structure, the structure may be a crosslinked structure. The monocyclic structure is preferably a cycloalkyl group having 3 to 8 carbon atoms, and examples thereof include a cyclopentyl group, a cyclohexyl group, a cyclobutyl group and a cyclooctyl group. Examples of the polycyclic structure include a group containing a bicyclo, tricyclo or tetracyclo structure having 5 or more carbon atoms. A cycloalkyl group having 6 to 20 carbon atoms is preferred, and examples thereof include an adamantyl group, a norbornyl group, a dicyclopentyl group, a tricyclodecanyl group and a tetracyclododecyl group. At least one of carbon atoms in the cycloalkyl group may be substituted with a heteroatom such as an oxygen atom. In particular, Q is preferably a norbornyl group, a tricyclodecanyl group, a tetracyclododecyl group or the like.

The hydrophobic resin may contain a silicon atom.

The resin preferably has, as a silicon atom-containing partial structure, an alkylsilyl structure (preferably a trialkylsilyl group) or a cyclic siloxane structure.

The alkylsilyl structure and cyclic siloxane structure specifically include, for example, the groups represented by the following formulae (CS-1) to (CS-3):

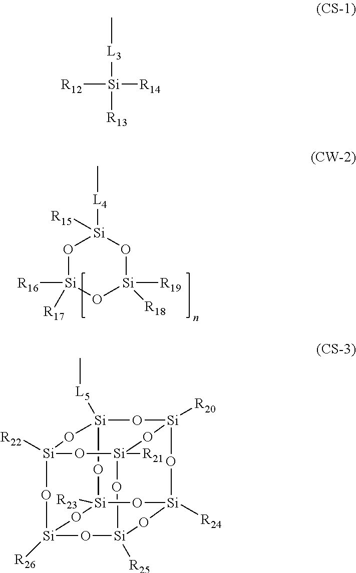

In formulae (CS-1) to (CS-3), R₁₂ to R₂₆ each independently represent a linear or branched alkyl group (preferably having 1 to 20 carbon atoms) or a cycloalkyl group (preferably having 3 to 20 carbon atoms).

L₃ to L₅ each represent a single bond or a divalent linking group. The divalent linking group is a sole group or a combination of two or more groups selected from the group consisting of an alkylene group, a phenylene group, an ether bond, a thioether bond, a carbonyl group, an ester bond, an amide bond, a urethane bond and a ureylene bond.

n represents an integer of 1 to 5. n is preferably an integer of 2 to 4.

The repeating unit having at least either a fluorine atom or a silicon atom is preferably a (meth)acrylate-based repeating unit.

Specific examples of the repeating unit having at least either a fluorine atom or a silicon atom are illustrated below, but the present invention is not limited thereto. In specific examples, X₁ represents a hydrogen atom, —CH₃, —F or —CF₃, and X₂ represents —F or —CF₃.

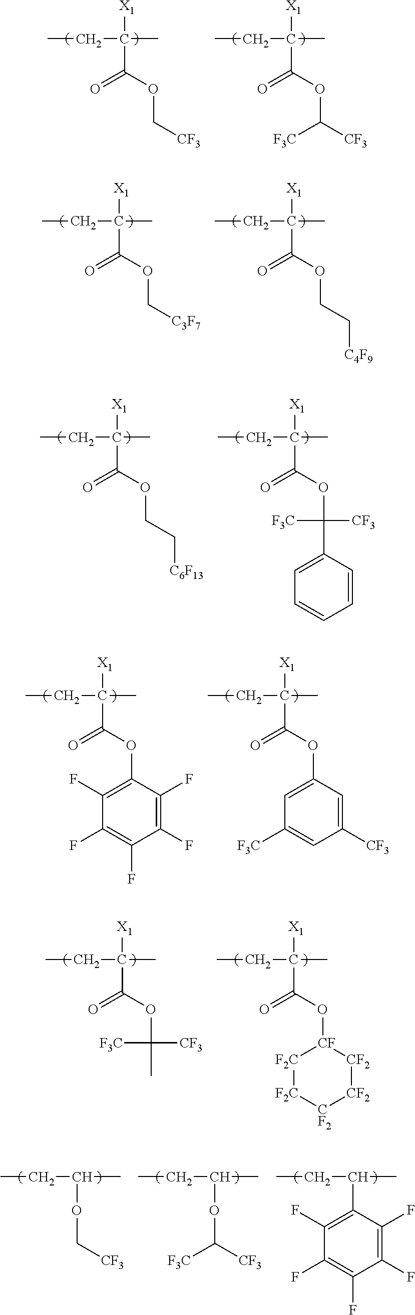

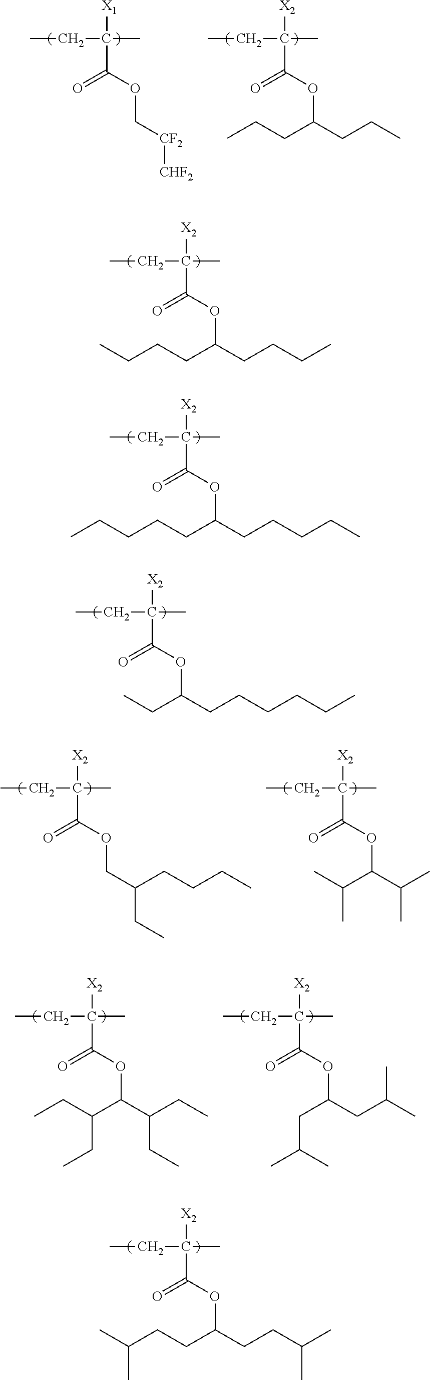

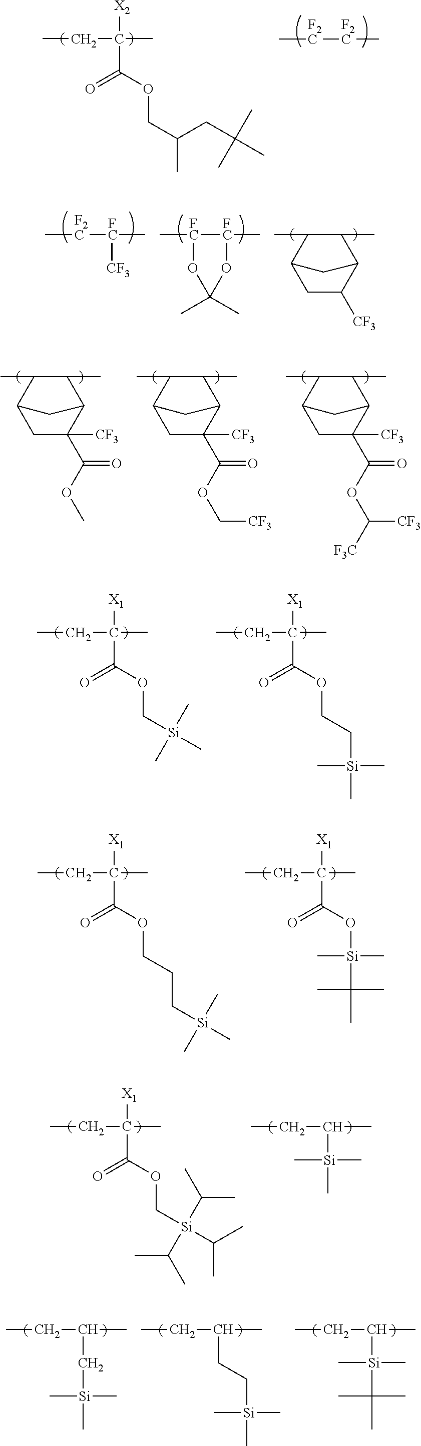

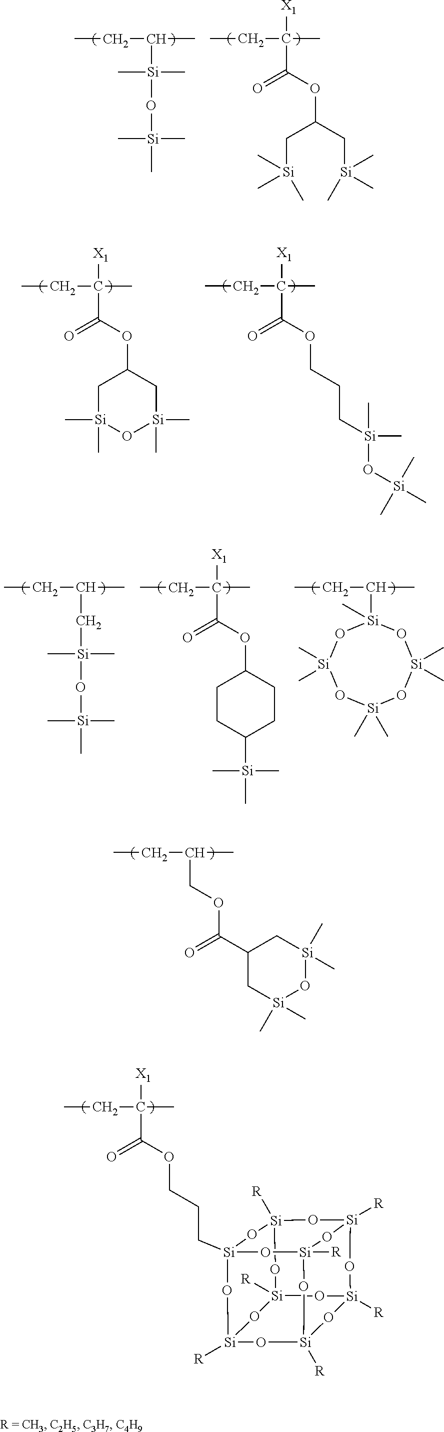

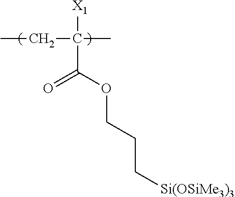

The hydrophobic resin preferably contains a repeating unit (b) having at least one group selected from the group consisting of the following (x) to (z):

(x) an alkali-soluble group,

(y) a group capable of decomposing by the action of an alkaline developer to increase the solubility in an alkaline developer (hereinafter, also referred to as a “polarity converting group”), and

(z) a group capable of decomposing by the action of an acid to increase the solubility in an alkaline developer.

The repeating unit (b) includes the following types.
(b′) a repeating unit having at least either a fluorine atom or a silicon atom and at least one group selected from the group consisting of (x) to (z) on one side chain,
(b*) a repeating unit having at least one group selected from the group consisting of (x) to (z) and having neither a fluorine atom nor a silicon atom,
(b″) a repeating unit having at least one group selected from the group consisting of (x) to (z) on one side chain and having at least either a fluorine atom or a silicon atom on a side chain different from the side chain above in the same repeating unit The hydrophobic resin more preferably contains the repeating unit (b′) as the repeating unit (b). That is, the repeating unit (b) having at least one group selected from the group consisting of (x) to (z) more preferably contains at least either a fluorine atom or a silicon atom.

In the case where the hydrophobic resin contains the repeating unit (b*), the resin is preferably a copolymer with a repeating unit having at least either a fluorine atom or a silicon atom (a repeating unit different from the repeating units (b*) and (b**)). Also, in the repeating unit (b″), the side chain having at least one group selected from the group consisting of (x) to (z) and the side chain having at least either a fluorine atom or a silicon atom are preferably bonded to the same carbon atom in the main chain, that is, have a positional relationship as in the following formula (K1).

In the formula, B1 represents a partial structure having at least one group selected from the group consisting of (x) to (z), and B2 represents a partial structure having at least either a fluorine atom or a silicon atom.

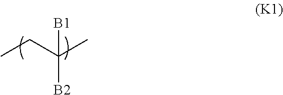

The group selected from the group consisting of (x) to (z) is preferably (x) an alkali-soluble group or (y) a polarity converting group, and more preferably (y) a polarity converting group.

Examples of the (x) alkali-soluble group include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group and a tris(alkylsulfonyl)methylene group. Preferred alkali-soluble groups include a fluorinated alcohol group (preferably, a hexafluoroisopropanol group), a sulfonimide group and a bis(carbonyl)methylene group.

Examples of the repeating unit (bx) having (x) an alkali-soluble group include a repeating unit where an alkali-soluble group is directly bonded to the main chain of the resin, such as repeating unit by an acrylic acid or a methacrylic acid, and a repeating unit where an alkali-soluble group is bonded to the main chain of the resin through a linking group. Furthermore, an alkali-soluble group may be introduced into the polymer chain terminal by using an alkali-soluble group-containing polymerization initiator or chain transfer agent at the polymerization. All of these cases are preferred.

In the case where the repeating unit (bx) is a repeating unit having at least either a fluorine atom or a silicon atom (that is, a repeating unit corresponding to the repeating unit (b′) or (b″)), examples of the fluorine atom-containing partial structure in the repeating unit (bx) are the same as those described for the repeating unit having at least either a fluorine atom or a silicon atom and preferably include the groups represented by formulae (F2) to (F4). Also in this case, examples of the silicon atom-containing partial structure in the repeating unit (bx) are the same as those described for the repeating unit having at least either a fluorine atom or a silicon atom and preferably include the groups represented by formulae (CS-1) to (CS-3).

The content of the repeating unit (bx) having (x) an alkali-soluble group is preferably from 1 to 50 mol %, more preferably from 3 to 35 mol %, and still more preferably from 5 to 20 mol %, based on all repeating units in the hydrophobic resin.

Specific examples of the repeating unit (bx) having (x) an alkali-soluble group are illustrated below, but the present invention is not limited thereto. In specific examples, X₁ represents a hydrogen atom, CH₃, —F or —CF₃.

In the formulae, Rx represents a hydrogen atom, CH₃, CF₃ or CH₂OH.

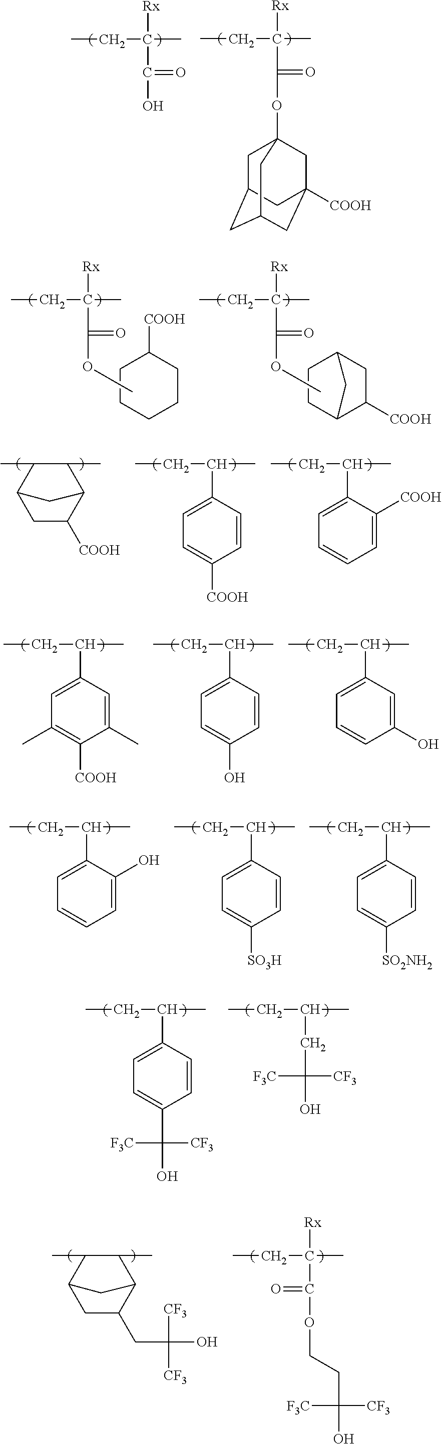

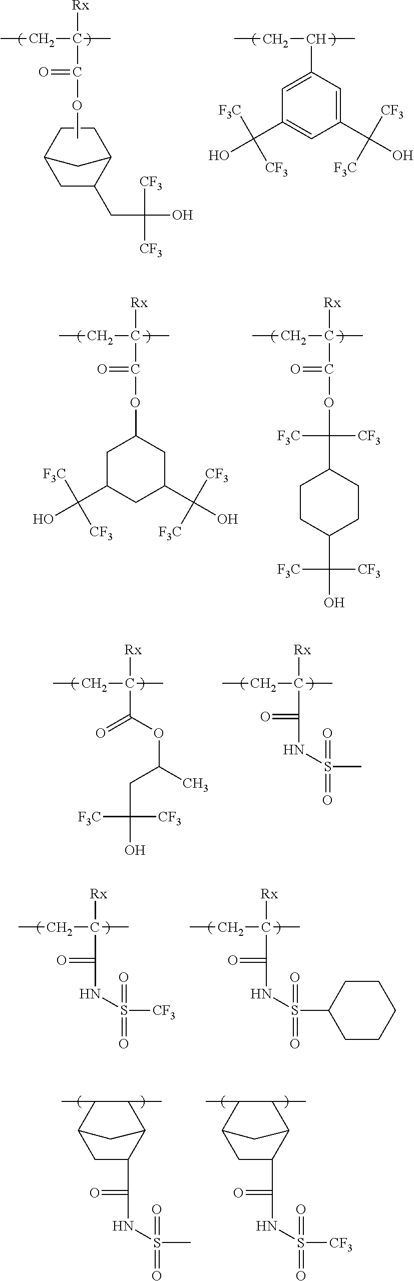

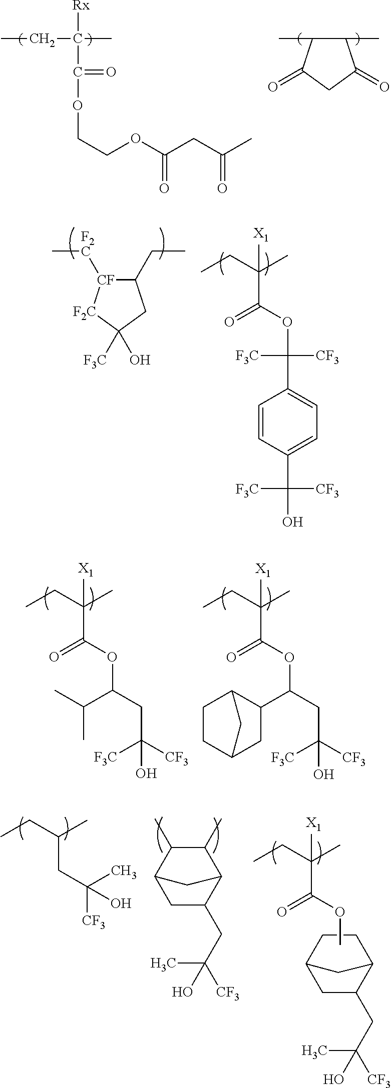

Examples of the polarity converting group (y) include a lactone group, a carboxylic acid ester group (—COO—), an acid anhydride group (—C(O)OC(O)—), an acid imide group (—NHCONH—), a carboxylic acid thioester group (—COS—), a carbonic acid ester group (—OC(O)O—), a sulfuric acid ester group (−OSO₂O—) and a sulfonic acid ester group (—SO₂O—), with a lactone group being preferred.

As for the polarity converting group (y), both a configuration where the polarity converting group is contained in a repeating unit composed of an acrylic acid ester or a methacrylic acid ester and thereby is introduced into the side chain of the resin, and a configuration where the polarity converting group is introduced into the polymer chain terminal by using a polymerization initiator or chain transfer agent containing the polarity converging group at the polymerization are preferred.

Specific examples of the repeating unit (by) having (y) a polarity converting group include repeating units having a lactone structure represented by formulae (KA-1-1) to (KA-1-17) to be described hereinafter.

Further, the repeating unit (by) having (y) a polarity converting group is preferably a repeating unit having at least either a fluorine atom and a silicon atom (that is, a repeating unit corresponding to the repeating unit (b′) or (b″)). The repeating unit (by)-containing resin has hydrophobicity, and addition thereof is preferred particularly from the viewpoint of reducing the development defect.

The repeating unit (by) includes, for example, a repeating unit represented by formula (KO):

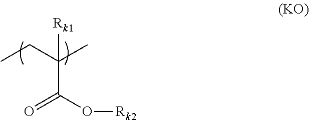

In the formula, Rₖ₁ represents a hydrogen atom, a halogen atom, a hydroxyl group, an alkyl group, a cycloalkyl group, an aryl group, or a polarity converting group-containing group.

Rₖ₂ represents an alkyl group, a cycloalkyl group, an aryl group, or a polarity converting group-containing group.

However, at least either one of Rₖ₁ and Rₖ₂ represents a polarity converting group-containing group.

The polarity converting group is, as described above, a group capable of decomposing by the action of an alkaline developer to increase the solubility in an alkaline developer. The polarity converting group is preferably a group X in a partial structure represented by formula (KA-1) or (KB-1):

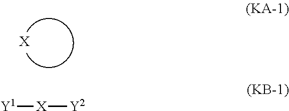

In formulae (KA-1) and (KB-1), X represents a carboxylic acid ester group: —COO—, an acid anhydride group: —C(O)OC(O)—, an acid imide group: —NHCONH—, a carboxylic acid thioester group: —COS—, a carbonic acid ester group: —OC(O)O—, a sulfuric acid ester group: —OSO₂O—, or a sulfonic acid ester group: —SO₂O—.

Each of Y¹ and Y², which may be the same or different, represents an electron-withdrawing group.

Incidentally, the repeating unit (by) has a preferred group capable of increasing the solubility in an alkaline developer by containing a group having a partial structure represented by formula (KA-1) or (KB-1), but as in the case of the partial structure represented by formula (KA-1) or the partial structure represented by formula (KB-1) where Y¹ and Y² are monovalent, when the partial structure does not have a bond, the group having the partial structure is a group having a monovalent or higher valent group formed by removing at least one arbitrary hydrogen atom in the partial structure.

The partial structure represented by formula (KA-1) or (KB-1) is connected to the main chain of the hydrophobic resin at an arbitrary position through a substituent.

The partial structure represented by formula (KA-1) is a structure forming a ring structure together with the group as X.

In formula (KA-1), X is preferably a carboxylic acid ester group (that is, a case of forming a lactone ring structure as KA-1), an acid anhydride group or a carbonic acid ester group, more preferably a carboxylic acid ester group.

The ring structure represented by formula (KA-1) may have a substituent and, for example, may have nka substituents Zₖₐ₁.

When a plurality of Zₖₐ₁'s are present, Z_{ka1's} each independently represent a halogen atom, an alkyl group, a cycloalkyl group, an ether group, a hydroxyl group, an amido group, an aryl group, a lactone ring group, or an electron-withdrawing group.

Zₖₐ₁'s may combine with each other to form a ring. Examples of the ring formed by combining Zₖₐ₁'s with each other include a cycloalkyl ring and a heterocyclic ring (e.g., a cyclic ether ring, or a lactone ring).

nka represents an integer of 0 to 10 and is preferably an integer of 0 to 8, more preferably an integer of 0 to 5, still more preferably an integer of 1 to 4, and most preferably an integer of 1 to 3.

The electron-withdrawing group as Zₖₐ₁ has the same meaning as the electron-withdrawing group of Y¹ and Y² to be described hereinafter. Incidentally, the electron-withdrawing group above may be substituted with another electron-withdrawing group.

Zₖₐ₁ is preferably an alkyl group, a cycloalkyl group, an ether group, a hydroxyl group or an electron-withdrawing group, more preferably an alkyl group, a cycloalkyl group or an electron-withdrawing group. The ether group is preferably an ether group substituted, for example, with an alkyl group or a cycloalkyl group, that is, an alkyl ether group. The electron-withdrawing group has the same meaning as above.

Examples of the halogen atom as Zₖₐ₁ include a fluorine atom, a chlorine atom, a bromine atom and an iodine atom, with a fluorine atom being preferred.

The alkyl group as Zₖₐ₁ may have a substituent and may be either linear or branched. The linear alkyl group is preferably an alkyl group having 1 to 30 carbon atoms, more preferably 1 to 20 carbon atoms, and examples thereof include a methyl group, an ethyl group, an n-propyl group, an n-butyl group, a sec-butyl group, a tert-butyl group, an n-pentyl group, an n-hexyl group, an n-heptyl group, an n-octyl group, an n-nonyl group and an n-decanyl group. The branched alkyl group is preferably an alkyl group having 3 to 30 carbon atoms, more preferably 3 to 20, and examples thereof include an i-propyl group, an i-butyl group, a tert-butyl group, an i-pentyl group, a tert-pentyl group, an i-hexyl group, a tert-hexyl group, an i-heptyl group, a tert-heptyl group, an i-octyl group, a tert-octyl group, an i-nonyl group and a tert-decanyl group. An alkyl group having 1 to 4 carbon atoms is preferred, such as a methyl group, an ethyl group, an n-propyl group, an i-propyl group, am n-butyl group, an i-butyl group and a tert-butyl group.

The cycloalkyl group as Zₖₐ₁ may have a substituent and may be monocyclic or polycyclic. The polycyclic cycloalkyl group may be crosslinked. That is, in this case, the cycloalkyl group may have a bridged structure. The monocyclic type is preferably a cycloalkyl group having 3 to 8 carbon atoms, and examples thereof include a cyclopropyl group, a cyclopentyl group, a cyclohexyl group, a cyclobutyl group and a cyclooctyl group. The polycyclic type includes a group having a bicyclo, tricyclo or tetracyclo structure or the like and having 5 or more carbon atoms. A cycloalkyl group having 6 to 20 carbon atoms is preferred, and examples thereof include an adamantyl group, a norbornyl group, an isobornyl group, a camphanyl group, a dicyclopentyl group, an α-pinel group, a tricyclodecanyl group, a tetracyclododecyl group and an androstanyl group. The following structures are also preferred as the cycloalkyl group. Incidentally, at least one of carbon atoms in the cycloalkyl group may be substituted with a hetero atom such as an oxygen atom.

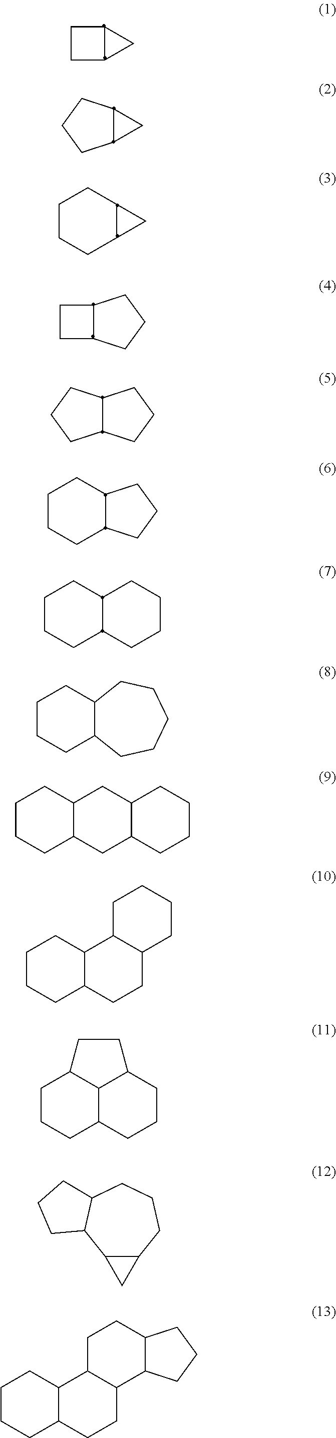

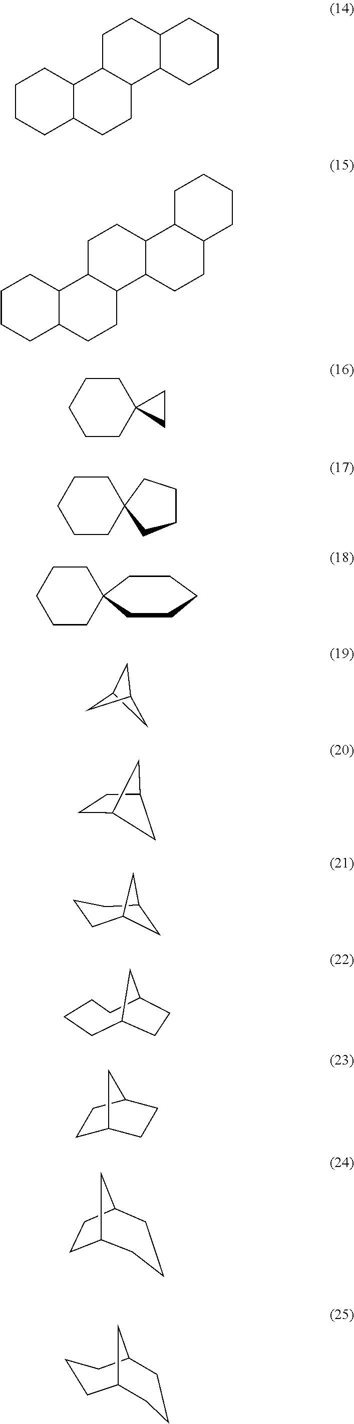

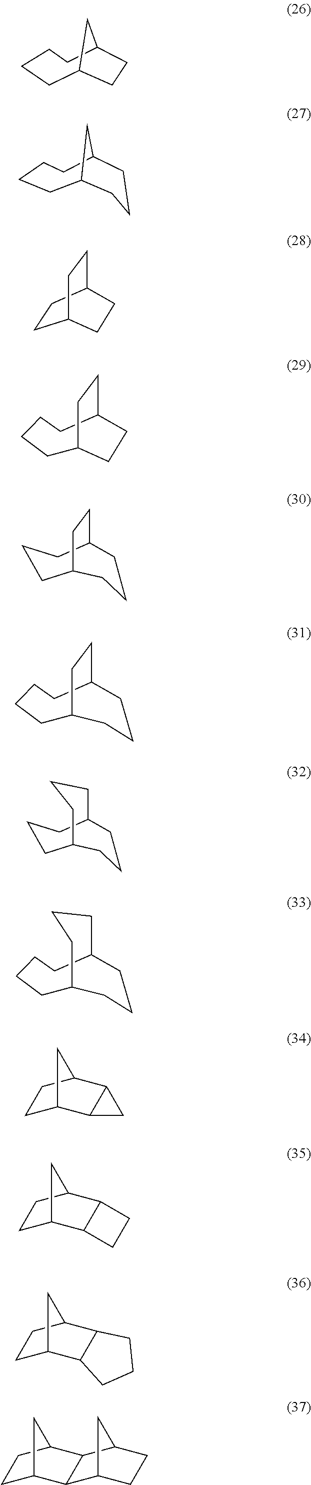

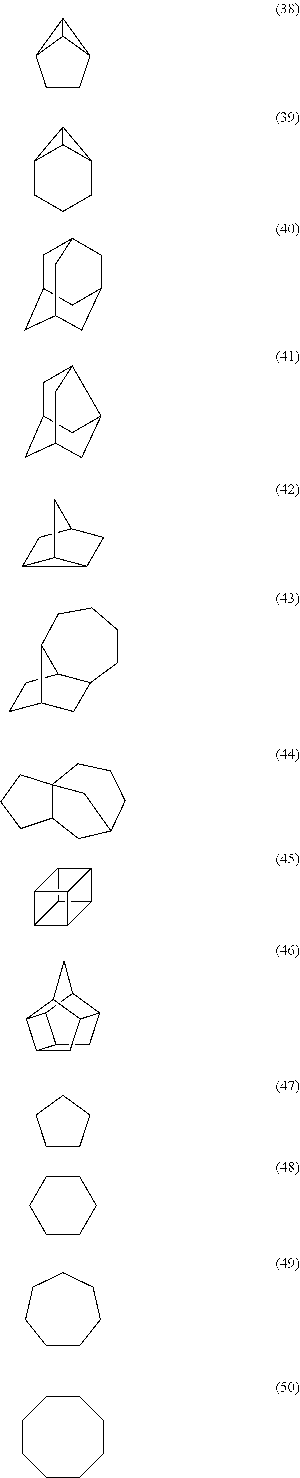

The alicyclic moiety is preferably an adamantyl group, a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group or a cyclododecanyl group, more preferably an adamantyl group, a decalin group, a norbornyl group, a cedrol group, a cyclohexyl group, a cycloheptyl group, a cyclooctyl group, a cyclodecanyl group, a cyclododecanyl group or a tricyclodecanyl group.

The substituent in such an alicyclic moiety includes an alkyl group, a halogen atom, a hydroxyl group, an alkoxy group, a carboxyl group and an alkoxycarbonyl group. The alkyl group is preferably a lower alkyl group such as a methyl group, an ethyl group, a propyl group, an isopropyl group or a butyl group, more preferably a methyl group, an ethyl group, a propyl group or an isopropyl group. The alkoxy group is preferably an alkoxy group having 1 to 4 carbon atoms, such as a methoxy group, an ethoxy group, a propoxy group or a butoxy group. Examples of the substituent that the alkyl group and alkoxy group may have include a hydroxyl group, a halogen atom and an alkoxy group (preferably having 1 to 4 carbon atoms).

Each of these groups may further have a substituent, and examples of the further substituent include a hydroxyl group, a halogen atom (e.g., fluorine, chlorine, bromine, or iodine), a nitro group, a cyano group, the foregoing alkyl group, an alkoxy group such as a methoxy group, an ethoxy group, a hydroxyethoxy group, a propoxy group, a hydroxypropoxy group, an n-butoxy group, an isobutoxy group, a sec-butoxy group or a tert-butoxy group, an alkoxycarbonyl group such as a methoxycarbonyl group or an ethoxycarbonyl group, an aralkyl group such as a benzyl group, a phenethyl group or a cumyl group, an aralkyloxy group, an acyl group such as a formyl group, an acetyl group, a butyryl group, a benzoyl group, a cinnamoyl group or a valeryl group, an acyloxy group such as a butyryloxy group, an alkenyl group such as a vinyl group, a propenyl group or an allyl group, an alkenyloxy group such as a vinyloxy group, a propenyloxy group, an allyloxy group or a butenyloxy group, an aryl group such as a phenyl group or a naphthyl group, an aryloxy group such as a phenoxy group, and an aryloxycarbonyl group such as a benzoyloxy group.

It is preferred that X in formula (KA-1) is a carboxylic acid ester group and the partial structure represented by formula (KA-1) is a lactone ring, and the lactone ring is preferably a 5- to 7-membered lactone ring.

In this connection, as in (KA-1-1) to (KA-1-17) described below, another ring structure is preferably fused to a 5- to 7-membered lactone ring that is the partial structure represented by formula (KA-1), in the form of forming a bicyclo or spiro structure.

Examples of the peripheral ring structure with which the ring structure represented by formula (KA-1) may combine include those in (KA-1-1) to (KA-1-17) and structures based on these structures.

The structure containing the lactone ring structure represented by formula (KA-1) is more preferably a structure represented by any one of the following (KA-1-1) to (KA-1-17). The lactone structure may be bonded directly to the main chain. Preferred structures are (KA-1-1), (KA-1-4), (KA-1-5), (KA-1-6), (KA-1-13), (KA-1-14), and (KA-1-17).

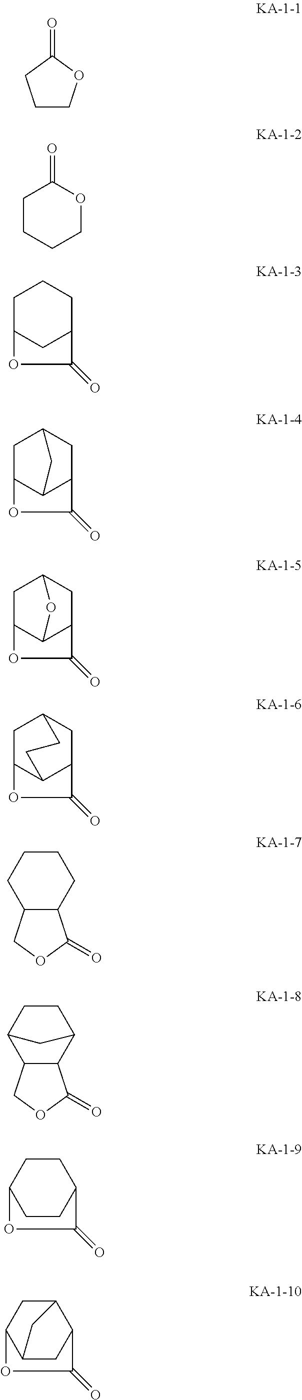

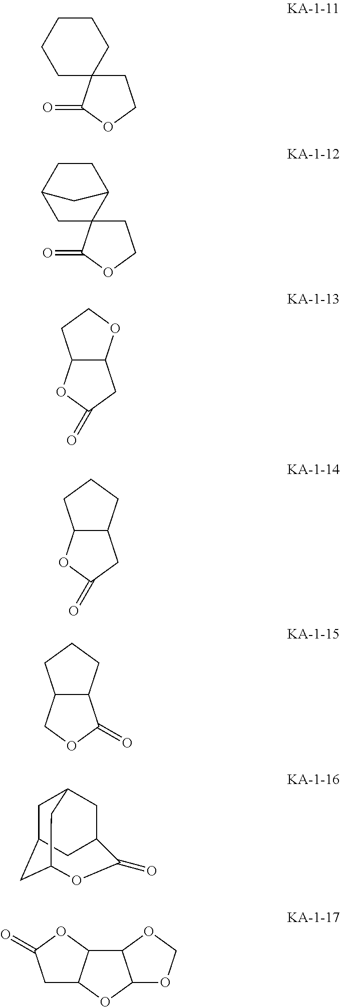

The structure containing the above-described lactone ring structure may or may not have a substituent. Preferred examples of the substituent are the same as those of the substituent Zₖₐ₁ which the ring structure represented by formula (KA-1) may have.

In formula (KB-1), X is preferably a carboxylic acid ester group (—COO—).

In formula (KB-1), Y¹ and Y² each independently represent an electron-withdrawing group.

The electron-withdrawing group is a partial structure represented by formula (EW) described below. In formula (EW), * indicates a direct bond to (KA-1) or a direct bond to X in (KB-1).

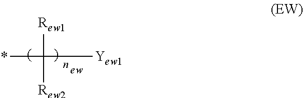

In formula (EW), n_{ew} is a repetition number of the linking group represented by —C(R_{ew1})(R_{ew2})— and represents an integer of 0 or 1. In the case where n_{ew} is 0, this indicates that the bond is a single bond and Y_{ew1} is directly bonded.

Y_{ew1} is a halogen atom, a cyano group, a nitrile group, a nitro group, a halo(cyclo)alkyl group represented by —C(R_{f1})(R_{f2})—R_{f3}, a haloaryl group, an oxy group, a carbonyl group, a sulfonyl group, a sulfinyl group, or a combination thereof. The electron-withdrawing group may be, for example, a structure shown below. The “halo(cyclo)alkyl group” indicates an alkyl or cycloalkyl group that is at least partially halogenated, and the “haloaryl group” indicates an aryl group that is at least partially halogenated. In the following structural formulae, R_{ew3} and R_{ew4} each independently represent an arbitrary structure. The partial structure represented by formula (EW) has an electron-withdrawing group regardless of what structure R_{ew3} or R_{ew4} may take, and each of R_{ew3} and R_{ew4} may be connected, for example, to the main chain of the resin but is preferably an alkyl group, a cycloalkyl group or an alkyl fluoride group.

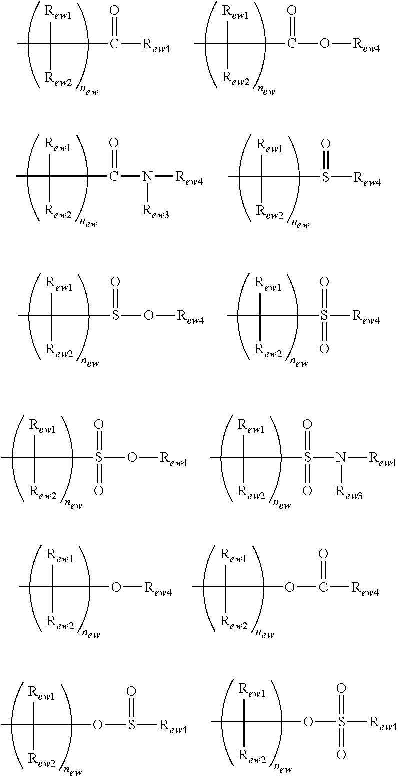

When Y_{ew1} is a divalent or higher valent group, the remaining bond forms bonding to an arbitrary atom or substituent. At least any one group of Y_{ew1}, R_{ew1} and R_{ew2} may be connected to the main chain of the hydrophobic resin through a further substituent.

Y_{ew1} is preferably a halogen atom, a halo(cyclo)alkyl group represented by —C(R_{f1})(R_{f2})—R_{f3} or a haloaryl group.

R_{ew1} and R_{ew2} each independently represent an arbitrary substituent, for example, represents a hydrogen atom, an alkyl group, a cycloalkyl group, or an aryl group.

At least two members out of R_{ew1}, R_{ew2} and Y_{ew1} may combine with each other to form a ring.

R_{f1} represents a halogen atom, a perhaloalkyl group, a perhalocycloalkyl group or a perhaloaryl group and is preferably a fluorine atom, a perfluoroalkyl group or a perfluorocycloalkyl group, more preferably a fluorine atom or a trifluoromethyl group.

R_{f2} and R_{f3} each independently represent a hydrogen atom, a halogen atom or an organic group, or alternatively R_{f2} and R_{f3} may combine to form a ring. Examples of the organic group include an alkyl group, a cycloalkyl group and an alkoxy group. R_{f2} is more preferably the same group as R_{f1} or combines with R_{f3} to form a ring.

R_{f1} to R_{f3} may combine to form a ring, and examples of the ring formed include a (halo)cycloalkyl ring and a (halo)aryl ring.

Examples of the (halo)alkyl group in R_{f1} to R_{f3} include the alkyl group in Zₖₐ₁ and halogenated structures thereof.

Examples of the (per)halocycloalkyl group and (per)haloaryl group in R_{f1} to R_{f3} or in the ring formed by combining R_{f2} and R_{f3} include structures resulting from halogenation of cycloalkyl groups in Zₖₐ₁, preferably a fluorocycloalkyl group represented by —C₍ₙ₎F₍₂ₙ₋₂₎H, and a perfluoroaryl group represented by —C(ₙ)F(ₙ₋₁), wherein the carbon number n is not particularly limited but is preferably from 5 to 13, more preferably 6.

The ring which may be formed by combining at least two members of R_{ew1}, R_{ew2} and Y_{ew1} with each other is preferably a cycloalkyl group or a heterocyclic group, and the heterocyclic group is preferably a lactone ring group. Examples of the lactone ring include structures represented by formulae (KA-1-1) to (KA-1-17).

Incidentally, the repeating unit (by) may have a plurality of partial structures represented by formula (KA-1), a plurality of partial structures represented by formula (KB-1), or both a partial structure of formula (KA-1) and a partial structure of formula (KB-1).

Here, the partial structure of formula (KA-1) may partially or entirely serve also as the electron-withdrawing group of Y¹ or Y² in formula (KB-1). For example, in the case where X in formula (KA-1) is a carboxylic acid ester group, the carboxylic acid ester group may function as an electron-withdrawing group of Y¹ or Y² in formula (KB-1).

In the case where the repeating unit (by) corresponds to the repeating unit (b*) or (b″) and has a partial structure represented by formula (KA-1), the partial structure represented by formula (KA-1) is more preferred when the polarity converting group is a partial structure represented by —COO— in the structure of formula (KA-1).

The repeating unit (by) may be a repeating unit having a partial structure represented by formula (KY-0).

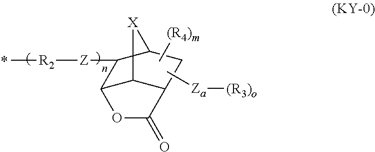

In formula (KY-0), R₂ represents a chain or cyclic alkylene group and when a plurality of R₂'s are present, each R₂ may be the same as or different from every other R₂.

R₃ represents a linear, branched or cyclic hydrocarbon group where a part or all of hydrogen atoms on the constituent carbons are substituted for by a fluorine atom.

R₄ represents a halogen atom, a cyano group, a hydroxy group, an amide group, an alkyl group, a cycloalkyl group, an alkoxy group, a phenyl group, an acyl group, an alkoxycarbonyl group or a group represented by R—C(═O)— or R—C(═O)O— (wherein R represents an alkyl group or a cycloalkyl group). When a plurality of R₄'s are present, each R₄ may be the same as or different from every other R₄, and two or more R₄'s may combine to form a ring.

X represents an alkylene group, an oxygen atom or a sulfur atom.

Each of Z and Za represents a single bond, an ether bond, an ester bond, an amide bond, a urethane bond or a urea bond and when a plurality of Z's or Za's are present, each Z or Za may be the same as or different from every other Z or Za.

* represents a bond to the main or side chain of the resin.

o is the number of substituents and represents an integer of 1 to 7.

m is the number of substituents and represents an integer of 0 to 7.

n is a repetition number and represents an integer of 0 to 5.

The structure of —R₂—Z— is preferably a structure represented by —(CH₂)ₗCOO— (wherein l represents an integer of 1 to 5).

The preferred carbon number range and specific examples of the chain or cyclic alkylene group as R₂ are the same as those described for the chain alkylene group and cyclic alkylene group in Z₂ of formula (bb).

The carbon number of the linear, branched or cyclic hydrocarbon group as R₃ is, in the case of a linear hydrocarbon group, preferably from 1 to 30, more preferably from 1 to 20; in the case of a branched hydrocarbon group, preferably from 3 to 30, more preferably from 3 to 20; and in the case of a cyclic hydrocarbon group, from 6 to 20. Specific examples of R₃ include specific examples of the alkyl group and cycloalkyl group as Zₖₐ₁ above.

The preferred carbon numbers and specific examples of the alkyl group and cycloalkyl group as R₄ and R are the same as those described above for the alkyl group and cycloalkyl group as Zₖₐ₁.

The acyl group as R₄ is preferably an acyl group having 1 to 6 carbon atoms, and examples thereof include a formyl group, an acetyl group, a propionyl group, a butyryl group, an isobutyryl group, a valeryl group and a pivaloyl group.

The alkyl moiety in the alkoxy group and alkoxycarbonyl group as R₄ includes a linear, branched or cyclic alkyl moiety, and the preferred carbon number and specific examples of the alkyl moiety are the same as those described above for the alkyl group and cycloalkyl group as Zₖₐ₁.

The alkylene group as X includes a chain or cyclic alkylene group, and the preferred carbon number and specific examples thereof are the same as those described for the chain alkylene group and cyclic alkylene group as R₂.

As for the specific structure of the repeating unit (by), the repeating unit also includes repeating units having a partial structure shown below.

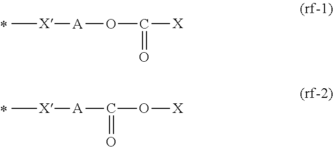

In formulae (rf-1) and (rf-2), X′ represents an electron-withdrawing substituent and is preferably a carbonyloxy group, an oxycarbonyl group, a fluorine atom-substituted alkylene group or a fluorine atom-substituted cycloalkylene group.

A represents a single bond or a divalent linking group represented by —C(Rx)(Ry)— wherein Rx and Ry each independently represent a hydrogen atom, a fluorine atom, an alkyl group (preferably having 1 to 6 carbon atoms; which may be substituted with a fluorine atom or the like), or a cycloalkyl group (preferably having 5 to 12 carbon atoms; which may be substituted with a fluorine atom or the like). Each of Rx and Ry is preferably a hydrogen atom, an alkyl group or a fluorine atom-substituted alkyl group.

X represents an electron-withdrawing group and specific examples thereof include those electron-withdrawing groups as Y¹ and Y² above. Among these, an alkyl fluoride group, a cycloalkyl fluoride group, an aryl group substituted with fluorine or an alkyl fluoride group, an aralkyl group substituted with fluorine or an alkyl fluoride group, a cyano group, and a nitro group are preferred.

* represents a bond to the main or side chain of the resin, that is, a bond to the main chain of the resin through a single bond or a linking group.

Incidentally, when X′ is a carbonyloxy group or an oxycarbonyl group, A is not a single bond.

The polarity converting group is decomposed by the action of an alkaline developer to effect polarity conversion, whereby the receding contact angle with water of the resin film after alkali development can be decreased. Decreasing the receding contact angle with water of the film after alkali development is preferred from the standpoint of suppressing the development defect.

The receding contact angle with water of the resin film after alkali development is preferably 50° or less, more preferably 40° or less, still more preferably 35° or less, and most preferably 30° or less, at a temperature of 23±3° C. and a humidity of 45±5%.

The receding contact angle is a contact angle measured when a contact line recedes on the liquid droplet-substrate interface, and this is generally known to be useful in simulating the mobility of a liquid droplet in the dynamic state. In a simple manner, the receding contact angle is defined as a contact angle at the time of the liquid droplet interface receding when a liquid droplet ejected from a needle tip is landed on a substrate and then the liquid droplet is again suctioned into the needle. In general, the receding contact angle may be measured by a contact angle measuring method called an expansion/contraction method.

The hydrolysis rate of the hydrophobic resin for an alkaline developer is preferably 0.001 nm/sec or more, more preferably 0.01 nm/sec or more, still more preferably 0.1 nm/sec or more, and most preferably 1 nm/sec or more.

Here, the hydrolysis rate of the hydrophobic resin for an alkaline developer is a rate at which the thickness of a resin film formed of only the hydrophobic resin decreases when treated with TMAH (an aqueous tetramethylammonium hydroxide solution) (2.38 mass %) at 23° C.

The repeating unit (by) is more preferably a repeating unit having at least two or more polarity converting groups.

In the case where the repeating unit (by) has at least two polarity converting groups, the repeating unit preferably has a group containing a partial structure having two polarity converting groups represented by the following formula (KY-1). Incidentally, when the structure represented by formula (KY-1) does not have a bond, this is a group containing a monovalent or higher valent group formed by removing at least one arbitrary hydrogen atom from the structure.

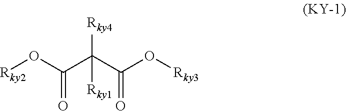

In formula (KY-1), R_{ky1} and R_{ky4} each independently represent a hydrogen atom, a halogen atom, an alkyl group, a cycloalkyl group, a carbonyl group, a carbonyloxy group, an oxycarbonyl group, an ether group, a hydroxyl group, a cyano group, an amide group or an aryl group. Alternatively, R_{ky1} and R_{ky4} may be bonded to the same atom to form a double bond. For example, R_{ky1} and R_{ky4} may be bonded to the same oxygen atom to form a part (═O) of a carbonyl group.

R_{ky2} and R_{ky3} each independently represent an electron-withdrawing group, or while R_{ky1} and Rₖ₂ combine to form a lactone ring, R_{ky3} is an electron-withdrawing group. The lactone ring formed is preferably a structure of (KA-1-1) to (KA-1-17). Examples of the electron-withdrawing group are the same as those for Y₁ and Y₂ in formula (KB-1), and a halogen atom, or a halo(cyclo)alkyl group or haloaryl group represented by —C(R_{f1})(R_{f2})—R_{f3} is preferred. Preferably, R_{ky3} is a halogen atom, or a halo(cyclo)alkyl group or haloaryl group represented by —C(R_{f1})(R_{f2})—R_{f3}, and R_{ky2} combines with R_{ky1} to form a lactone ring or is an electron-withdrawing group containing no halogen atom.

R_{ky1}, R_{ky2} and R_{ky4} may combine with each other to form a monocyclic or polycyclic structure.

Specific examples of R_{ky1} and R_{ky4} include the same groups as those for Zₖₐ₁ in formula (KA-1).

The lactone ring formed by combining R_{ky1} and R_{ky2} is preferably a structure of (KA-1-1) to (KA-1-17). Examples of the electron-withdrawing group are the same as those for Y₁ and Y₂ in formula (KB-1).

The structure represented by formula (KY-1) is preferably a structure represented by the following formula (KY-2). Here, the structure represented by formula (KY-2) is a group having a monovalent or higher valent group formed by removing at least one arbitrary hydrogen atom from the structure.

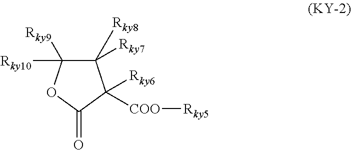

In formula (KY-2), R_{ky6} to R_{ky10} each independently represent a hydrogen atom, a halogen atom, an alkyl group, a cycloalkyl group, a carbonyl group, a carbonyloxy group, an oxycarbonyl group, an ether group, a hydroxyl group, a cyano group, an amide group or an aryl group.

Two or more members of R_{ky6} to R_{ky10} may combine with each other to form a monocyclic or polycyclic structure.

R_{ky5} represents an electron-withdrawing group. Examples of the electron-withdrawing group are the same as those for Y₁ and Y₂ above, and among these, a halogen atom, or a halo(cyclo)alkyl group or haloaryl group represented by —C(R_{f1})(R_{f2})—R_{f3} is preferred.

Specific examples of R_{ky5} to R_{ky10} include the same groups as those for Zₖₐ₁ in formula (KA-1).

The structure represented by formula (KY-2) is preferably a partial structure represented by the following formula (KY-3):

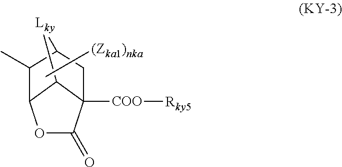

In formula (KY-3), Zₖₐ₁ and nka have the same meanings as in formula (KA-1). R_{ky5} has the same meaning as in formula (KY-2).

L_{ky} represents an alkylene group, an oxygen atom or a sulfur atom. Examples of the alkylene group of L_{ky} include a methylene group and an ethylene group. L_{ky} is preferably an oxygen atom or a methylene group, and more preferably a methylene group.

The repeating unit (b) is not limited as long as it is a repeating unit obtained by polymerization such as addition polymerization, condensation polymerization or addition condensation, but this repeating unit is preferably a repeating unit obtained by addition polymerization of a carbon-carbon double bond. Examples thereof include an acrylate-based repeating unit (including a system having a substituent at the α- or β-position), a styrene-based repeating unit (including a system having a substituent at the α- or β-position), a vinyl ether-based repeating unit, a norbornene-based repeating unit, and a maleic acid derivative (such as a maleic anhydride or its derivative, or maleimide) repeating unit. An acrylate-based repeating unit, a styrene-based repeating unit, a vinyl ether-based repeating unit and a norbornene-based repeating unit are preferred, an acrylate-based repeating unit, a vinyl ether-based repeating unit and a norbornene-based repeating unit are more preferred, and an acrylate-based repeating unit is most preferred.

In the case where the repeating unit (by) is a repeating unit having at least either a fluorine atom or a silicon atom (that is, a repeating unit corresponding to the repeating unit (b′) or (b″)), examples of the fluorine atom-containing partial structure in the repeating unit (by) are the same as those in the repeating unit having at least either a fluorine atom or a silicon atom, and the groups represented by formula (F2) to (F4) are preferred. Also, examples of the silicon atom-containing partial structure in the repeating unit (by) are the same as those in the repeating unit having at least either a fluorine atom or a silicon atom, and the groups represented by formulae (CS-1) to (CS-3) are preferred.

In the hydrophobic resin, the content of the repeating unit (by) is preferably from 10 to 100 mol %, more preferably from 20 to 99 mol %, still more preferably from 30 to 97 mol %, and most preferably from 40 to 95 mol %, based on all repeating units in the hydrophobic resin.

Specific examples of the repeating unit (by) having a group capable of increasing the solubility in an alkaline developer are illustrated below, but the present invention is not limited thereto. Specific examples of the repeating unit (a3) of the resin (A) are also included in specific examples of the repeating unit (by).

In specific examples shown below, Ra represents a hydrogen atom, a fluorine atom, a methyl group or a trifluoromethyl group.

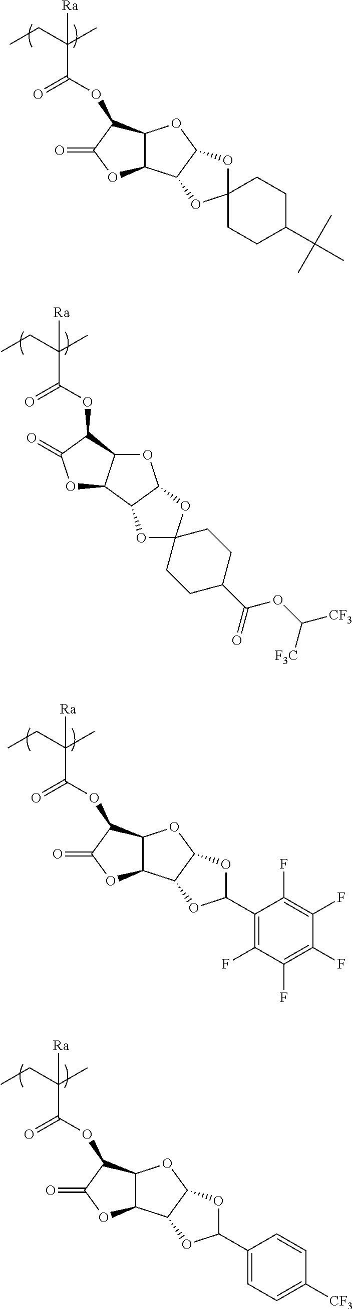

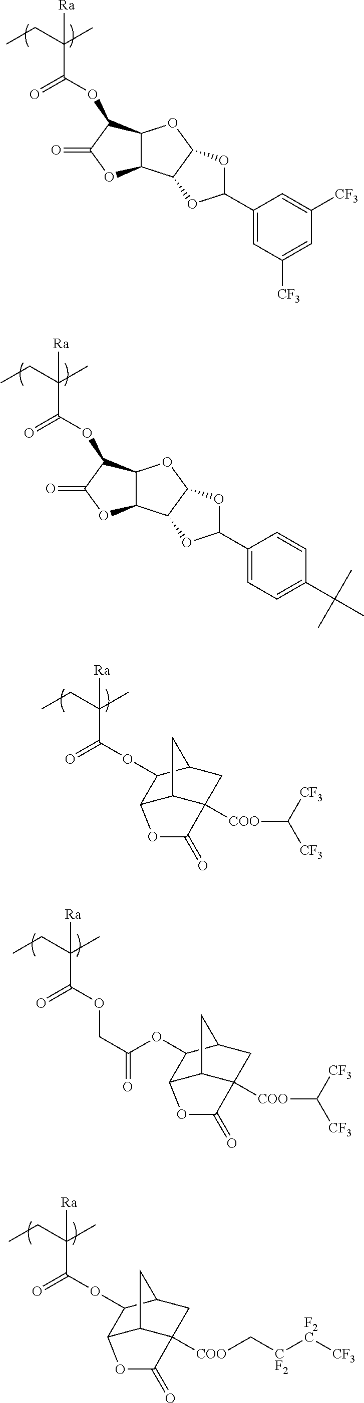

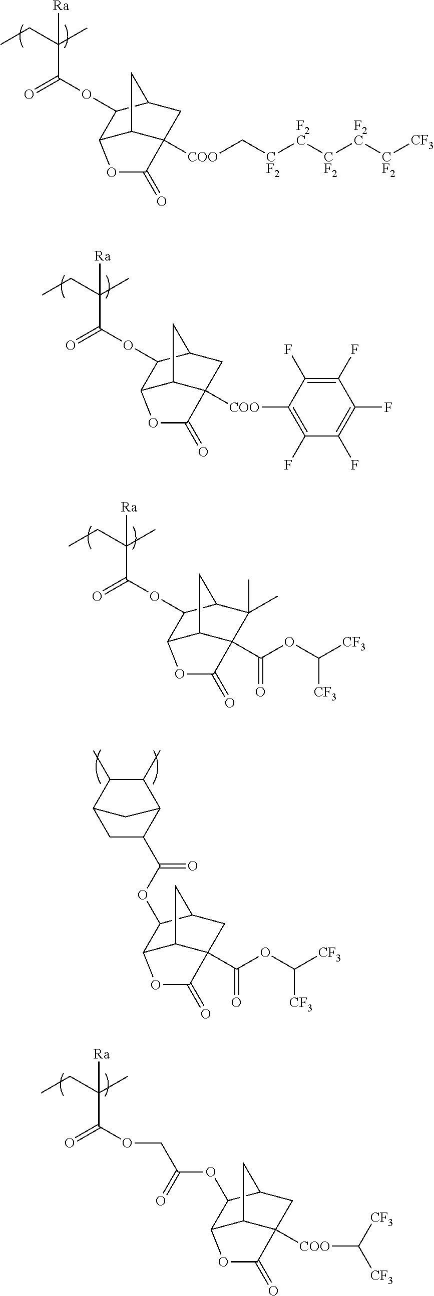

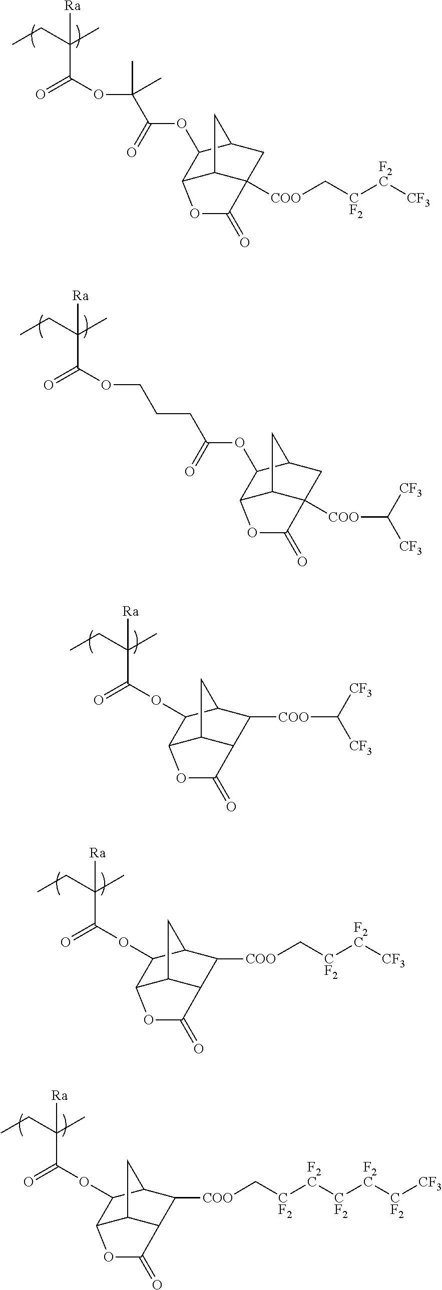

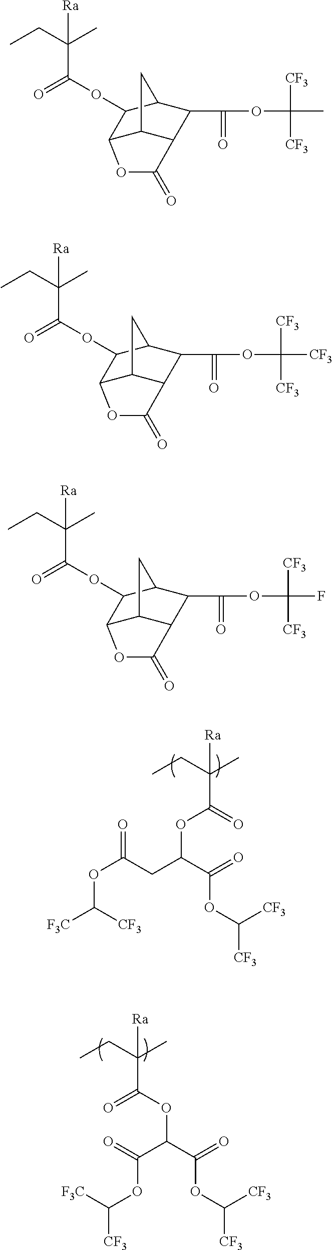

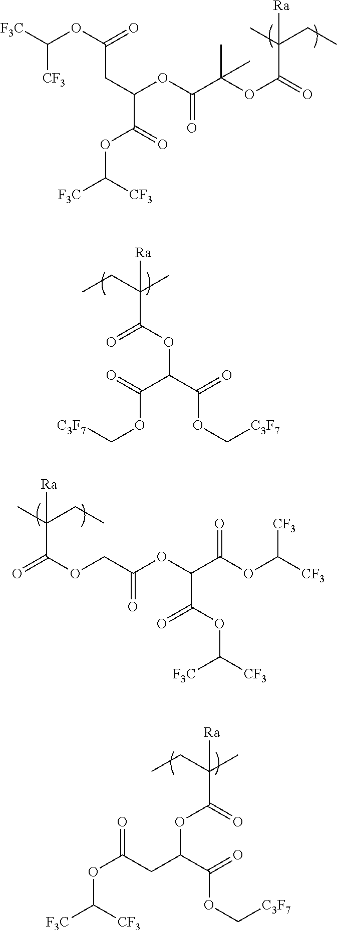

Synthesis of monomers corresponding to the repeating unit (by) having the polarity converting group (y) as described above may be carried out, for example, with reference to the method disclosed in WO2010/067905A or WO2010/067905A.

In the hydrophobic resin, examples of the repeating unit (bz) having a group (z) capable of decomposing by the action of an acid are the same as those described for the repeating unit having an acid-decomposable group in the resin (A).

In the case where the repeating unit (bz) is a repeating unit having at least either a fluorine atom or a silicon atom (that is, a repeating unit corresponding to the repeating unit (b′) or (b″)), examples of the fluorine atom-containing partial structure in the repeating unit (bz) are the same as those described for the repeating unit having at least either a fluorine atom or a silicon atom and preferably include the groups represented by formulae (F2) to (F4). Also in this case, examples of the silicon atom-containing partial structure in the repeating unit (by) are the same as those described for the repeating unit having at least either a fluorine atom or a silicon atom and preferably include the groups represented by formulae (CS-1) to (CS-3).

In the hydrophobic resin, the content of the repeating unit (bz) having a group (z) capable of decomposing by the action of an acid is preferably from 1 to 80 mol %, more preferably from 10 to 80 mol %, and still more preferably from 20 to 60 mol %, based on all repeating units in the hydrophobic resin.

The repeating unit (b) having at least one group selected from the group consisting of (x) to (z) was described as above, but the content of the repeating unit (b) in the hydrophobic resin is preferably from 1 to 98 mol %, more preferably from 3 to 98 mol %, still more preferably from 5 to 97 mol %, and most preferably from 10 to 95 mol %, based on all repeating units in the hydrophobic resin.

The content of the repeating unit (b′) is preferably from 1 to 100 mol %, more preferably from 3 to 99 mol %, still more preferably from 5 to 97 mol %, and most preferably from 10 to 95 mol %, based on all repeating units in the hydrophobic resin.

The content of the repeating unit (b*) is preferably from 1 to 90 mol %, more preferably from 3 to 80 mol %, still more preferably 5 to 70 mol %, and most preferably 10 to 60 mol %, based on all repeating units in the hydrophobic resin. The content of the repeating unit having at least either a fluorine atom or a silicon atom, which is used together with the repeating unit (b*) is preferably from 10 to 99 mol %, more preferably from 20 to 97 mol %, still more preferably from 30 to 95 mol %, and most preferably from 40 to 90 mol %, based on all repeating units in the hydrophobic resin.

The content of the repeating unit (b″) is preferably from 1 to 100 mol %, more preferably from 3 to 99 mol %, more preferably from 5 to 97 mol %, and most preferably from 10 to 95 mol %, based on all repeating units in the hydrophobic resin.

The hydrophobic resin may further contain a repeating unit represented by the following formula (CIII):

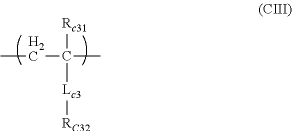

In formula (CIII), R_{c31} represents a hydrogen atom, an alkyl group (which may be substituted with a fluorine atom or the like), a cyano group or a —CH₂—O—R_{ac2} group wherein

R_{ac2} represents a hydrogen atom, an alkyl group or an acyl group. R_{c31} is preferably a hydrogen atom, a methyl group, a hydroxymethyl group or a trifluoromethyl group, and more preferably a hydrogen atom or a methyl group.

R_{c32} represents a group having an alkyl group, a cycloalkyl group, an alkenyl group, a cycloalkenyl group or an aryl group. Each of these groups may be substituted with a fluorine atom- or silicon atom-containing group or the like.

L_{c3} represents a single bond or a divalent linking group.

In formula (CIII), the alkyl group of R_{c32} is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, more preferably a phenyl group or a naphthyl group, each of which may have a substituent.

R_{c32} is preferably an unsubstituted alkyl group or a fluorine atom-substituted alkyl group.

The divalent linking group of L_{c3} is preferably an alkylene group (preferably having 1 to 5 carbon atoms), an oxy group, a phenylene group or an ester bond (a group represented by —COO—).

It is also preferred that the hydrophobic resin further contains a repeating unit represented by the following formula (BII-AB):

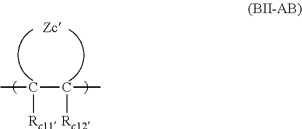

In formula (BII-AB), R_{c11}′ and R_{c12}′ each independently represent a hydrogen atom, a cyano group, a halogen atom or an alkyl group.

Z_{c}′ represents an atomic group for forming an alicyclic structure containing two carbon atoms (C—C) to which Z_{c}′ is bonded.

In the case where each group in the repeating units represented by formulae (III) and (BII-AB) is substituted with a fluorine atom- or silicon atom-containing group, the repeating unit corresponds also to the repeating unit having at least either a fluorine atom or a silicon atom.

Specific examples of the repeating units represented by formulae (III) and (BII-AB) are illustrated below, but the present invention is not limited thereto. In the formulae, Ra represents H, CH₃, CH₂OH, CF₃ or CN. Incidentally, the repeating unit where Ra is CF₃ corresponds also to the repeating unit having at least either a fluorine atom or a silicon atom.

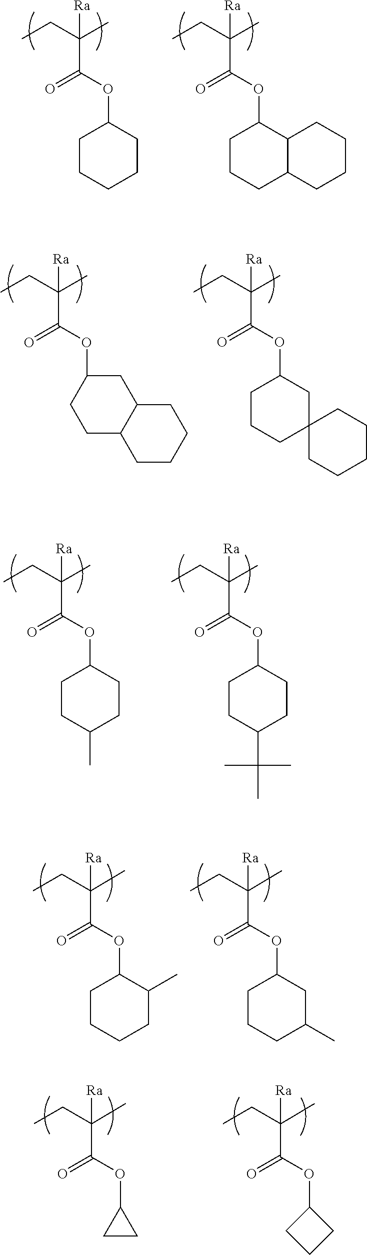

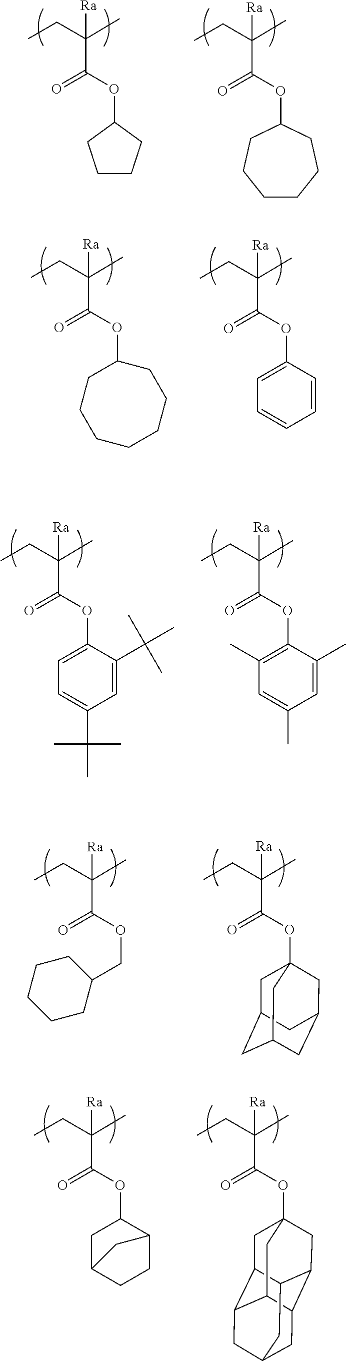

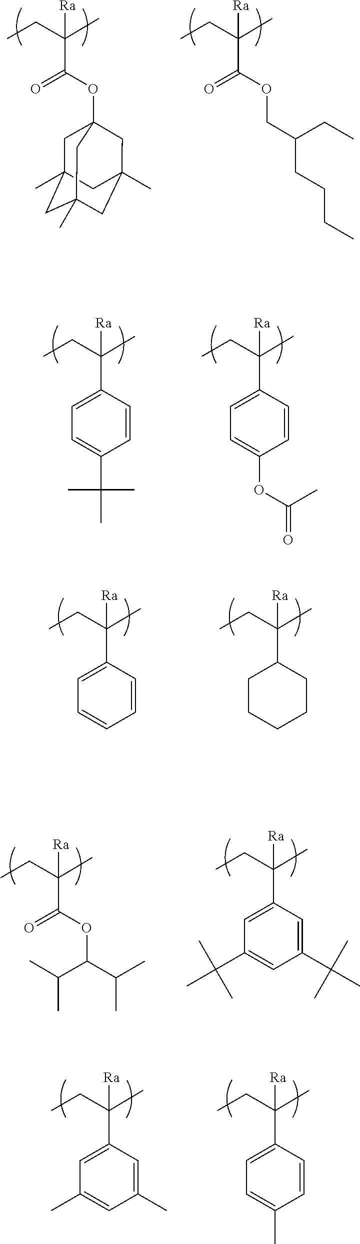

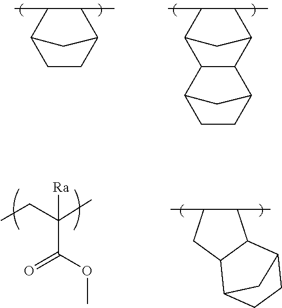

In the hydrophobic resin, similarly to the resin (B), it is of course preferred that the content of impurities such as metals is low, but also, the content of residual monomers or oligomer components is preferably from 0 to 10 mass %, more preferably from 0 to 5 mass %, and still more preferably from 0 to 1 mass %. When these conditions are satisfied, a resist composition free from foreign substances in liquid or change with aging of sensitivity or the like can be obtained. Furthermore, in view of resolution, resist profile, side wall of resist pattern, roughness and the like, the molecular weight distribution (Mw/Mn, also referred to as “dispersity”) is preferably from 1 to 3, more preferably from 1 to 2, still more preferably from 1 to 1.8, and most preferably from 1 to 1.5.

As for the hydrophobic resin, various commercially available products may be also used, or the resin may be synthesized by a conventional method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred.

The reaction solvent, the polymerization initiator, the reaction conditions (e.g., temperature, concentration) and the purification method after reaction are the same as those described for the resin (B).

Specific examples of the hydrophobic resin (HR) are illustrated below. Also, the molar ratio of repeating units (corresponding to repeating units starting from the left), weight average molecular weight and dispersity of each resin are shown in Table 1 below.

TABLE 1

| Polymer | Ratio (mol %) | Mw | Mw/Mn |
|---|---|---|---|
| B-1 | 50/50 | 6000 | 1.5 |
| B-2 | 30/70 | 6500 | 1.4 |
| B-3 | 45/55 | 8000 | 1.4 |
| B-4 | 100 | 15000 | 1.7 |
| B-5 | 60/40 | 6000 | 1.4 |
| B-6 | 40/60 | 8000 | 1.4 |
| B-7 | 30/40/30 | 8000 | 1.4 |
| B-8 | 60/40 | 8000 | 1.3 |
| B-9 | 50/50 | 6000 | 1.4 |
| B-10 | 40/40/20 | 7000 | 1.4 |
| B-11 | 40/30/30 | 9000 | 1.6 |
| B-12 | 30/30/40 | 6000 | 1.4 |
| B-13 | 60/40 | 9500 | 1.4 |
| B-14 | 60/40 | 8000 | 1.4 |
| B-15 | 35/35/30 | 7000 | 1.4 |
| B-16 | 50/40/5/5 | 6800 | 1.3 |
| B-17 | 20/30/50 | 8000 | 1.4 |
| B-18 | 25/25/50 | 6000 | 1.4 |
| B-19 | 100 | 9500 | 1.5 |
| B-20 | 100 | 7000 | 1.5 |
| B-21 | 50/50 | 6000 | 1.6 |
| B-22 | 40/60 | 9600 | 1.3 |
| B-23 | 100 | 20000 | 1.7 |
| B-24 | 100 | 25000 | 1.4 |
| B-25 | 100 | 15000 | 1.7 |
| B-26 | 100 | 12000 | 1.8 |
| B-27 | 100 | 18000 | 1.3 |
| B-28 | 70/30 | 15000 | 2.0 |
| B-29 | 80/15/5 | 18000 | 1.8 |
| B-30 | 60/40 | 25000 | 1.8 |
| B-31 | 90/10 | 19000 | 1.6 |
| B-32 | 60/40 | 20000 | 1.8 |
| B-33 | 50/30/20 | 11000 | 1.6 |
| B-34 | 60/40 | 12000 | 1.8 |
| B-35 | 60/40 | 15000 | 1.6 |
| B-36 | 100 | 22000 | 1.8 |
| B-37 | 20/80 | 35000 | 1.6 |
| B-38 | 30/70 | 12000 | 1.7 |
| B-39 | 30/70 | 9000 | 1.5 |
| B-40 | 100 | 9000 | 1.5 |
| B-41 | 40/15/45 | 12000 | 1.9 |
| B-42 | 30/30/40 | 13000 | 2.0 |
| B-43 | 40/40/20 | 23000 | 2.1 |
| B-44 | 65/30/5 | 25000 | 1.6 |
| B-45 | 100 | 15000 | 1.7 |
| B-46 | 20/80 | 9000 | 1.7 |
| B-47 | 70/30 | 18000 | 1.5 |
| B-48 | 60/20/20 | 18000 | 1.8 |
| B-49 | 100 | 12000 | 1.4 |
| B-50 | 60/40 | 20000 | 1.6 |
| B-51 | 70/30 | 33000 | 2.0 |
| B-52 | 60/40 | 19000 | 1.8 |
| B-53 | 50/50 | 15000 | 1.5 |
| B-54 | 40/20/40 | 35000 | 1.9 |
| B-55 | 100 | 16000 | 1.4 |

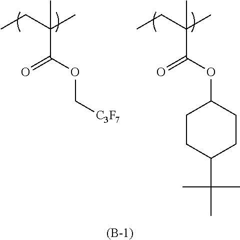

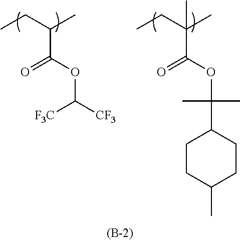

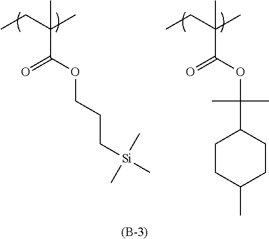

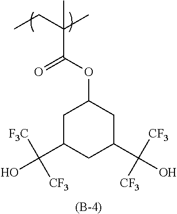

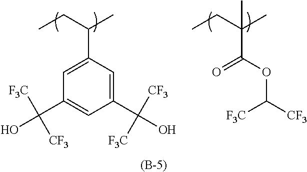

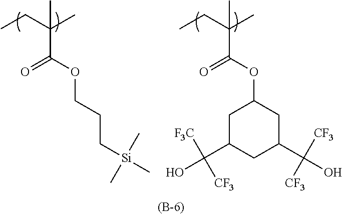

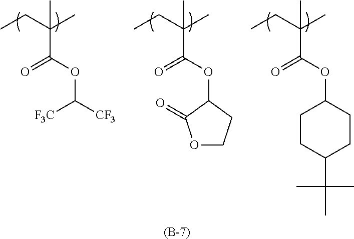

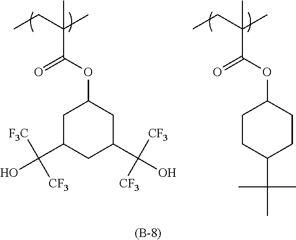

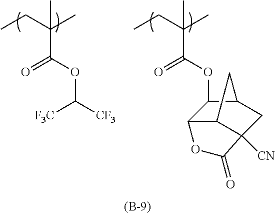

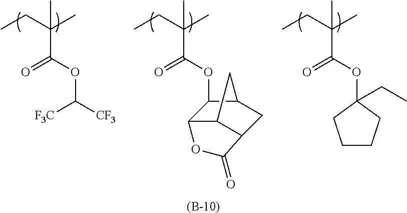

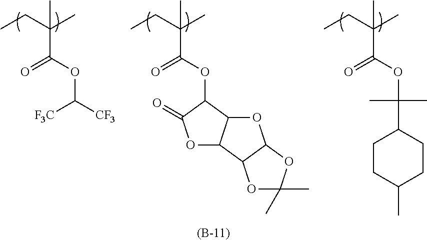

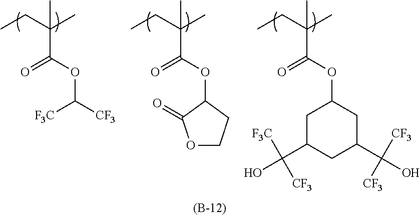

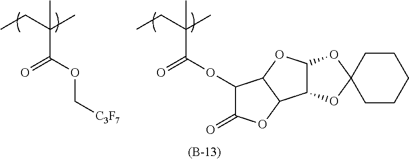

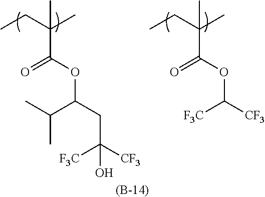

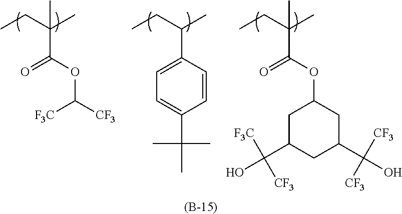

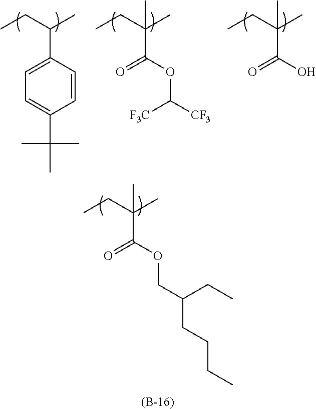

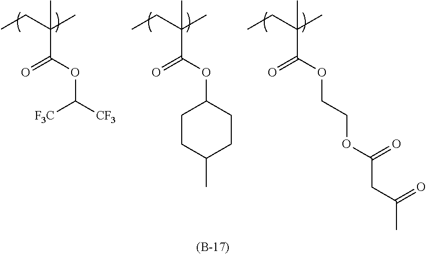

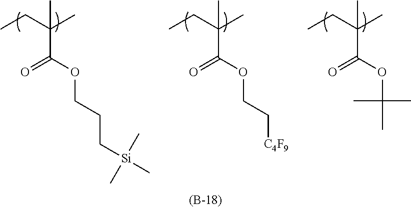

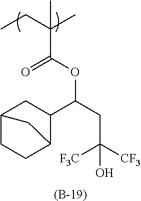

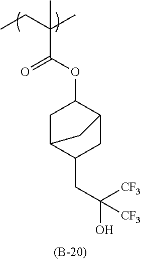

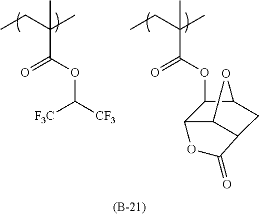

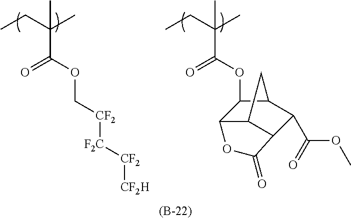

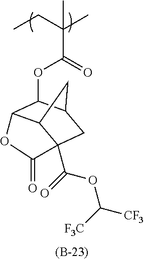

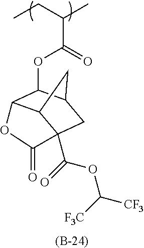

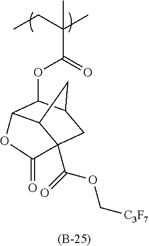

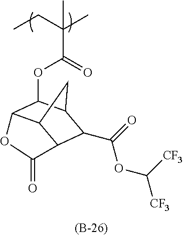

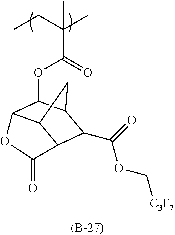

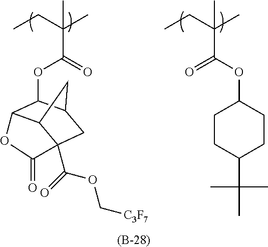

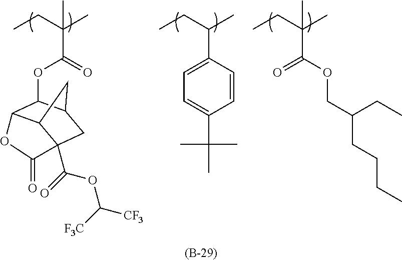

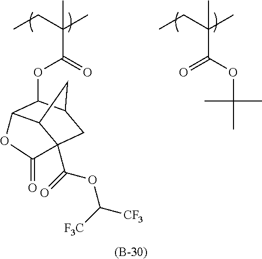

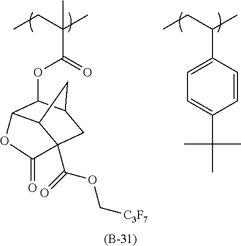

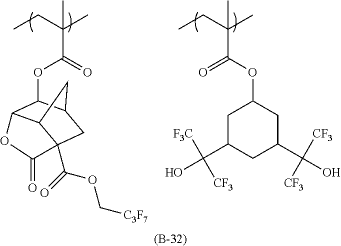

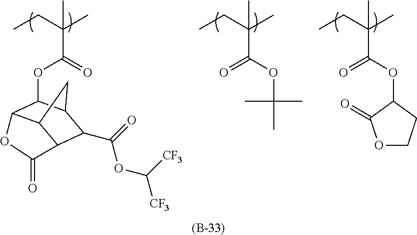

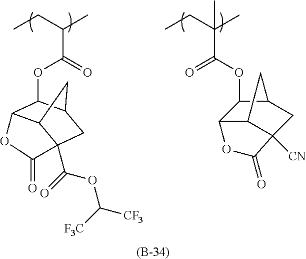

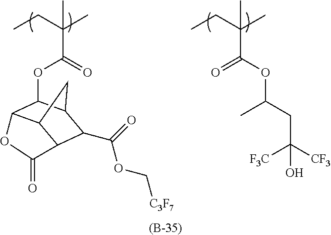

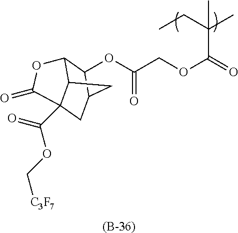

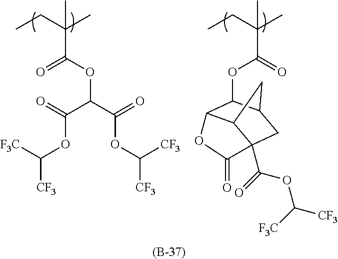

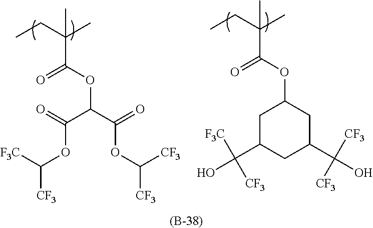

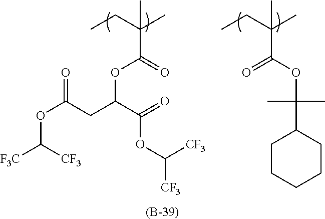

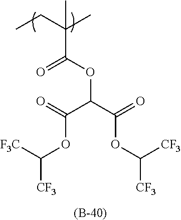

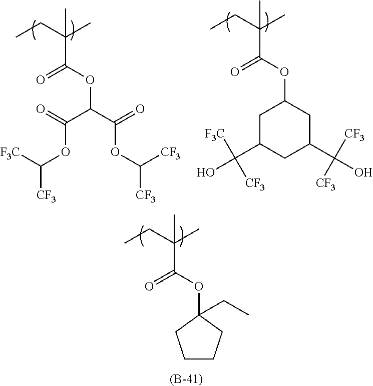

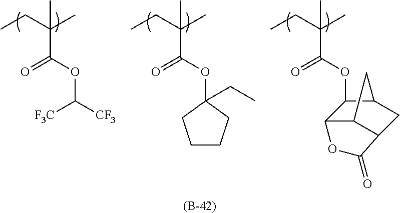

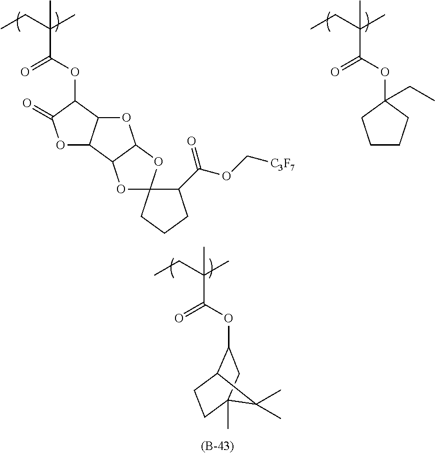

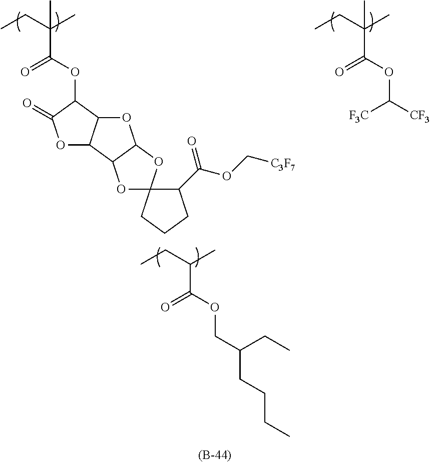

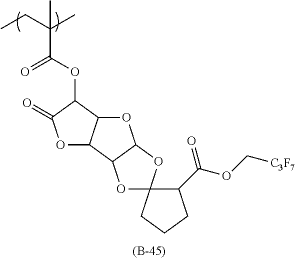

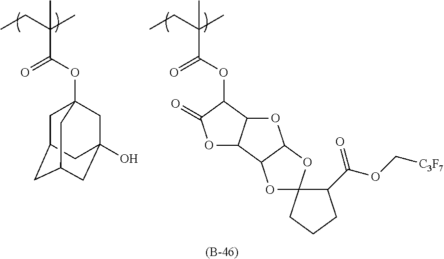

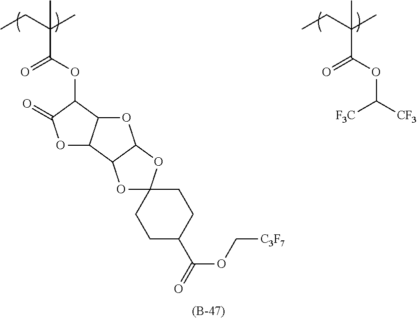

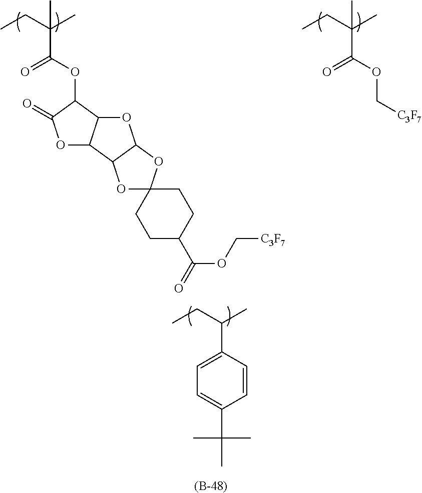

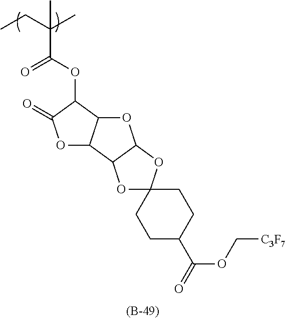

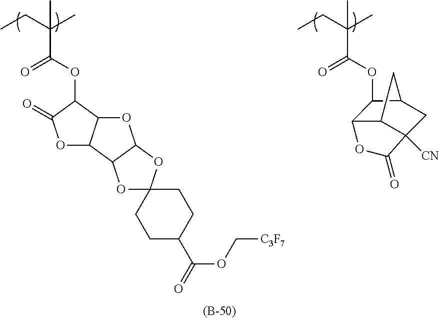

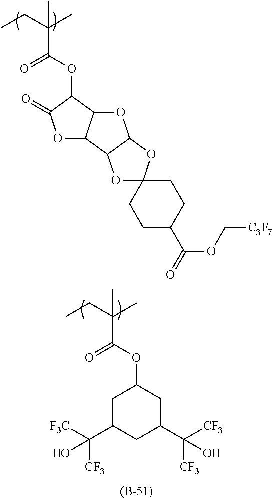

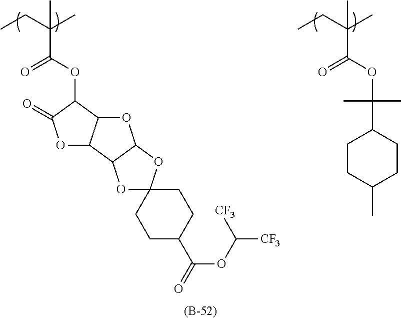

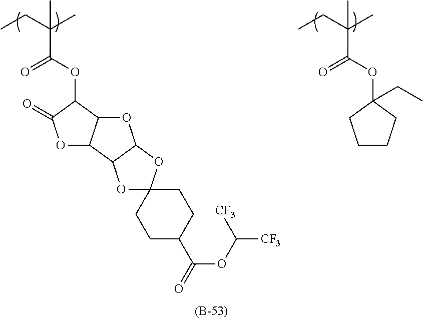

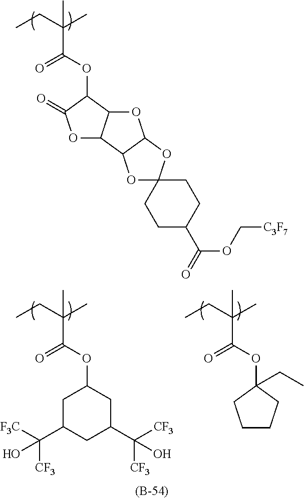

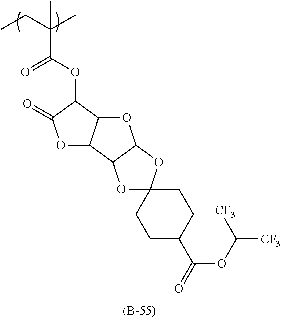

Since the hydrophobic resin containing at least either a fluorine atom or a silicon atom is contained in the actinic-ray-sensitive or radiation-sensitive resin composition of the present invention, the hydrophobic resin is unevenly distributed to a surface layer of the film formed from the actinic-ray-sensitive or radiation-sensitive resin composition and when the immersion medium is water, the receding contact angle of the film surface with water after baking and before exposure can be increased to thereby enhance followability of the immersion liquid.

The receding contact angle of the film of the actinic-ray-sensitive or radiation-sensitive resin composition of the present invention that has been baked but is not yet exposed, as measured at the exposure temperature, generally room temperature of 23±3° C. and a humidity of 45±5%, is preferably in the range of 60° to 90°, more preferably 65° or greater, still more preferably 70° or greater and most preferably 75° or greater.

The hydrophobic resin is, as described above, unevenly distributed to the interface but unlike a surfactant, need not have necessarily a hydrophilic group in the molecule and may not contribute to uniform mixing of polar/nonpolar substances.

In the immersion exposure step, the immersion liquid needs to move on a wafer following the movement of an exposure head that is scanning the wafer at a high speed and forming an exposure pattern. Therefore, the contact angle of the immersion liquid with the resist film in a dynamic state is important, and the resist is required to have a performance of allowing liquid droplets to follow the high-speed scanning of an exposure head without leaving any liquid droplet.

As the hydrophobic resin is hydrophobic, the problems of development residue (scum) and blob defect after alkali development are likely to become serious. However, improvement of performance in terms of the development residue (scum) and blob defect can be attained due to an increase in alkali dissolution rate by containing three or more polymer chains combined together through at least one branch point, as compared with linear chain resins.

When the hydrophobic resin contains a fluorine atom, the content of the fluorine atoms is preferably from 5 to 80 mass %, and more preferably from 10 to 80 mass %, based on the molecular weight of the hydrophobic resin. The proportion of the repeating unit containing a fluorine atom is preferably from 10 to 100 mol %, and more preferably 30 to 100 mol %, based on all repeating units in the hydrophobic resin.

When the hydrophobic resin contains a silicon atom, the content of the silicon atoms is preferably from 2 to 50 mass %, and more preferably from 2 to 30 mass %, based on the molecular weight of the hydrophobic resin. The proportion of the repeating unit containing a silicon atom is preferably from 10 to 90 mol %, and more preferably 20 to 80 mol %, based on all the repeating units of the hydrophobic resin.

The weight average molecular weight of the hydrophobic resin is preferably in the range of 1000 to 100,000, more preferably 2000 to 50,000 and still more preferably 3000 to 35,000. Here, the weight average molecular weight of the resin indicates a molecular weight in terms of polystyrene measured by GPC (carrier: tetrahydrofuran (THF)). Specifically, the weight average molecular weight of the resin was measured by using, for example, HLC-8120 (available from Tosoh Corporation) using TSK gel Multipore HXL-M (available from Tosoh Corporation, 7.8 mmID×30.0 cm) as a column and tetrahydrofuran (THF) as an eluent. The content of the hydrophobic resin in the actinic-ray-sensitive or radiation-sensitive resin composition may be adjusted prior to use so that the receding contact angle of the film formed of the actinic-ray-sensitive or radiation-sensitive resin composition falls within the above-specified range. The content of the hydrophobic resin is preferably in the range of 0.01 to 20 mass %, more preferably 0.1 to 15 mass %, still more preferably 0.1 to 10 mass % and most preferably 0.5 to 8 mass %, based on the total solid content of the actinic-ray-sensitive or radiation-sensitive resin composition.

The hydrophobic resins may be used alone or in combination of two or more thereof.

[4] Basic Compound

The actinic-ray-sensitive or radiation-sensitive resin composition of the present invention preferably contains a basic compound so as to reduce the change in performance with aging from exposure to heating.

Preferred basic compounds include a compound having a structure represented by the following formulae (A) to (E):

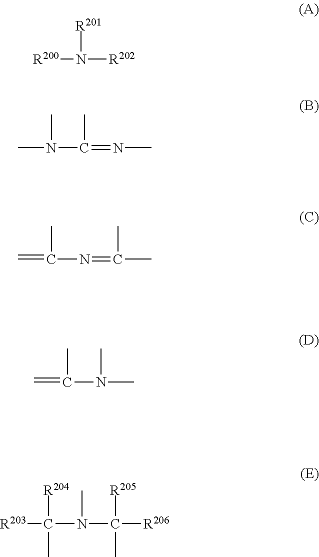

In formulae (A) and (E), R²⁰⁰, R²⁰¹ and R²⁰², which may be the same or different, represent a hydrogen atom, an alkyl group (preferably having 1 to 20 carbon atoms), a cycloalkyl group (preferably having 3 to 20 carbon atoms) or an aryl group (having 6 to 20 carbon atoms), and R²⁰¹ and R²⁰² may combine together to form a ring.

R²⁰³, R²⁰⁴, R²⁰⁵ and R²⁰⁶, which may be the same or different, represent an alkyl group having 1 to 20 carbon atoms.

As for the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl group in formulae (A) and (E) is more preferably unsubstituted.

Preferred examples of the compound include guanidine, aminopyrrolidine, pyrazole, pyrazoline, piperazine, aminomorpholine, aminoalkylmorpholine and piperidine. More preferred examples of the compound include a compound having an imidazole structure, a diazabicyclo structure, an onium hydroxide structure, an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

Examples of the compound having an imidazole structure include imidazole, 2,4,5-triphenylimidazole, benzimidazole and 2-phenylbenzimidazole. Examples of the compound having a diazabicyclo structure include 1,4-diazabicyclo[2,2,2]octane, 1,5-diazabicyclo[4,3,0]non-5-ene and 1,8-diazabicyclo[5,4,0]undec-7-ene. Examples of the compound having an onium hydroxide structure include tetrabutylammonium hydroxide, a triarylsulfonium hydroxide, a phenacylsulfonium hydroxide, and a sulfonium hydroxide having a 2-oxoalkyl group, specifically, triphenylsulfonium hydroxide, tris(tert-butylphenyl)sulfonium hydroxide, bis(tert-butylphenyl)iodonium hydroxide, phenacylthiophenium hydroxide and 2-oxopropylthiophenium hydroxide. The compound having an onium carboxylate structure is a compound where the anion moiety of the compound having an onium hydroxide structure becomes a carboxylate, and examples thereof include an acetate, an adamantane-1-carboxylate and a perfluoroalkyl carboxylate. Examples of the compound having a trialkylamine structure include tri(n-butyl)amine and tri(n-octyl)amine. Examples of the aniline compound include 2,6-diisopropylaniline, N,N-dimethylaniline, N,N-dibutylaniline and N,N-dihexylaniline. Examples of the alkylamine derivative having a hydroxyl group and/or an ether bond include ethanolamine, diethanolamine, triethanolamine, N-phenyldiethanolamine and tris(methoxyethoxyethyl)amine. Examples of the aniline derivative having a hydroxyl group and/or an ether bond include N,N-bis(hydroxyethyl)aniline.

Other preferred basic compounds include a phenoxy group-containing amine compound, a phenoxy group-containing ammonium salt compound, a sulfonic acid ester group-containing amine compound and a sulfonic acid ester group-containing ammonium salt compound.

As for the amine compound, a primary, secondary or tertiary amine compound may be used, and an amine compound where at least one alkyl group is bonded to the nitrogen atom is preferred. The amine compound is more preferably a tertiary amine compound. In the amine compound, as long as at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms) may be bonded to the nitrogen atom in addition to the alkyl group. The amine compound preferably has an oxygen atom in the alkyl chain to form an oxyalkylene group. The number of oxyalkylene groups within the molecule is 1 or more, preferably from 3 to 9, and more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

As for the ammonium salt compound, a primary, secondary, tertiary or quaternary ammonium salt compound may be used, and an ammonium salt compound where at least one alkyl group is bonded to the nitrogen atom is preferred. In the ammonium salt compound, as long as at least one alkyl group (preferably having 1 to 20 carbon atoms) is bonded to the nitrogen atom, a cycloalkyl group (preferably having 3 to 20 carbon atoms) or an aryl group (preferably having 6 to 12 carbon atoms) may be bonded to the nitrogen atom in addition to the alkyl group. The ammonium salt compound preferably has an oxygen atom in the alkyl chain to form an oxyalkylene group. The number of oxyalkylene groups within the molecule is 1 or more, preferably from 3 to 9, and more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

Examples of the anion of the ammonium salt compound include a halogen atom, a sulfonate, a borate and a phosphate, with a halogen atom and a sulfonate being preferred. The halogen atom is preferably chloride, bromide or iodide, and the sulfonate is preferably an organic sulfonate having 1 to 20 carbon atoms. Examples of the organic sulfonate include an alkylsulfonate and an arylsulfonate each having 1 to 20 carbon atoms. The alkyl group of the alkylsulfonate may have a substituent, and examples of the substituent include fluorine, chlorine, bromine, an alkoxy group, an acyl group and an aryl group. Specific examples of the alkylsulfonate include methanesulfonate, ethanesulfonate, butanesulfonate, hex anesulfonate, octanesulfonate, benzylsulfonate, trifluoromethanesulfonate, pentafluoroethanesulfonate and nonafluorobutanesulfonate. The aryl group of the arylsulfonate includes a benzene ring, a naphthalene ring and an anthracene ring. The benzene ring, naphthalene ring and anthracene ring may have a substituent, and the substituent is preferably a linear or branched alkyl group having 1 to 6 carbon atoms, or a cycloalkyl group having 3 to 6 carbon atoms. Specific examples of the linear or branched alkyl group and cycloalkyl group include methyl, ethyl, n-propyl, isopropyl, n-butyl, i-butyl, tert-butyl, n-hexyl and cyclohexyl. Other examples of the substituent include an alkoxy group having 1 to 6 carbon atoms, a halogen atom, cyano, nitro, an acyl group and an acyloxy group.

The phenoxy group-containing amine compound and the phenoxy group-containing ammonium salt compound are an amine compound or ammonium salt compound having a phenoxy group at the terminal opposite the nitrogen atom of the alkyl group. The phenoxy group may have a substituent. Examples of the substituent of the phenoxy group include an alkyl group, an alkoxy group, a halogen atom, a cyano group, a nitro group, a carboxyl group, a carboxylic acid ester group, a sulfonic acid ester group, an aryl group, an aralkyl group, an acyloxy group and an aryloxy group. The substitution site of the substituent may be any of 2- to 6-positions, and the number of substituents may be any in the range of 1 to 5.

The compound preferably has at least one oxyalkylene group between the phenoxy group and the nitrogen atom. The number of oxyalkylene groups within the molecule is 1 or more, preferably from 3 to 9, and more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

The sulfonic acid ester group in the sulfonic acid ester group-containing amine compound and the sulfonic acid ester group-containing ammonium salt compound may be any of an alkylsulfonic acid ester, a cycloalkylsulfonic acid ester and an arylsulfonic acid ester. In the case of an alkylsulfonic acid ester, the alkyl group preferably has 1 to 20 carbon atoms; in the case of a cycloalkylsulfonic acid ester, the cycloalkyl group preferably has 3 to 20 carbon atoms; and in the case of an arylsulfonic acid ester, the aryl group preferably has 6 to 12 carbon atoms. The alkylsulfonic acid ester, cycloalkylsulfonic acid ester and arylsulfonic acid ester may have a substituent, and the substituent is preferably a halogen atom, a cyano group, a nitro group, a carboxyl group, a carboxylic acid ester group or a sulfonic acid ester group.

The compound preferably has at least one oxyalkylene group between the sulfonic acid ester group and the nitrogen atom. The number of oxyalkylene groups within the molecule is 1 or more, preferably from 3 to 9, and more preferably from 4 to 6. Among oxyalkylene groups, an oxyethylene group (—CH₂CH₂O—) and an oxypropylene group (—CH(CH₃)CH₂O— or —CH₂CH₂CH₂O—) are preferred, and an oxyethylene group is more preferred.

The compounds shown below are also preferred as the basic compound.

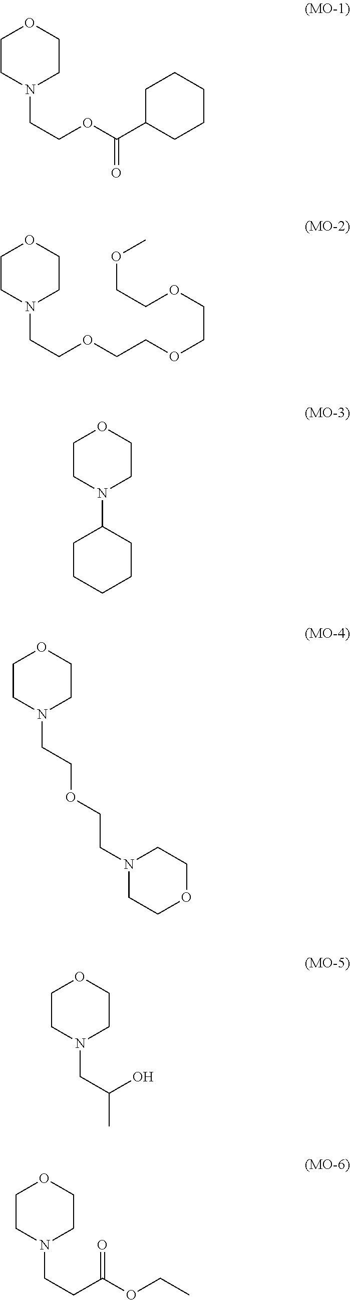

These basic compounds may be used alone or in combination of two or more thereof.

The composition of the present invention may or may not contain a basic compound, but in the case of containing a basic compound, the content thereof is usually from 0.001 to 10 mass %, and preferably from 0.01 to 5 mass %, based on the solid content of the actinic-ray-sensitive or radiation-sensitive resin composition.

The ratio between the acid generator (including the acid generator (A′)) and the basic compound used in the composition is preferably acid generator/basic compound (by mol)=from 2.5 to 300. That is, the molar ratio is preferably 2.5 or more in view of sensitivity and resolution and preferably 300 or less from the standpoint of suppressing the reduction in resolution due to thickening of the resist pattern with aging after exposure until heat treatment. The acid generator/basic compound (by mol) is more preferably from 5.0 to 200, and still more preferably from 7.0 to 150.

Such a basic compound is preferably used, based on (D) a low molecular weight compound shown in Section [5], in a molar ratio of (D) a low molecular weight compound/a basic compound=from 100/0 to 10/90, more preferably from 100/0 to 30/70, and still more preferably from 100/0 to 50/50.

Incidentally, the basic compound as used herein does not include a low molecular weight compound containing a nitrogen atom and having a group capable of leaving by the action of an acid when this is also a basic compound.

[5] Low Molecular Weight Compound Containing a Nitrogen Atom and Having a Group Capable of Leaving by the Action of an Acid

The composition of the present invention may contain a low molecular weight compound containing a nitrogen atom and having a group capable of leaving by the action of an acid (hereinafter, also referred to as a “low molecular weight compound (D)” or “compound (D)”).

The group capable of leaving by the action of an acid is not particularly limited but is preferably an acetal group, a carbonate group, a carbamate group, a tertiary ester group, a tertiary hydroxyl group or a hemiaminal ether group, and more preferably a carbamate group or a hemiaminal ether group.

The molecular weight of the low molecular weight compound (D) having a group capable of leaving by the action of an acid is preferably from 100 to 1,000, more preferably from 100 to 700, and still more preferably from 100 to 500.

The compound (D) is preferably an amine derivative having on the nitrogen atom a group capable of leaving by the action of an acid.

The compound (D) may have a protective group-containing carbamate group on the nitrogen atom. The protective group constituting the carbamate group may be represented by the following formula (d-1):

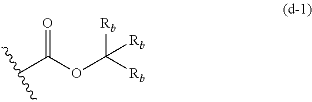

In formula (d-1), each of Rb's independently represents a hydrogen atom, an alkyl group, a cycloalkyl group, an aryl group, an aralkyl group or an alkoxyalkyl group. Rb's may combine with every other to form a ring.

Each of the alkyl group, cycloalkyl group, aryl group and aralkyl group of Rb may be substituted with a functional group such as a hydroxyl group, a cyano group, an amino group, a pyrrolidino group, a piperidino group, a morpholino group or an oxo group, an alkoxy group or a halogen atom. The same shall apply to the alkoxyalkyl group of Rb.

Examples of the alkyl group, cycloalkyl group, aryl group and aralkyl group (each of these alkyl group, cycloalkyl group, aryl group and aralkyl group may be substituted with the above-described functional group, an alkoxy group or a halogen atom) of Rb include: a group derived from a linear or branched alkane such as methane, ethane, propane, butane, pentane, hexane, heptane, octane, nonane, decane, undecane or dodecane, or a group where the group derived from an alkane is substituted with one or more kinds of or one or more groups of cycloalkyl groups such as a cyclobutyl group, a cyclopentyl group and cyclohexyl group; a group derived from a cycloalkane such as cyclobutane, cyclopentane, cyclohexane, cycloheptane, cyclooctane, norbornane, adamantane or noradamantane, or a group where the group derived from a cycloalkane is substituted with one or more kinds of or one or more groups of linear or branched alkyl groups such as a methyl group, an ethyl group, an n-propyl group, an i-propyl group, an n-butyl group, a 2-methylpropyl group, a 1-methylpropyl group and a tert-butyl group;

a group derived from an aromatic compound such as benzene, naphthalene or anthracene, or a group where the group derived from an aromatic compound is substituted with one or more kinds of or one or more groups of linear or branched alkyl groups such as a methyl group, an ethyl group, an n-propyl group, an i-propyl group, an n-butyl group, a 2-methylpropyl group, a 1-methylpropyl group and a tert-butyl group;

a group derived from a heterocyclic compound such as pyrrolidine, piperidine, morpholine, tetrahydrofuran, tetrahydropyran, indole, indoline, quinoline, perhydroquinoline, indazole or benzimidazole, or a group where the group derived from a heterocyclic compound is substituted with one or more kinds of or one or more groups of linear or branched alkyl groups or aromatic compound-derived groups; a group where the group derived from a linear or branched alkane or the group derived from a cycloalkane is substituted with one or more kinds of or one or more groups of aromatic compound-derived groups such as a phenyl group, a naphthyl group and anthracenyl group; and a group where the substituent above is substituted with a functional group such as a hydroxyl group, a cyano group, an amino group, a pyrrolidino group, a piperidino group, a morpholino group or an oxo group.

Rb is preferably a linear or branched alkyl group, a cycloalkyl group or an aryl group, and more preferably a linear or branched alkyl group or a cycloalkyl group.

Examples of the ring formed by combining two Rb's include an alicyclic hydrocarbon group, an aromatic hydrocarbon group, a heterocyclic hydrocarbon group, and a derivative thereof.

Specific structures of the group represented by formula (d-1) are illustrated below,

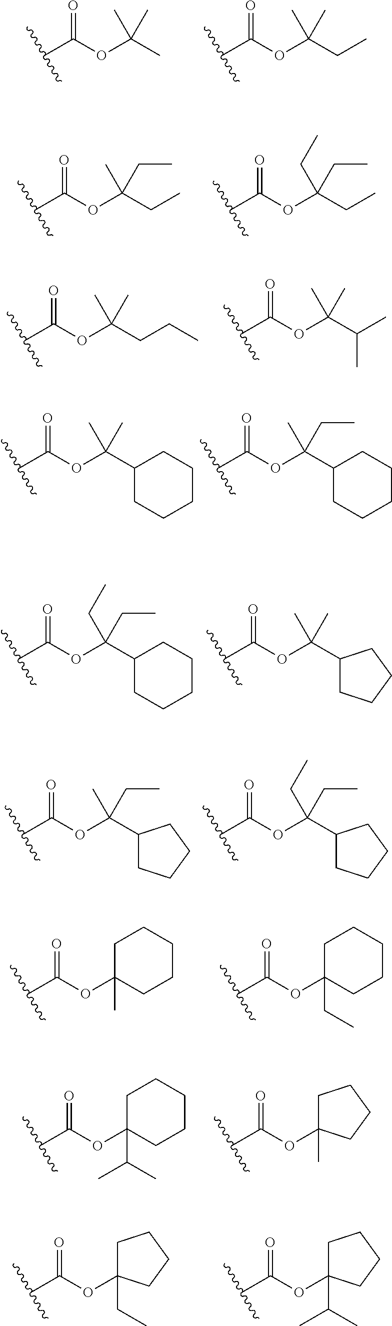

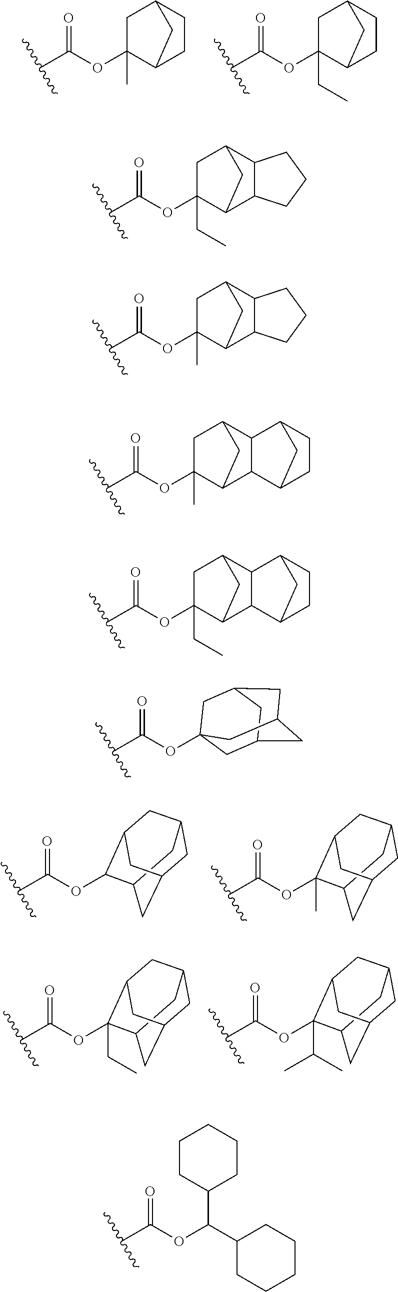

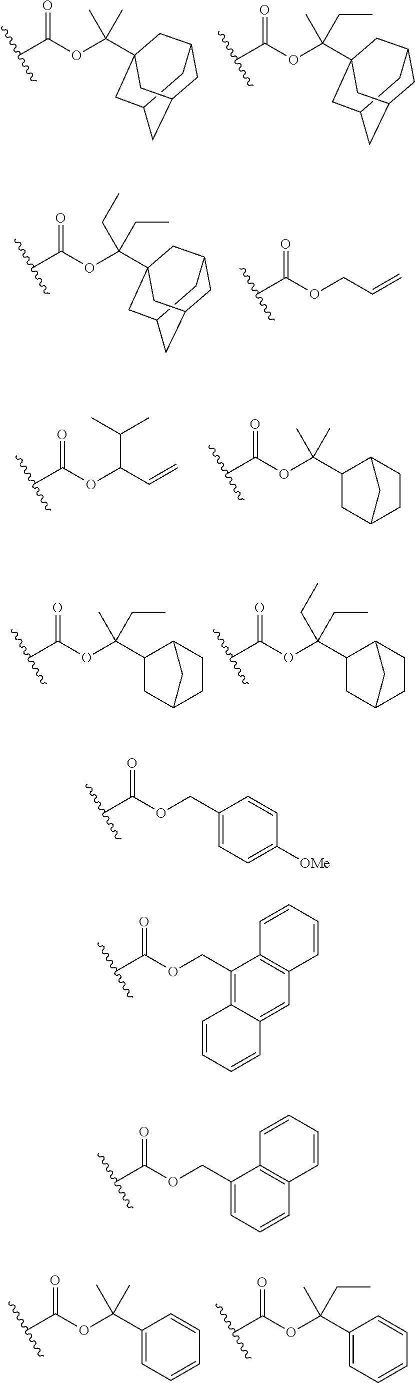

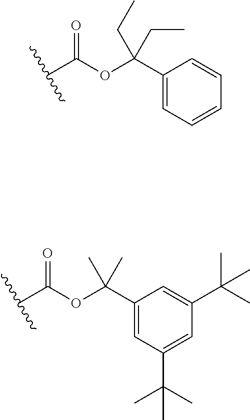

The compound (D) may be also composed by arbitrarily combining the above-described basic compound and the structure represented by formula (d-1).

The compound (D) is more preferably a compound having a structure represented by the following formula (A).

Incidentally, the compound (D) may be a compound corresponding to the above-described basic compound as long as it is a low molecular weight compound having a group capable of leaving by the action of an acid.

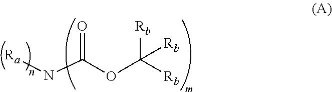

In formula (A), each Ra independently represents a hydrogen atom, an alkyl group, a cycloalkyl group, an aryl group or an aralkyl group. Also, when n=2, two Ra's may be the same or different, and two Ra's may combine with each other to form a divalent heterocyclic hydrocarbon group (preferably having 20 or less carbon atoms) or a derivative thereof.

Rb has the same meaning as Rb in formula (d-1) and preferred examples are also the same. However, in —C(Rb)(Rb)(Rb), when one or more Rb's are a hydrogen atom, at least one of the remaining Rb's is a cyclopropyl group, a 1-alkoxyalkyl group or an aryl group.

n represents an integer of 0 to 2, m represents an integer of 1 to 3, and n+m=3.

In formula (A), each of the alkyl group, cycloalkyl group, aryl group and aralkyl group of Ra may be substituted with those described for the group which may be substituted on the alkyl group, cycloalkyl group, aryl group and aralkyl group of Rb.

Examples of the alkyl group, cycloalkyl group, aryl group and aralkyl group (each of these alkyl group, cycloalkyl group, aryl group and aralkyl group may be substituted with the above-described group) of Ra are the same as specific examples of Rb.

Examples of the divalent heterocyclic hydrocarbon group (preferably having 1 to 20 carbon atoms) formed by combining Ra's with each other or a derivative thereof include a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline or 1,5,9-triazacyclododecane, and a group where the group derived from a heterocyclic compound is substituted with one or more kinds of or one or more groups of linear or branched alkane-derived group, cycloalkane-derived group, aromatic compound-derived group, heterocyclic compound-derived group, and functional group such as a hydroxyl group, a cyano group, an amino group, a pyrrolidino group, a piperidino group, a morpholino group or oxo group.

Specific examples of the compound (D) particularly preferred in the present invention are illustrated below, but the present invention is not limited thereto.

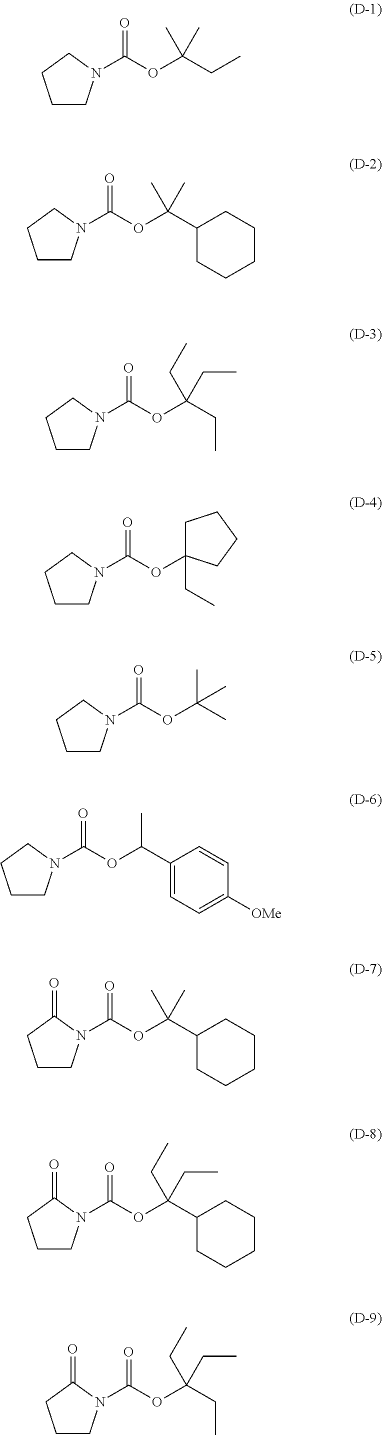

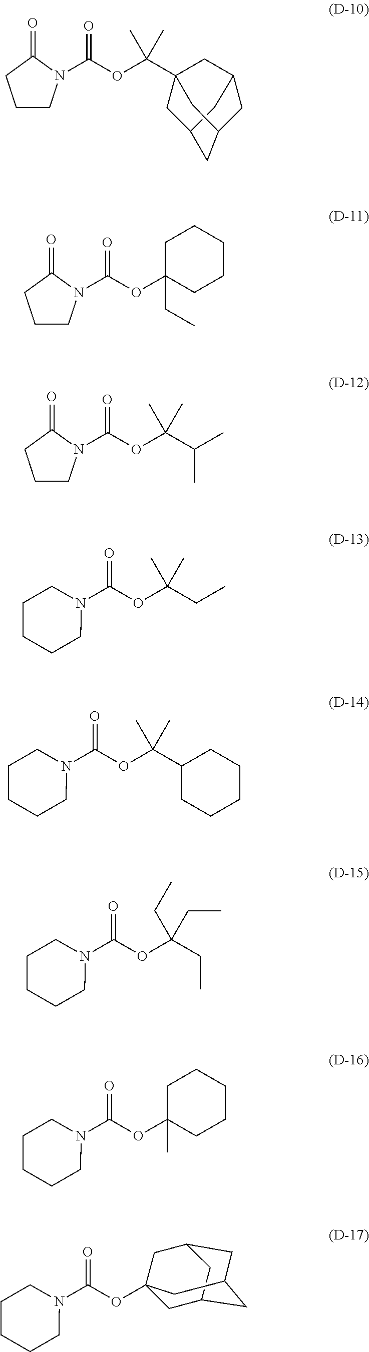

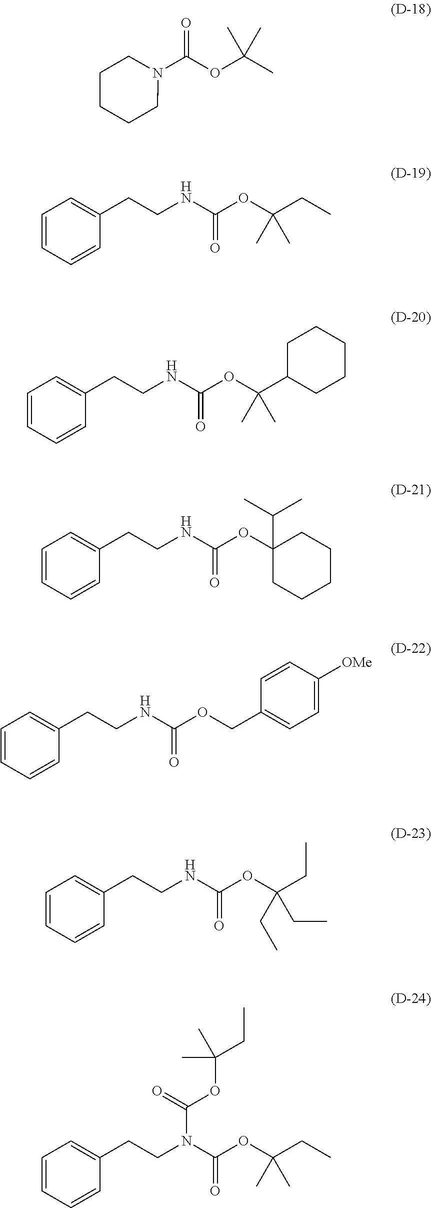

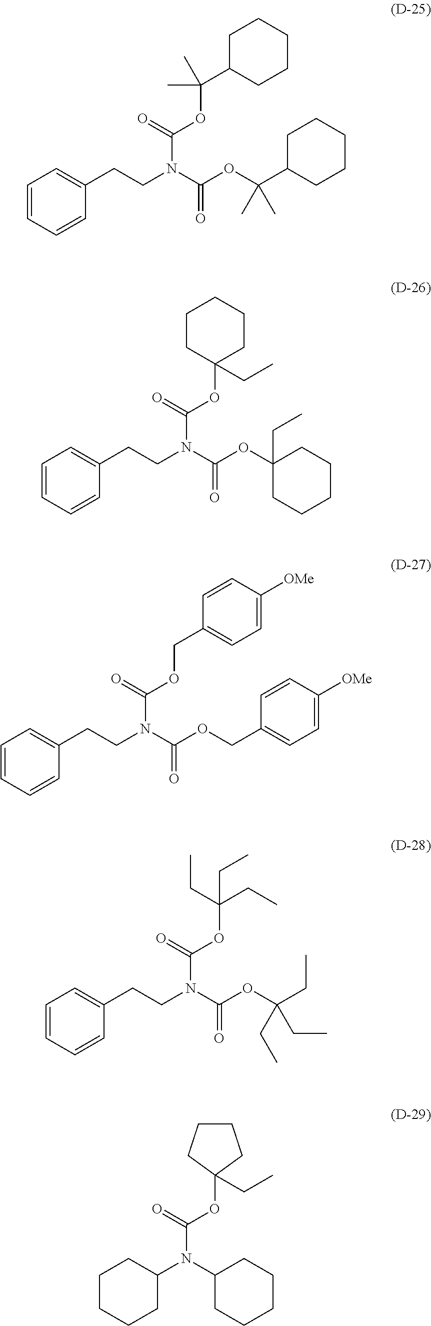

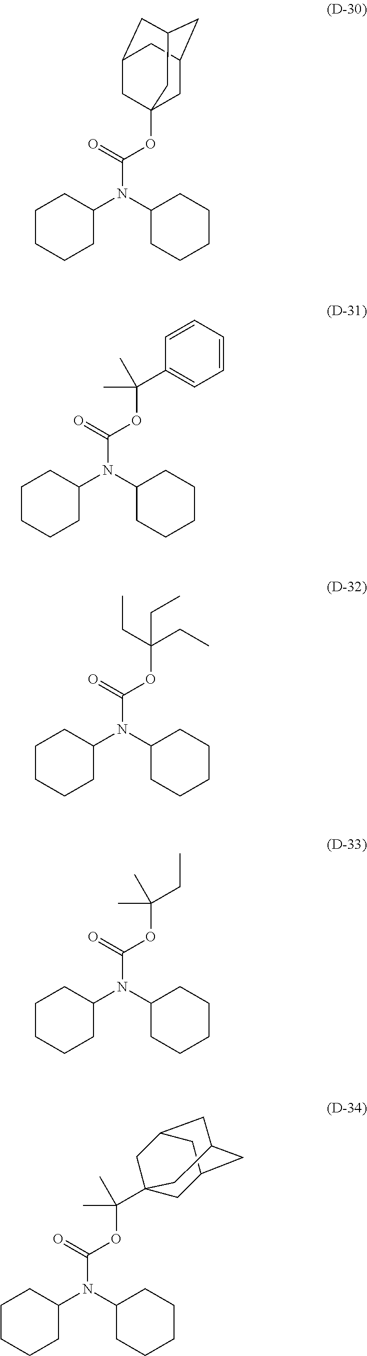

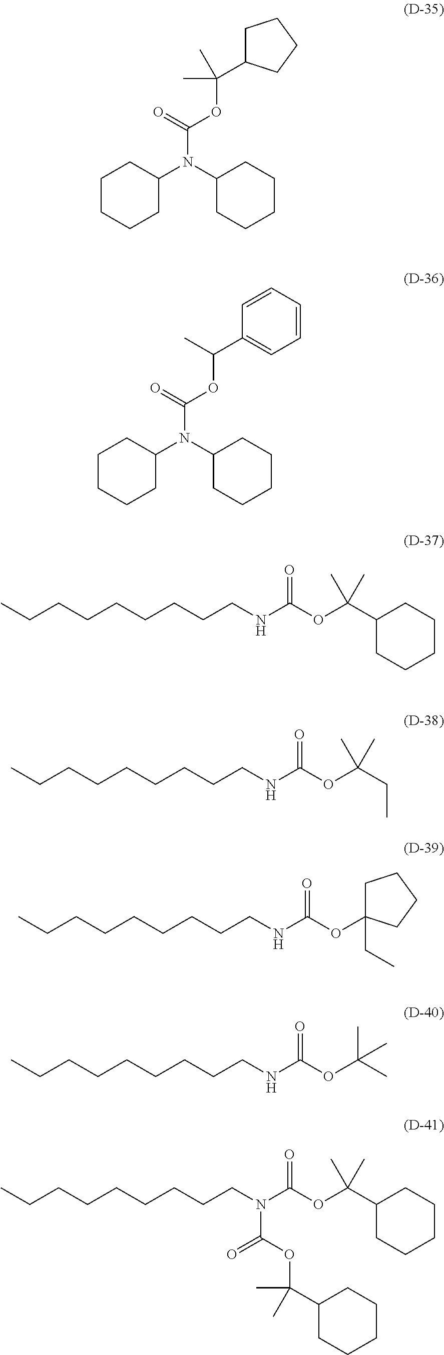

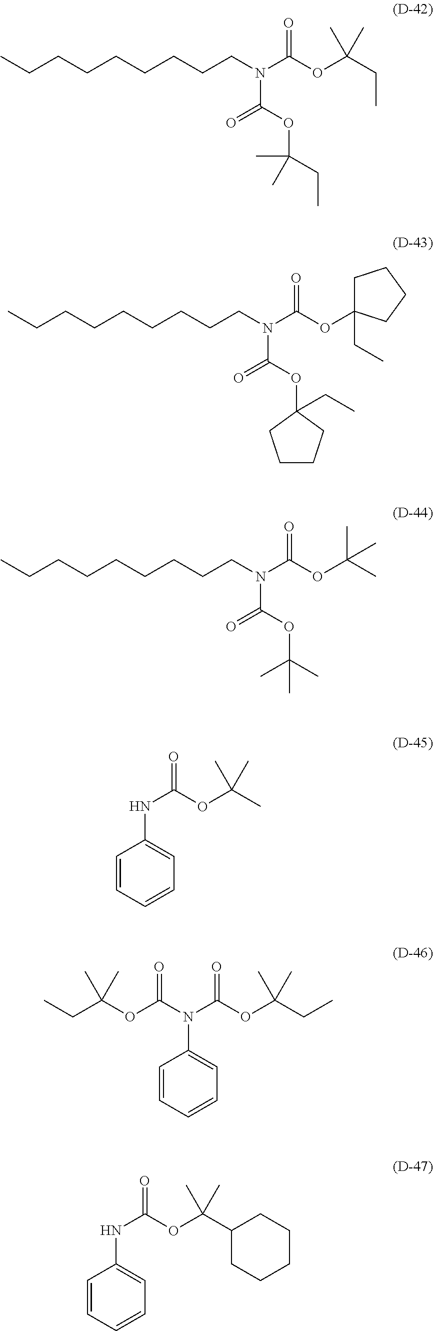

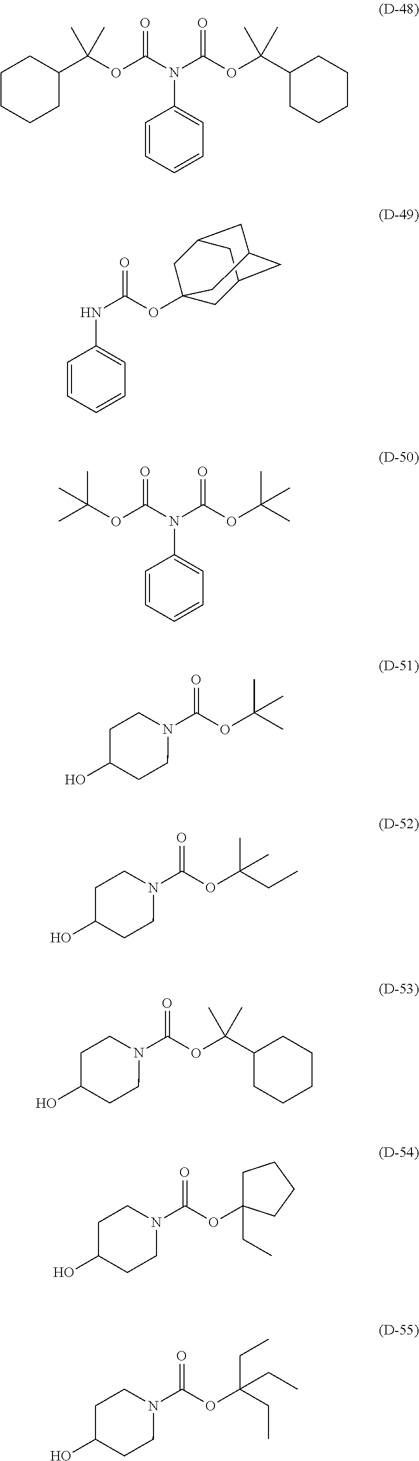

The compound represented by formula (A) may be synthesized based on JP2007-298569A, JP2009-199021A, or the like.

In the present invention, as for the (D) low molecular weight compound containing a nitrogen atom and having a group capable of leaving by the action of an acid, one kind of a compound may be used alone, or two or more kinds of compounds may be mixed and used.

The actinic-ray-sensitive or radiation-sensitive resin composition of the present invention may or may not contain (D) a low molecular weight compound containing a nitrogen atom and having a group capable of leaving by the action of an acid, but in the case of containing the low molecular weight compound (D), the content thereof is usually from 0.001 to 20 mass %, preferably from 0.001 to 10 mass %, and more preferably from 0.01 to 5 mass %, based on the total solid content of the composition combined with the basic compound.

[6] Surfactant

The composition of the present invention may or may not further contain a surfactant. Fluorine-based and/or silicon-based surfactants are preferred.

Examples of these surfactants include Megaface F176, Megaface R08 (available from DIC Corporation), PF656, PF6320 (available from OMNOVA), Troysol S-366 (available from Chemical Co., Ltd), Florad FC430 (available from Sumitomo 3M Limited), and Polysiloxane Polymer KP-341 (available from Shin-Etsu Chemical Co., Ltd.).

In the present invention, a surfactant other than the fluorine-based and/or silicon-based surfactant may be also used. Specific examples thereof include polyoxyethylene alkyl ethers and polyoxyethylene alkylaryl ethers.

Known surfactants other than these may also be appropriately used. Examples of usable surfactants include those described in Section [0273] et seq. of US 2008/0248425 A1.

These surfactants may be used alone or in combination of two or more thereof.

The actinic-ray-sensitive or radiation-sensitive resin composition of the present invention may or may not contain a surfactant, but in the case of containing a surfactant, the content thereof is preferably from 0 to 2 mass %, more preferably from 0.0001 to 2 mass %, and still more preferably from 0.0005 to 1 mass %, based on the total solid content of the composition.

On the other hand, it is also preferred that the surfactant is not added or is added in an amount of 10 ppm or less. In this case, the hydrophobic resin is more unevenly distributed to the surface, so that the resist film surface can be made more hydrophobic. As a result, the followability of water upon immersion exposure of the resist film can be enhanced.

[7] Solvent

The solvent that can be used at the time of preparing the composition is not particularly limited as long as it can dissolve the components of the composition. Examples of the solvent include an alkylene glycol monoalkyl ether carboxylate (propylene glycol monomethyl ether acetate or the like), an alkylene glycol monoalkyl ether (propylene glycol monomethyl ether or the like), an alkyl lactate (ethyl lactate, methyl lactate or the like), a cyclic lactone (γ-butyrolactone or the like, preferably having 4 to 10 carbon atoms), a chain or cyclic ketone (2-heptanone, cyclohexanone or the like, preferably having 4 to 10 carbon atoms), an alkylene carbonate (ethylene carbonate, propylene carbonate or the like), an alkyl carboxylate (preferably an alkyl acetate such as butyl acetate), and an alkyl alkoxyacetate (ethyl ethoxypropionate or the like). Examples of other useful solvents include those described in Section [0244] et seq. of US 2008/0248425 A1.

Among the above solvents, alkylene glycol monoalkyl ether carboxylate and alkylene glycol monoalkyl ether are preferred.

These solvents may be used alone or in combination of two or more thereof. When two or more of these solvents are mixed together, it is preferred to mix a solvent containing a hydroxyl group and a solvent containing no hydroxyl group. The mixing ratio (by mass) of the solvent containing a hydroxyl group to the solvent containing no hydroxyl group is from 1/99 to 99/1, preferably from 10/90 to 90/10, and more preferably from 20/80 to 60/40.

The solvent containing a hydroxyl group is preferably alkylene glycol monoalkyl ether. The solvent containing no hydroxyl group is preferably alkylene glycol monoalkyl ether carboxylate.

(8) Other Components

The composition of the present invention may appropriately contain, in addition to the above components, an onium salt of carboxylic acid, a dissolution inhibiting compound having a molecular weight of 3000 or less described in, for example, Proceeding of SPIE, 2724, 355 (1996), a dye, a plasticizer, a photosensitizer, a light absorber, etc. It is of course needless to say that the total content of individual components based on the total solid content in the composition is not more than 100 mass %.

[9] Pattern Forming Method

The pattern forming method of the present invention includes steps of exposing and developing a resist film.

The resist film is formed from the actinic-ray-sensitive or radiation-sensitive resin composition of the present invention and more specifically, is preferably formed on a substrate. In the pattern forming method of the present invention, a step of forming a film of a resist composition on a substrate, a step of exposing the film, and a step of developing the film are generally carried out by a known method.

The actinic-ray-sensitive or radiation-sensitive resin composition of the present invention is preferably used in the formation of a resist film having a thickness of 30 to 250 nm, more preferably from 30 to 200 nm, from the standpoint of enhancing the resolution. A resist film having such a film thickness may be formed by setting the solid content concentration in the actinic-ray-sensitive or radiation-sensitive resin composition to an appropriate range, thereby imparting an appropriate viscosity and enhancing the coatability and film-forming property.

The total solid content concentration in the actinic-ray-sensitive or radiation-sensitive resin composition of the present invention is generally from 1 to 10 mass %, preferably from 1 to 8.0 mass %, and more preferably from 1.0 to 6.0 mass %.

The actinic-ray-sensitive or radiation-sensitive resin composition of the present invention is used by dissolving the components above in a solvent, filtering the solution, and coating it on a support. The filter used for filtration is preferably a polytetrafluoroethylene-, polyethylene- or nylon-made filter having a pore size of 0.1 μm or less, more preferably 0.05 μm or less, and still more preferably 0.03 μm or less. Further, plural kinds of filters may be used in serial or parallel connection. Further, the composition may be filtered several times. Further, the composition may be subjected to a deaeration treatment or the like before and after filtration.

The composition is coated on a substrate (e.g., silicon/silicon dioxide-coated substrate) as used in the production of an integrated circuit device, by an appropriate coating method such as by using a spinner and then dried to form a photosensitive resist film.

The resist film is irradiated with actinic-rays or radiations through a predetermined mask, then preferably baked (heated), and subjected to development and rinsing, whereby a favorable pattern may be obtained. When the film is subjected to irradiation of an electron beam, lithography through no mask (direct lithography) is generally carried out.

The pattern forming method also preferably includes, after film formation, a pre-baking step (PB) before entering the exposure step.

Furthermore, the pattern forming method also preferably includes a post-exposure baking step (PEB) after the exposure step but before the development step.

As for the heating temperature, both PB and PEB are preferably carried out at a temperature of 70 to 120° C., and more preferably at 80 to 110° C.

The heating time is preferably from 30 to 300 seconds, more preferably from 30 to 180 seconds, and still more preferably from 30 to 90 seconds.

The heating may be carried out using a device attached to an ordinary exposure/developing machine or may be carried out using a hot plate or the like.

Thanks to baking, the reaction in the exposed area is accelerated, and the sensitivity and pattern profile are improved.

The actinic-rays or radiations are not particularly limited, but examples thereof include a KrF excimer laser, an ArF excimer laser, EUV light, and an electron beam. Among these, ArF excimer laser, EUV light, and an electron beam are preferred.

In the development step, an alkaline developer used is usually a quaternary ammonium salt typified by tetramethylammonium hydroxide, but other than this compound, an aqueous alkali solution of an inorganic alkali, a primary to tertiary amine, an alcohol amine, a cyclic amine or the like may also be used.

Furthermore, the alkaline developer may be used after adding thereto alcohols and a surfactant each in an appropriate amount.

The alkali concentration of the alkaline developer is usually from 0.1 to 20 mass %. The pH of the alkaline developer is usually from 10.0 to 15.0.

As for the rinsing solution, pure water is used, and an appropriate amount of a surfactant may be added to the pure water before use.

Examples of the development method applicable herein include a method of dipping a substrate for a predetermined period of time into a bath filled with a developer (dip method), a method of raising a developer on a substrate surface by the effect of surface tension and leaving the developer at rest for a given period of time to perform the development (puddle method), a method of spraying a developer on a substrate surface (spray method) and a method of continuously ejecting a developer on a substrate rotating at a constant speed while scanning a developer ejecting nozzle at a constant rate (dynamic dispense method).

After the development or rinsing, a treatment of removing the developer or rinsing solution adhering on the pattern by a supercritical fluid may be carried out.

Before forming the photosensitive film (resist film), an antireflection film may be previously provided by coating on the substrate.

The antireflection film used may be either an inorganic film type such as titanium, titanium dioxide, titanium nitride, chromium oxide, carbon or amorphous silicon, or an organic film type composed of a light absorber and a polymer material. As for the organic antireflection film, commercially available organic antireflection films may also be used such as DUV30 Series and DUV-40 Series available from Brewer Science, Inc. and AR-2, AR-3 and AR-5 available from Shipley Co., Ltd.

For the film formed using the actinic-ray-sensitive or radiation-sensitive resin composition of the present invention, the exposure may also be carried out by filling a liquid (immersion medium) having a refractive index higher than that of air between the film and the lens at the irradiation with actinic-rays or radiations (immersion exposure). By this exposure, the resolution may be enhanced. The immersion medium used is preferably water. Water is also preferred in view of low temperature coefficient of refractive index, easy availability and easy handleability.

Furthermore, a medium having a refractive index of 1.5 or more may also be used from the standpoint that the refractive index can be further enhanced. This medium may be either an aqueous solution or an organic solvent.

In the case of using water as the immersion liquid, an additive for the purpose of increasing the refractive index or the like may be added in a slight proportion. Examples of the additive are particularized in Chapter 12 of “Processes and Materials of Liquid Immersion Lithography” published by CMC Publishing Co., Ltd. On the other hand, if a substance opaque to light at 193 nm or an impurity greatly differing in the refractive index from water is intermixed, this incurs distortion of the optical image projected on the film. Therefore, the water used is preferably distilled water. Pure water obtained by further filtering the distilled water through an ion exchange filter or the like may be also used.

The electrical resistance of pure water used as the immersion liquid is preferably 18.3 MQcm or more, and TOC (total organic carbon) is preferably 20 ppb or less. Also, the water is preferably subjected to a deaeration treatment.

In order to prevent the resist film from directly contacting with the immersion liquid, a film (hereinafter, also referred to as a “top coat”) sparingly soluble in an immersion liquid may be provided between the resist film and the immersion liquid. The functions required of the top coat are suitability for coating on the resist film, transparency to radiations, particularly, radiations having a wavelength of 193 nm, and sparing solubility in the immersion liquid. The top coat is preferably unmixable with the resist film and uniformly coatable on the resist film.

In view of transparency to light at 193 nm, the top coat is preferably an aromatic-free polymer. Examples of such a polymer include a hydrocarbon polymer, an acrylic acid ester polymer, a polymethacrylic acid, a polyacrylic acid, a polyvinyl ether, a silicon-containing polymer and a fluorine-containing polymer. The above-described hydrophobic resin is suitable also as the top coat. If impurities are dissolved out into the immersion liquid from the top coat, the optical lens is contaminated. In this viewpoint, little residual monomer components of the polymer are preferably contained in the top coat.

On peeling off the top coat, a developer may be used or a releasing agent may be separately used. The releasing agent is preferably a solvent permeating the resist film to a lower extent. From the standpoint that the peeling step may be carried out simultaneously with the development step of the resist, the top coat is preferably peelable with an alkaline developer. From the standpoint of peeling with an alkaline developer, the top coat is preferably acidic, but in view of non-intermixing with the resist, the top coat may be neutral or alkaline.

The difference in the refractive index between the top coat and the immersion liquid is preferably zero or small. In this case, the resolution can be enhanced. In the case where the exposure light source is an ArF excimer laser (wavelength: 193 nm), water is preferably used as the immersion liquid and therefore, the top coat for ArF immersion exposure preferably has a refractive index close to the refractive index (1.44) of water.

Also, in view of transparency and refractive index, the top coat is preferably a thin film.

The top coat is preferably unmixable with the resist film and further unmixable with the immersion liquid. From this point of view, when the immersion liquid is water, the solvent used for the top coat is preferably a medium that is sparingly soluble in the solvent used for the actinic-ray-sensitive or radiation-sensitive resin composition of the present invention and is insoluble in water. Furthermore, when the immersion liquid is an organic solvent, the top coat may be either water-soluble or water-insoluble.

### EXAMPLES

Hereinafter, the present invention will be described with reference to Examples, but the present invention should not be construed as being limited thereto.

### Synthesis Example 1

### Synthesis of Compound A-1

### 1,1,2,2,3,3-hexafluoro-3-(piperidine-1-sulfonyl)propane-1-sulfonic acid 9-ethylcarbazol-2-yltetrahydrothiophenium

First, 3.0 g of 9-ethylcarbazole and 3.6 g of tetramethylene sulfoxide were dissolved in 120 ml of chloroform, and the solution was cooled to −30° C. under a nitrogen stream.

A solution of 7.2 g of a trifluoroacetic anhydride in 30 g of chloroform was dropped thereto over 30 minutes. The temperature of the mixed solution was raised to room temperature, followed by reaction for 4 hours, and 10.6 g of sodium 1,1,2,2,3,3-hexafluoro-3-(piperidine-1-sulfonyl)propane-1-sulfonate dissolved in 80 ml of acetonitrile/20 ml of water was added thereto. The chloroform phase was washed with water and then concentrated to obtain crude crystals. The crystals were washed with cyclopentyl methyl ether to obtain 8.3 g of 1,1,2,2,3,3-hexafluoro-3-(piperidine-1-sulfonyl)propane-1-sulfonic acid 9-ethylcarbazol-2-yltetrahydrothiophenium (compound A-1).

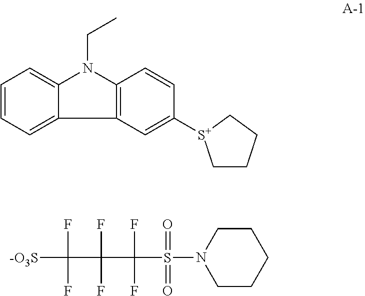

¹H-NMR (300 MHz, CDCl₃): δ8.5 (s. 1H), δ8.2 (d. 1H), δ7.8 (d. 1H), δ7.65 (d. 12H), δ7.6 (t. 1H), δ7.45 (d. 1H), δ7.35 (t. 1H), δ4.4 (t. 2H), δ4.2 (m. 2H), δ3.95 (d. 1H), δ3.8 (d. 1H), δ3.65 (m. 2H), δ3.0 (t. 1H), δ2.7 (m. 3H), δ2.5 (m. 2H), δ1.75 (m. 2H), δ1.75-1.5 (m. 4H), δ1.45 (t. 3H), δ1.4-1.2 (m. 4H), δ1.1-0.85 (m. 3H)

Other photoacid generators shown in Table 2 to be described later were synthesized in the same manner as in Synthesis Example 1.

### Synthesis Example 2

### Synthesis of Resin A

Under a nitrogen stream, 40 g of cyclohexanone was charged in a three-necked flask and heated at 80° C. (Solvent 1). Monomers corresponding to the respective repeating units were dissolved in a molar ratio of 40/10/50 in cyclohexanone to prepare 22 mass % of a monomer solution (400 g), and a polymerization initiator V-601 (available from Wako Pure Chemical Industries, Ltd.) was added thereto and dissolved in a concentration of 7.2 mol % based on all monomers. The resulting solution was added dropwise to Solvent 1 over 6 hours. After the completion of dropwise addition, the reaction was further allowed to proceed at 80° C. for 2 hours. The reaction liquid was left standing to cool and then poured into 3,600 ml of heptane/400 ml of ethyl acetate, and the resulting precipitate was collected by filtration and dried to obtain 74 g of Resin A. The polymer composition ratio as measured by NMR was 40/10/50. The weight average molecular weight of the obtained Resin A was 9800 and the dispersity (Mw/Mn) was 1.53.

Resins B to F were synthesized in the same manner as in Synthesis Example 2.

### Synthesis Example 3

### Synthesis of Hydrophobic Resin B-2

Monomers corresponding to the respective repeating units (starting from the left) of the above-exemplified hydrophobic resin B-2 were charged in a molar ratio of 30/70 and dissolved in propylene glycol monomethyl ether acetate (PGMEA) to prepare 450 g of a solution having a solid content concentration of 15 mass %. Subsequently, 1 mol % of a polymerization initiator V-60 (available from Wako Pure Chemical Industries, Ltd.) was added thereto. The resulting solution was added dropwise to 50 g of PGMEA heated to 100° C., under a nitrogen atmosphere over 6 hours. After the completion of dropwise addition, the reaction liquid was stirred for 2 hours. After the completion of the reaction, the reaction liquid was cooled to room temperature, and crystallized from 5 L of methanol. The thus precipitated white material was collected by filtration to recover a desired hydrophobic resin B-2.

The polymer composition ratio as measured by NMR was 30/70. The weight average molecular weight thereof in terms of standard polystyrene as measured by GPC was 6500, and the dispersity thereof was 1.4.

Hydrophobic resins B-4, B-10, B-12, B-18, B-28 and B-52 were synthesized in the same manner as in Synthesis Example 3, except that monomers corresponding to the respective repeating units were used in a desired composition ratio (by mol).

<Preparation of Actinic-Ray-Sensitive or Radiation-Sensitive Resin Composition and Resist Evaluation>

Each of actinic-ray-sensitive or radiation-sensitive resin compositions was prepared by dissolving components shown in Table 2 below in a solvent to obtain a solution having a solid content concentration of 4 mass % with respect to each of the components, and filtering the same through a polyethylene filter having a pore size of 0.05 μm. The thus prepared actinic-ray-sensitive or radiation-sensitive resin compositions were evaluated in the following manner. The results are given in Table 2.

With respect to the components of Table 2, the ratio in the use of multiple components is a mass ratio.

In Table 2, the addition mode is indicated as “Addition” when the actinic-ray-sensitive or radiation-sensitive resin composition contained a hydrophobic resin (HR). On the other hand, the addition mode is indicated as “TC” when the actinic-ray-sensitive or radiation-sensitive resin composition was free of a hydrophobic resin (HR) and when after the formation of a film, a top coat protective film containing a hydrophobic resin (HR) was formed on an upper layer of the film.

TABLE 2

| | | | Basic | | | | | | |
|---|---|---|---|---|---|---|---|---|---|
| | | | compound | Hydrophobic | | | Evaluation results | | |
| | Photoacid | | or | resin | | | Exposure | Dissolution into | |
| | generator | Resin | compound | (HR) | | Surfactant | latitude | immersion liquid | Pattern |
| | (g) | (10 g) | (D) (g) | (35 mg) | Solvent | (10 mg) | (%) | (×10⁻¹² mol/cm²) | profile |
| Example 1 | A-1 | A | DIA | Addition | A1 = 100 | W-1 | 19.0 | 24 | A |
| | (2.1) | | (0.3) | B-2 | | | | | |
| Example 2 | A-2 | B | APCA | Addition | A1/B1 = | W-2 | 18.7 | 28 | A |
| | (2.1) | | (0.33) | B-10 | 60/40 | | | | |
| Example 3 | A-3 | C | DBA | Addition | A1/A2 = | W-1 | 18.4 | 31 | A |
| | (2.0) | | (0.35) | B-12 | 90/10 | | | | |
| Example 4 | A-4 | E | APCA | Addition | A1/A3 = | W-3 | 19.4 | 20 | A |
| | (1.9) | | (0.28) | B-18 | 90/10 | | | | |
| Example 5 | A-5 | D | PBI | Addition | A1 = 100 | W-1 | 17.6 | 41 | A |
| | (1.9) | | (0.38) | B-28 | | | | | |
| Example 6 | A-6 | F | DIA | Addition | A1 = 100 | W-4 | 17.8 | 40 | A |
| | (1.6) | | (0.36) | B-52 | | | | | |
| Example 7 | A-7 | D | PBI | TC | A1/A2 = | — | 18.0 | 39 | A |
| | (2.2) | | (0.35) | B-4 | 90/10 | | | | |
| Example 8 | A-8 | A | PEA | Addition | A1/B1 = | W-1 | 18.1 | 35 | A |
| | (2.0) | | (0.40) | B-2 | 60/40 | | | | |
| Example 9 | A-9 | E | DIA | Addition | A1 = 100 | W-2 | 18.3 | 33 | A |
| | (1.8) | | (0.41) | B-12 | | | | | |
| Example 10 | A-10 | C | PBI | TC | A1 = 100 | W-1 | 17.5 | 45 | A |
| | (1.8) | | (0.37) | B-4 | | | | | |
| Example 11 | A-11 | B | DBA | TC | A1/B2/A3 | W-2 | 17.3 | 48 | A |
| | (2.2) | | (0.10) | B-28 | 75/20/5 | | | | |
| | | | APCA | | | | | | |
| | | | (0.15) | | | | | | |
| Example 12 | A-12 | C | TMEA | Addition | A1 = 100 | W-3 | 17.1 | 50 | A |
| | (1.9) | | (0.36) | B-52 | | | | | |
| Example 13 | A-1 | C | APCA | Addition | A1 = 100 | W-1 | 19.0 | 35 | A |
| | (1.5) | | (0.28) | B-52 | | | | | |
| | z1 | | | | | | | | |
| | (0.3) | | | | | | | | |
| Example 14 | A-13 | A | PBI | Addition | A1/B2 = | W-2 | 18.9 | 25 | A |
| | (2.0) | | (0.37) | B-18 | 80/20 | | | | |
| Example 15 | A-15 | A(5 g) | DBA | Addition | A1/A3 = | W-1 | 19.2 | 22 | A |
| | (1.5) | E(5 g) | (0.28) | B-18 | 90/10 | | | | |
| Example 16 | A-26 | A | APCA | Addition | A1 = 100 | W-4 | 19.2 | 21 | A |
| | (2.0) | | (0.28) | B-52 | | | | | |
| Example 17 | A-4 | C | PBI | Addition | A1/B2 = | W-1 | 19.1 | 36 | A |
| | (1.7) | | (0.37) | B-52 | 80/20 | | | | |
| | z45 | | | | | | | | |
| | (0.2) | | | | | | | | |
| Example 18 | A-14 | A(5 g) | APCA | Addition | A1 = 100 | W-2 | 19.0 | 24 | A |
| | (2.0) | E(5 g) | (0.28) | B-12 | | | | | |
| Example 19 | A-1 | A(5 g) | PBI | Addition | A1/A3 = | W-1 | 19.1 | 23 | A |
| | (2.1) | D(5 g) | (0.37) | B-52 | 90/10 | | | | |
| | | | | (26 mg) | | | | | |
| | | | | B-28 | | | | | |
| | | | | (10 mg) | | | | | |
| Example 20 | A-2 | E | APCA | Addition | A1 = 100 | W-2 | 19.0 | 26 | A |
| | (0.5) | | (0.28) | B-18 | | | | | |
| | A-2 | | | | | | | | |
| | (0.6) | | | | | | | | |
| Example 21 | A-44 | A | DIA | Addition2 | A1 = 100 | W-1 | 19.0 | — | A |
| | (2.1) | | (0.42) | B-2 | | | | | |
| Comparative | RA-1 | A | DIA | Addition | A1 = 100 | W-1 | 15.3 | 98 | C |
| Example 1 | (2.0) | | (0.42) | B-12 | | | | | |
| Comparative | RA-2 | A | APCA | Addition | A1 = 100 | W-1 | 16.5 | 65 | B |
| Example 2 | (2.0) | | (0.42) | B-10 | | | | | |
| Comparative | RA-3 | A | APCA | Addition | A1 = 100 | W-1 | 16.3 | 68 | B |
| Example 3 | (1.8) | | (0.42) | B-10 | | | | | |

The abbreviated codes used in the table are as follows.

[Photoacid Generator]

Compounds A-1 to A-15, A-22, A-26, A-44, z1, z45 are as described hereinbefore.

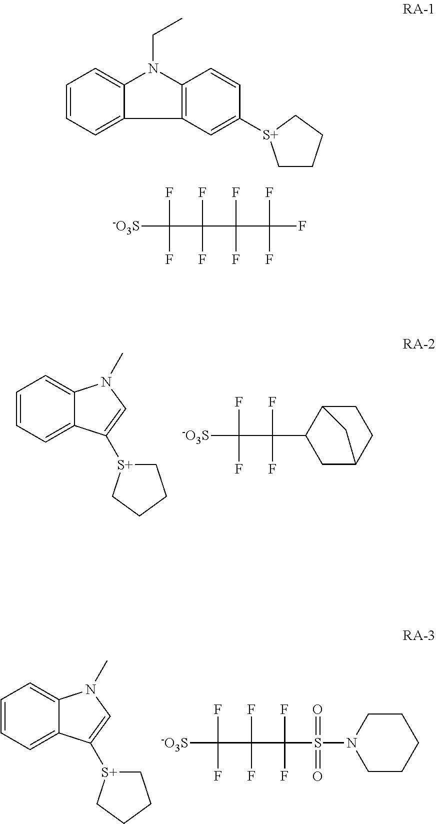

[Resin (B)]

The structure and weight average molecular weight (Mw) and dispersity (Mw/Mn) of the resin (B) used in Examples are illustrated below.

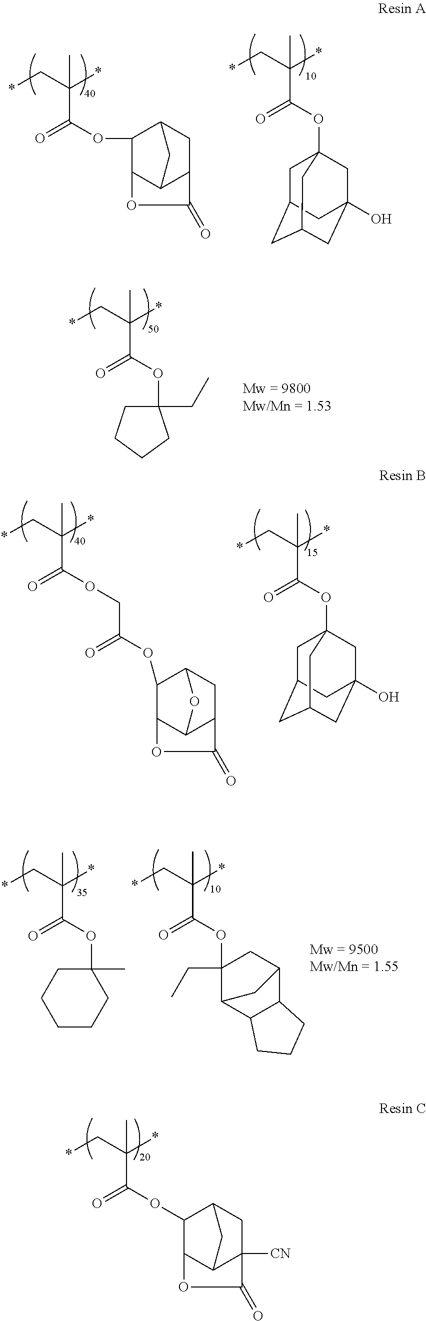

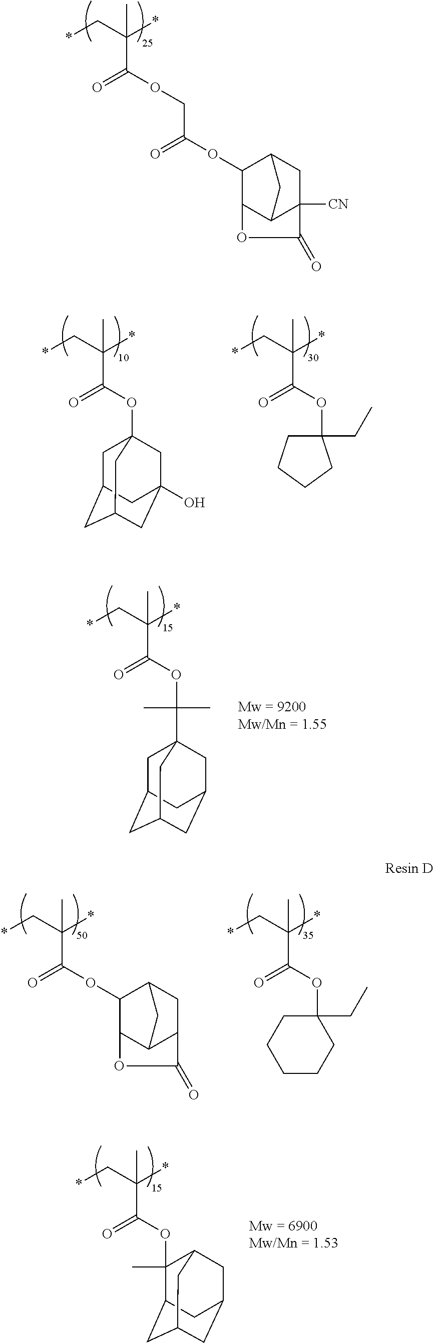

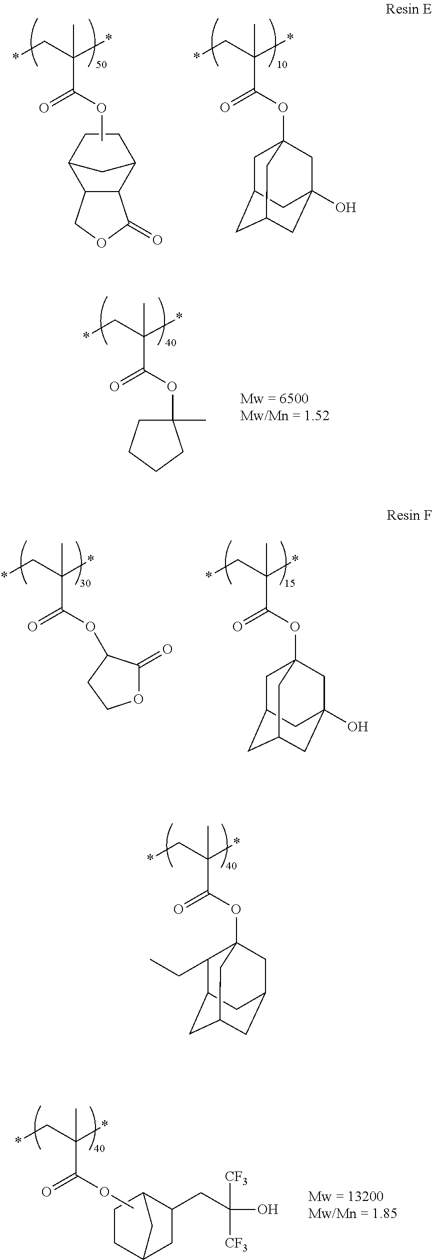

[Hydrophobic Resin (HR)]

Hydrophobic resins B-2, B-4, B-10, B-12, B-18, B-28, and B-52 are as described hereinbefore.

[Basic Compound]

DIA: 2,6-diisopropylaniline

PEA: N-phenyldiethanolamine

TMEA: Tris(methoxyethoxyethyl)amine

DBA: N,N-dibutylaniline

PBI: Phenylbenzoimidazole

[(D) A low molecular weight compound containing a nitrogen atom and having a group capable of leaving by the action of an acid (compound (D)]

APCA: 4-hydroxy-1-tert-butoxycarbonylpiperidine

[Surfactant]

W-1: Megaface F176 (available from DIC Corporation; fluorine-based)

W-2: Megaface R08 (available from DIC Corporation; fluorine and silicon-based),

W-3: Troysol S-366 (available from Troy Chemical Co., Ltd.), and

W-4: PF656 (available from OMNOVA; fluorine-based).

[Solvent]

A1: Propylene glycol monomethyl ether acetate (PGMEA),

A2: Cyclohexanone,

A3: γ-butyrolactone,

B1: Propylene glycol monomethyl ether (PGME), and

B2: Ethyl lactate.

[Exposure Condition 1 (ArF Immersion Exposure): Examples 1 to 6, 8, 9, 12 to 20 and Comparative Examples 1 to 3]

ARC29SR (available from Nissan Chemical Industries, Ltd.) for forming an organic antireflection film, was applied onto a 12-inch silicon wafer and baked at 205° C. for 60 seconds to form a 95 nm-thick antireflection film, and the actinic-ray-sensitive or radiation-sensitive resin composition prepared was coated thereon and baked at 85° C. for 60 seconds to form a resist film having a thickness of 100 nm. The obtained wafer was exposed through a 6% halftone mask having a 1:1 line-and-space pattern with a line width of 48 nm by using an ArF excimer laser immersion scanner (XT-1700i, available from ASML, NA: 1.20, σo/σi=0.94/0.74). As for the immersion liquid, ultrapure water was used. Thereafter, the wafer was heated at 90° C. for 60 seconds, developed by applying a puddling method with an aqueous tetramethylammonium hydroxide solution (2.38 mass %) for 30 seconds, rinsed by applying a puddling method with pure water and spin-dried to obtain a resist pattern.

[Exposure condition 2 (ArF immersion exposure): Examples 7, 10, and 11]

A resist pattern was formed under the same condition as in Exposure condition 1, except that the resist film having a thickness of 100 nm was formed and prior to exposure, each of top coat compositions prepared using each of hydrophobic resins shown in Table 2 was coated on the resist film, followed by baking at 115° C. for 60 seconds to form a top coat film having a thickness of 0.05 μm.

[Evaluation of Exposure Latitude in ArF Immersion Exposure]

The exposure amount that reproduced a line-and-space pattern with a line width of 48 nm was determined and denoted as an optimum exposure amount. Thereafter, an exposure amount width which permits a pattern size of 48 nm±10% in response to a change in the exposure amount was determined and was divided by the optimum exposure amount. The value obtained was expressed in terms of percentage. As this value is greater, the change of performance in response to an exposure amount change is less and the exposure latitude is better.

[Test of Dissolution into Immersion Liquid]

The prepared actinic-ray-sensitive or radiation-sensitive resin composition was coated on an 8-inch silicon wafer and baked at 120° C. for 60 seconds to form a 150 nm-thick resist film. Subsequently, the entire surface of the resist film was exposed at 20 mJ/cm² by using an exposure machine with a wavelength of 193 nm. 5 mL of pure water deionized using an ultrapure water production apparatus (Milli-Q Jr, available from Nihon Millipore K.K.) was dropped on the resist film. After water was placed on the resist film for 10 seconds, the water was collected, and the dissolution concentration of an acid was determined by LC-MS.

LC apparatus: 2695 available from Waters Corporation

MS apparatus: Esquire 3000plus available from Brucker Daltonics

The detection intensity of ion species having a molecular weight corresponding to an anion was measured by the LC-MS apparatus to calculate the dissolution amount of the acid.

[Evaluation of Pattern Profile in ArF Immersion Exposure]

The section profile of the line pattern having a line width of 48 nm, which was obtained by the minimum exposure amount that reproduced a line pattern with a line width of 48 nm in a mask, was observed under a scanning electron microscope. The line pattern having a rectangular profile was designated as A, the line pattern having a round top profile was designated as C, and the line pattern having a slightly round top profile was designated as B.

[Exposure Condition 3 (ArF Dry Exposure): Example 21]

ARC29A (available from Nissan Chemical Industries, Ltd.) for forming an organic antireflection film, was applied onto an 8-inch silicon wafer and baked at 205° C. for 60 seconds to form a 78 nm-thick antireflection film, and the actinic-ray-sensitive or radiation-sensitive resin composition prepared was coated thereon and baked at 110° C. for 60 seconds to form a resist film having a thickness of 120 nm. The obtained wafer was exposed through a 6% halftone mask having a 1:1 line-and-space pattern with a line width of 75 nm by using an ArF excimer laser scanner (PAS5500/1100, available from ASML, NA: 0.75). Thereafter, the wafer was heated at 90° C. for 60 seconds, developed by applying a puddling method with an aqueous tetramethylammonium hydroxide solution (2.38 mass %) for 30 seconds, rinsed by applying a puddling method with pure water and spin-dried to obtain a resist pattern.

[Evaluation of Exposure Latitude in ArF Dry Exposure]

The exposure amount that reproduced a line-and-space pattern with a line width of 75 nm was determined and denoted as an optimum exposure amount. Thereafter, an exposure amount width which permits a pattern size of 75 nm±10% in response to a change in the exposure amount was determined and was divided by the optimum exposure amount. The value obtained was expressed in terms of percentage.

[Evaluation of Pattern Profile in ArF Dry Exposure]

The section profile of the line pattern having a line width of 75 nm, which was obtained by the minimum exposure amount that reproduced a line pattern with a line width of 75 nm in a mask, was observed under a scanning electron microscope. The line pattern having a rectangular profile was designated as A, the line pattern having a round top profile was designated as C, and the line pattern having a slightly round top profile was designated as B.

As apparent from the results given in Table 2, it can be seen that Comparative Examples 1 to 3 using a photoacid generator having no cation structure in formula (I) exhibited small exposure latitude and high dissolution of the components into an immersion liquid, were not rectangular in terms of a pattern profile, and were inferior in view of all evaluation items.

On the other hand, it can be seen that Examples 1 to 20 using the photoacid generator represented by formula (I) exhibited large exposure latitude and low dissolution of the components into an immersion liquid, were rectangular in terms of a pattern profile, and were excellent in view of all evaluation items.

Further, it can be seen that Examples 1 to 4, 7 to 9 and 13 to 20 using the photoacid generator of formula (I) wherein X is a nitrogen atom-containing group or a sulfur atom, and L is a group such as —COO—, —COO—, —SO₂— or —SO₂NH— exhibited a tendency of larger exposure latitude and further less dissolution of the components into an immersion liquid.

Among them, it can be seen that Examples where R₁ and R₂ in formula (I) do not combine to form a ring (Examples 4, 15 to 18 and 20 for the case where X is a nitrogen atom-containing group, and Example 9 for the case where X is a sulfur atom) exhibited a tendency of particularly large exposure latitude and particularly low dissolution of the components into an immersion liquid. Further, it can be seen that Example 21, which was applied to ArF dry exposure, also exhibited large exposure latitude, rectangular pattern profile, and excellent properties for any evaluation item.

What is claimed is:

1. An actinic-ray-sensitive or radiation-sensitive resin composition, comprising:
(A) a compound represented by formula (I) and capable of generating an acid upon irradiation of actinic-rays or radiations; and
(B) a resin capable of increasing the solubility in an alkaline developer by the action of an acid. 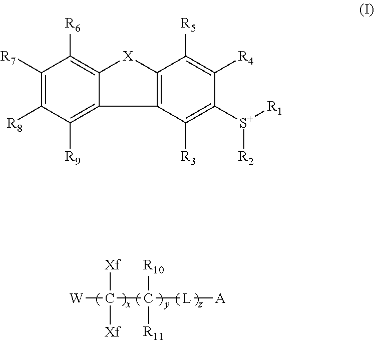
wherein
X represents an oxygen atom, a sulfur atom or —N(Rx)—,
R₁ and R₂ each independently represent an alkyl group, a cycloalkyl group or an aryl group,
R₃ to R₉ each independently represent a hydrogen atom, an alkyl group, a cycloalkyl group, an alkoxy group, an alkoxycarbonyl group, an acyl group, an alkylcarbonyloxy group, an aryl group, an aryloxy group, an aryloxycarbonyl group or an arylcarbonyloxy group,
Rx represents a hydrogen atom, an alkyl group, a cycloalkyl group, an acyl group, an alkenyl group, an alkoxycarbonyl group, an aryl group, an arylcarbonyl group or aryloxycarbonyl group,
R₁ and R₂ may combine with each other to form a ring, and two or more of R₆ to R₉, R₃ and R₉, R₄ and R₅, R₅ and Rx, and R₆ and Rx each may combine with each other to form a ring,
Xf's each independently represent a fluorine atom, or an alkyl group substituted with at least one fluorine atom,
R₁₀ and R₁₁ each independently represent a hydrogen atom, a fluorine atom, or an alkyl group, and in the case where a plurality of R₁₀'s or R₁₁'s are present, each R₁₀ or R₁₁ may be the same as or different from every other R₁₀ or R₁₁,
L represents a divalent linking group, and in the case where a plurality of L's are present, each L may be the same as or different from every other L,
A represents a cyclic organic group,
W represents ⁻O₃S—, RfSO₂—N⁻—SO₂—, Rf—CO—N⁻—SO₂— or Rf—SO₂—N⁻—CO— wherein Rf represents an alkyl group substituted with at least one fluorine atom, and
x represents an integer of 1 to 20, y represents an integer of 0 to 10, and z represents an integer of 0 to 10.

2. The actinic-ray-sensitive or radiation-sensitive resin composition according to claim 1, wherein X of formula (I) represents a sulfur atom or —N(Rx)—.

3. The actinic-ray-sensitive or radiation-sensitive resin composition according to claim 1, wherein L of formula (I) represents —COO—, —COO—, —CO—, —SO₂—, —CON(Ri)—, —SO₂N(Ri)—, —CON(Ri)-alkylene group-, —OCO-alkylene group- or —COO-alkylene group- (wherein Ri represents a hydrogen atom or alkyl).

4. The actinic-ray-sensitive or radiation-sensitive resin composition according to claim 2, wherein L of formula (I) represents —COO—, —COO—, —CO—, —SO₂—, —CON(Ri)—, —SO₂N(Ri)—, —CON(Ri)-alkylene group-, —OCO-alkylene group- or —COO-alkylene group- (wherein Ri represents a hydrogen atom or alkyl).

5. The actinic-ray-sensitive or radiation-sensitive resin composition according to claim 1, further comprising a hydrophobic resin.

6. The actinic-ray-sensitive or radiation-sensitive resin composition according to claim 5, wherein the hydrophobic resin has a repeating unit (b) containing at least one group selected from the group consisting of the following (x) to (z):
(x) an alkali-soluble group,
(y) a group capable of decomposing by the action of an alkaline developer to increase the solubility in an alkaline developer, and
(z) a group capable of decomposing by the action of an acid to increase the solubility in an alkaline developer.

7. The actinic-ray-sensitive or radiation-sensitive resin composition according to claim 5, wherein the content of the hydrophobic resin is in the range of 0.01 to 20 mass %, based on the total solid content.

8. The actinic-ray-sensitive or radiation-sensitive resin composition according to claim 1, wherein the resin (B) contains an alicyclic hydrocarbon structure.

9. The actinic-ray-sensitive or radiation-sensitive resin composition according to claim 1, wherein the resin (B) has at least either a repeating unit represented by formula (I) or a repeating unit represented by formula (II): 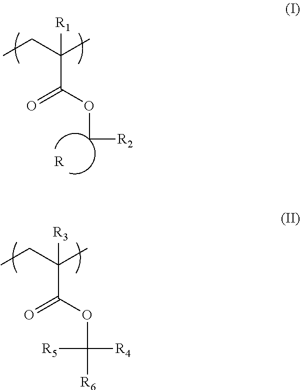
wherein
R₁ and R₃ each independently represent a hydrogen atom, a methyl group which may have a substituent, or a group represented by —CH₂—R₉ wherein R₉ represents a hydroxyl group or a monovalent organic group,
R₂, R₄, R₅, and R₆ each independently represent an alkyl group or a cycloalkyl group, and
R represents an atomic group necessary for forming an alicyclic structure together with the carbon atom.

10. The actinic-ray-sensitive or radiation-sensitive resin composition according to claim 1, wherein the resin (B) contains a repeating unit having a lactone structure.

11. The actinic-ray-sensitive or radiation-sensitive resin composition according to claim 1, wherein the cyclic organic group A in formula (I) is an alicyclic group.

12. The actinic-ray-sensitive or radiation-sensitive resin composition according to claim 1, further comprising at least one of a fluorine-based surfactant and a silicon-based surfactant.

13. The actinic-ray-sensitive or radiation-sensitive resin composition according to claim 1, further comprising a basic material.

14. The actinic-ray-sensitive or radiation-sensitive resin composition according to claim 1, further comprising a low molecular weight compound containing a nitrogen atom and having a group capable of leaving by the action of an acid.

15. The actinic-ray-sensitive or radiation-sensitive resin composition according to claim 5, wherein the hydrophobic resin is a hydrophobic resin having at least either a fluorine atom or a silicon atom.

16. A resist film formed using the actinic-ray-sensitive or radiation-sensitive resin composition of claim 1.

17. A pattern forming method, comprising:
exposing the resist film of claim 16; and
developing the exposed resist film.

18. The pattern forming method according to claim 17, wherein the exposure is immersion exposure.

19. A method of manufacturing an electronic device, comprising the pattern forming method of claim 17.

20. An electronic device manufactured by the method of claim 19.
